(19) United States
(12) Patent Application Publication
(10) Pub. No.: US 2008/0116861 A1
(43) Pub. Date: May 22, 2008

(54) APPARATUS AND METHOD FOR CONTROLLING THE PROPAGATION DELAY OF A CIRCUIT BY CONTROLLING THE VOLTAGE APPLIED TO THE CIRCUIT

(75) Inventors: KENT KERNAHAN, CUPERTINO, CA (US); MILTON D. RIBEIRO, LOS ALTOS, CA (US); DONGSHENG ZHOU, SAN JOSE, CA (US); SORIN ANDREI SPANOCHE, SANTA CLARA, CA (US); RAFAEL PAYSEO-DIAZ, SUNNYVALE, CA (US); CRAIG NORMAN LAMBERT, SAN JOSE, CA (US); MICHAEL W. CALDWELL, SANTA CLARA, CA (US); JINGQUAN CHEN, SAN JOSE, CA (US)

Correspondence Address: MICHAEL W. CALDWELL, 4226 RIVERMARK PARKWAY, SANTA CLARA, CA, 95054-4150, US

(73) Assignee: FyreStorm, Inc.

(21) Appl. No.: 11/618,942

(22) Filed: Jan. 2, 2007

Related U.S. Application Data
(63) Continuation of application No. 11/604,165, filed on Nov. 22, 2006.

(51) Int. Cl. G05F 1/577; G05F 1/00; H03H 11/26

(52) U.S. Cl. 323/267; 323/265; 327/276

(57) ABSTRACT

The voltage applied to an integrated circuit is controlled by a temporal process monitor formed as part of the integrated circuit. The temporal process monitor includes a voltage controlled oscillator for producing a first output signal having a first period. A comparator compares the first period to one or more reference values. Should the first period be greater than a first selected reference value the comparator sends a signal to increase the voltage being supplied to the integrated circuit. Should the first period be less than a second selected reference value, the comparator sends a signal to decrease the voltage applied to the integrated circuit. In some embodiments a scaling circuit is provided for producing a second output signal having a second period different from (typically but not necessarily longer than) the first period. By placing the temporal process monitor on an integrated circuit chip, process variations and environmental factors which affect the performance of the integrated circuit can be automatically compensated so that the integrated circuit performs within specifications. Two or more temporal process monitors can be placed on a single integrated circuit chip or on different integrated circuit chips and the longest period produced by the temporal process monitors can be used to control the voltage supplied to all the sections of the integrated circuit chip associated with the temporal process monitors or to all the integrated circuit chips associated with the temporal process monitors.

### CROSS REFERENCE TO RELATED APPLICATIONS

This application claims priority of and is a continuation of commonly assigned U.S. patent application Ser. No. 11/604,165 filed 22 NOV 2006 by Kent Kernahan, et al, entitled “APPARATUS AND METHOD FOR CONTROLLING THE PROPAGATION DELAY OF A CIRCUIT BY CONTROLLING THE VOLTAGE APPLIED TO THE CIRCUIT”, which is incorporated by reference herein in its entirety.

This application is also related to commonly assigned U.S. patent application Ser. No. 11/030,688, entitled “SWITCHING POWER CONVERTER EMPLOYING PULSE FREQUENCY MODULATION CONTROL”, U.S. patent application Ser. No. 11/030,585 entitled “POWER CONVERTERS WITH LIMITED OPERATION TO CONSERVE POWER AND WITH ADJUSTMENTS THAT OVERCOME RINGING”, and U.S. patent application Ser. No. 11/030,729 entitled “POWER CONVERTERS IN WHICH THE INPUT POWER COUPLING TIMES ARE ADJUSTED IN CONJUNCTION WITH CYCLE SKIP COUNTS”, all filed 5 JAN 2005 by Kent Kernahan and Milton D. Ribeiro, which are incorporated by reference herein in their entirety.

### BACKGROUND

Proper design of electronic components and of systems using electronic components requires that the designer provide design latitude such that the components and/or system operate properly over a specified range of temperature and voltage. Complex components, such as integrated circuits, are fabricated using a wafer-based process. Due to manufacturing variations from one fabricator to another, one wafer batch to another, one wafer to another within a common batch, or even individual circuits fabricated on a common wafer, each component so manufactured has differences in performance, behavior, and sensitivities compared to another so-called “identical” component.

Were components somehow able to be manufactured to be totally identical, the designer of a system using such components must still allow for the differences in operation due to variations in the voltage supplied and, importantly, in the temperature of operation. Thus a designer must take into account the range of allowable variations in manufacturing, temperature, and voltage.

For example, for integrated circuits manufactured from silicon wafers, circuits manufactured to a fast processing corner (for example, some combination of short transistor gate lengths, wide channels, thin gate oxide, low sheet resistance) may have yield loss due to hold violations. They also consume more power than necessary, in that the nominal voltage supplied is in excess of what is needed for target performance. Likewise, circuits manufactured to a slow processing corner (for example, some combination of long gate lengths, narrow channels, thick gate oxide, high sheet resistance) may have yield loss due to setup timing violations. Processing to a slow corner may also cause yield loss for otherwise fully-functional components that are not able to be clocked at the maximum design frequency. Manufacturers sometimes identify individual components by their minimum operating frequency and receive a lower price for slower units.

Once a component is manufactured, its behavior in a given operational condition is essentially fixed. In an effort to simplify design, limit the degree of design latitude needed, and control component behavior and power requirements as much as possible, circuit designers often specify tight control of the component supply voltage. This is to limit the universe of unknown conditions as much as possible. However, even were components able to be manufactured with perfect repeatability and power supplies able to provide the exact voltage requested with no variations, circuits would still experience significant changes due to temperature changes. Temperature changes can result from the surrounding environment and from self heating of the component.

All of these factors manifest themselves in the performance of a circuit at the individual element level with regard to its speed of operation. Were speed able to be controlled to a certain value regardless of manufacturing particulars and environmental factors, designers would be able to design with more latitude, more logic levels, faster clock speeds and would experience better yield at maximum clock speed. Once an individual component is made, the least controllable factor is temperature and the most direct control mechanism available is voltage. Thus what is needed is the ability to control component speed within a narrow range by controlling the voltage applied as-required for target speed operation. The maximum clocking speed of a digital component is a function of the propagation delay of the circuits employed. Therefore control of maximum clocking speed requires control of propagation delay.

The frequency of a VCO manufactured within an integrated circuit has been suggested as a measurement of the instant performance, that is, propagation delay, of the integrated circuit. The suggestion is to control the VCO frequency by controlling the voltage applied to the integrated circuit and the VCO, the VCO thereby forming a sensor for propagation delay. For example, see “A Fully Digital, Energy-Efficient, Adaptive Power Supply Regulator”, IEEE Journal of Solid-State Circuits, volume 34, No. 4, Apr., 1999, by G. Y. Wei and M. Horowitz. The VCO output signal may be viewed as “data” corresponding to the propagation delay of the monitored integrated circuit. A certain bandwidth is needed to provide adequate resolution in the data such that a controller may control the voltage provided to the integrated circuit such that the propagation delay of the integrated circuit remains within a predefined region. Additionally, the data must timely respond to changes in the propagation delay, enabling the controller to adequately detect and respond to transient conditions. To determine the frequency of a signal one must count the number of cycles during a certain time period, essentially a process of finding the average of the frequency within the time period. Resolution of the average frequency may be increased by counting across a longer time period, however a longer time period decreases the data bandwidth. Bandwidth may be increased by a higher frequency, here the frequency of the VCO output signal, allowing the same resolution by counting for a shorter period. However, the higher the VCO frequency, the greater the power required to carry the signal to the controller. What is needed is a low frequency signal with high data bandwidth and resolution.

Using the period of a version of the VCO output signal to provide data to a controller may provide the needed accuracy (resolution) and responsiveness (bandwidth) at lower power. A lower frequency signal's period, wherein the signal's period corresponds to a certain count of the VCO's output signal, may be measured by the controller to a resolution limited by the resolution capabilities of the controller, not by the resolution offered by the signal. Bandwidth is increased because averaging is not required. Table 1 compares a period-based data signal to a frequency-based data signal.

TABLE 1

| | Frequency | Period |
|---|---|---|
| Units | Cycles per unit time | Time |
| Resolution | Discrete, counting | Continuous, measurement |
| To increase | Longer sampling time. | Shorter incremental time. |
| resolution | | |
| Resolution of | Yes | No |
| control related | | |
| to sampling | | |
| interval | | |
| Conversion | (1/Freq) provides the | (1/Period) provides the |
| | average period of | instantaneous frequency |
| | cycles accumulated | represented by two |
| | over the sampling | individual events |
| | period | |
| Measurement type | Average (integration). | Rate (differentiation). |
| Interface power | Variable, proportional | Fixed, Independent of |
| for a fixed rate | to resolution. | resolution. |
| of control | | |

In the relevant art voltage is regulated to a certain target value by a power source, and provided to one or more components that require that same certain voltage. There is no feedback from the components on a common power line as to the individual component power requirements. This may cause power to be wasted in that the voltage, therefore power, provided may be in excess of the instant needs of all of the components on the power line. As individual component needs change due to activity, mode, or temperature, the minimum instant power requirement amongst all components may change.

Similarly, even within a given integrated circuit there may be multiple subsections powered by the same voltage source, but due to different structures, fan-out, or resistive drop along a power matrix, the various subsections may have differing power needs at any instant. If the instant power provided is in excess of the needs of all subsections, power is wasted. As temperature, performance, or load demands change, the power requirement of one subsection may change in a manner different from the power requirements of the other subsections. Thus there is a need to sense the power needs of all loads on a given power line and control the power source to provide the minimum power required amongst all monitored loads to provide for proper operation at the minimum power level.

Switching power converters are often used in electronic systems. In a synchronous switching power converter the timing of the synchronous regulator FET is critical to maximize the efficiency of the converter. In the relevant art the timing of the synchronous regulator FET is sometimes controlled by determining negative current conduction through the synchronous regulator FET. That, typically, requires a current sensor and a fast comparator. Typical implementations result in complex designs that penalize converter efficiency, especially at low load current conditions. The optimal synchronizing pulse width may be calculated, but heretofore has required knowledge of the input and output voltages of the switching power converter. What is needed is a method to optimize the timing of power and synchronous regulator FETs without knowledge of the input and output voltages or coil current.

Complex integrated circuits, for example personal computer microprocessors, often include an ability to request varying power levels from one or more power supplies. Such requests are due to, for example, varying demands for computing throughput, battery life extension, or user requests. Such integrated circuits may also vary their clocking speed in concert with the power change. Coordination of the two is a complex, inefficient task. Some applications would benefit from automatic correspondence between clock frequency and power demands.

### SUMMARY

In accordance with the present invention a power supply voltage is provided that is just high enough to guarantee a particular level of operation of a digital circuit throughout a specified temperature range and the vagaries of the fabrication process used to manufacture the circuit. The end result of operating at a minimum voltage is a potentially significant power savings. Additionally, a circuit may be physically smaller and higher yielding if timing, a critical design parameter, is adaptively controlled to a more narrow range. In the relevant art voltage is regulated to a certain target value and instant propagation delay is a result; in the present invention propagation delay is regulated and the instant voltage is controlled to overcome all factors which might cause an error in propagation delay.

In one embodiment of the present invention, a monitor is strategically placed within and manufactured in common with a digital circuit. The monitor is connected to the same power supply distribution matrix which is connected to the rest of the digital circuit and thus, experiences and is responsive to the same factors affecting the monitored circuit. The monitor provides an output signal which corresponds to the monitor's propagation delay, the propagation delay of the monitor corresponding to the propagation delay of the monitored circuit. The monitor's output signal is provided to a controller which compares the signal to a predetermined reference. The predetermined reference corresponds to the target propagation delay of the monitored circuit. The controller includes means for controlling the output voltage of a power supply which supplies power to the monitored circuit and the monitor. The controller determines the difference, if any, between the signal from the monitor and the predetermined reference and responsively controls the power supply such that the signal from the monitor is approximately the same as the predetermined reference. The result is control of the propagation delay of the monitored circuit to a target value, the propagation delay of the monitored circuit therefore being relatively insensitive to manufacturing variations and temperature.

In some embodiments a version of the monitor signal is also provided to the host circuit, within which the monitor is instantiated, the monitor signal providing the clocking signal for the host circuit instead of an independent time base, for example a crystal oscillator. The host circuit may modify its target propagation delay by adjusting a divide-by counter thereby modifying the period of the monitor signal. A power supply is controlled in response to the monitor signal, thereby providing a power level and clocking frequency for the host circuit which cooperatively change.

In an embodiment in accordance with the present invention a plurality of components are provided power by a common power supply wherein the power provided to the components is controlled to provide the minimum power which will maintain a minimum performance level amongst all of the components supplied by the common power supply. In one embodiment each individual component on a common power bus generates a representative timing signal responsive to the propagation delay of the individual component. The longest timing signal period from any of the components on the power bus is provided to an input port of a controller, the controller including a timer. The controller compares the period of the instant timing signal, as determined by the timer, to a predetermined target value. If the timing signal period is greater than the predetermined target value the controller increases the voltage output of the power supply. The timing signal period decreases, responsive to the increase in voltage. Accordingly, the controller is responsive to the specific component which indicates the longest timing signal period amongst all components that are supplied operating voltage by the common power supply.

In another embodiment each individual component on a common power line generates a representative timing signal responsive to the propagation delay of the individual component, the initiation of the representative timing signal generation being coordinated amongst all of the components such that they all start the timing signal generation at the same time. The timing signals are initially driven to a low logical level onto a common signal line, and released from the low level when the timing signal period is completed. A pull up in an interface circuit pulls the common signal line to a logical high level when the last of the timing signals has completed, and the interface circuit sends a signal to a controller. Accordingly, the longest timing signal period from any of the components connected to the common signal line is provided to an input port of the controller, the controller including a time sensor. The controller determines the period of the instant timing signal using the time sensor and compares the period of the instant timing signal to a predetermined target value. If the timing signal period is greater than the predetermined target value the controller increases the voltage provided to the power line, thereby decreasing the timing signal period. Accordingly, the controller is responsive to the specific component which indicates the longest timing signal period amongst all components that are supplied operating voltage by the common power line.

In one embodiment of the present invention the control signal period is controlled by a linear regulator. Voltage is provided to one terminal of an op amp by a first switched capacitor resistor and a first constant current source, wherein the control signal from the propagation delay monitor provides the driving frequency to the first switched capacitor resistor. Voltage is provided to a second terminal of the op amp by a second switched capacitor resistor and a second constant current source. The driving frequency to the second switched capacitor resistor is a precision time base. The output signal of the op amp is provided back to the circuit being monitored, including the monitor itself, responsive to any difference between the frequency of the control signal and the frequency of the precision time base, thereby minimizing the difference between them.

In one embodiment of the present invention a control loop examines the period of the instant monitor control. The control loop compares the period of the signal to a predetermined value and to certain boundary values to determine what, if any, action to take. In some cases the control loop quickly determines that no action is needed, minimizing the power consumed by execution of the control loop. In some embodiments an operating condition of the switching power converter is modified to allow efficient operation of the driven power components across a broad range of load conditions.

In an embodiment in accordance with the present invention the timing of a power FET in a switching power converter is controlled to provide an equilibrium condition wherein the average coil current is approximately the same as the current of the switching power converter load. At that condition the switching power converter power output level is acceptable from the standpoint of meeting the demands of the load. However the efficiency of the switching power converter may or may not be optimized. It can be shown that the maximum efficiency operating condition of a switching power converter has been attained when the power converter is in equilibrium with the load and the power FET duty cycle is at a minimum. In one embodiment the power FET timing is monitored to determine that the power converter is in equilibrium. A less frequent control loop makes small changes to the timing of a synchronous regulator FET while monitoring the power FET to determine the synchronous regulator FET timing which provides for the minimum duty cycle of the power FET, thus improving the efficiency of the switching power converter.

### BRIEF DESCRIPTION OF THE DRAWINGS

FIG. 1 shows overall system elements and their connections according to one embodiment of the present invention.

FIG. 2 is a schematic circuit of a VCO and a scaling circuit according to one embodiment of the present invention.

FIG. 3 shows schematically an alternative embodiment for inverting elements of a VCO according to an embodiment of the present invention.

FIG. 4 is a circuit diagram for a level shifter suitable for use in the system of FIG. 1.

FIG. 5 is a schematic of one embodiment wherein a plurality of bi-directional temporal process monitors in accordance with FIG. 6A are cooperatively connected to provide a single temporal process monitor signal.

FIG. 6A is a schematic of a bi-directional temporal process monitor.

FIG. 6B is a schematic of an open drain OR gate from FIG. 6A.

FIG. 7 is a schematic of an embodiment wherein a plurality of bi-directional temporal process monitors in accordance with FIG. 8 are cooperatively connected to provide a single temporal process monitor signal.

FIG. 8 is a schematic of a bi-directional temporal process monitor according to another embodiment of the present invention.

FIG. 9 shows the relationship between the counts of a reference clock during one period of a temporal process monitor signal.

FIG. 10 shows the relationship between the counts of a reference clock and multiple temporal process monitor signals wherein two counters are used, each counting reference clocks during a different temporal process monitor signal phase.

FIG. 11 shows simulation traces of power and clock frequency in response to a change in load and a change of a divide by value.

FIG. 12 shows a representative synchronous buck power converter coupled to the temporal power converter shown in FIG. 1.

FIG. 13 illustrates coil current in a switching power converter in continuous coil current mode (DCM).

FIG. 14 illustrates coil current in a switching power convert in discontinuous coil current mode (DCM).

FIG. 15 illustrates coil current in a switching power converter at the critical coil current point.

FIG. 16 superimposes a second coil current trace upon a previous coil current trace wherein the second coil current trace results from a change in power FET drive time.

FIG. 17 and FIG. 18 define various charge energies associated with first and second coil current traces of FIG. 16.

FIG. 19 is a more detailed version of FIG. 12 wherein the Coss capacitances of the FETs are shown.

FIG. 20 is an analytical model of the resonant circuit of FIG. 19.

FIG. 21 shows output voltage over time in relation to target, upper, and lower voltage limits.

FIG. 22 is a flow chart of the PFM control method used in a temporal power converter in one embodiment of the present invention.

FIG. 23 shows the relationship between time and current during time period T where a single set of control signals are applied to the converter of FIG. 12.

FIG. 24 shows an embodiment wherein correction is achieved by using multiple shorter duration pulses during a correction period rather than a single set of pulses such as that shown in FIG. 23.

FIG. 25 illustrates a non-synchronous boost converter coupled to an alternative temporal power converter, according to an embodiment of the present invention.

FIG. 26 defines the limits of certain regions of a temporal process monitor signal period as used by a control loop according to one embodiment of the present invention.

FIG. 27 illustrates certain trends of a temporal process monitor signal period over time in relation to the limits as defined in FIG. 26.

FIG. 28A is a flow chart of a VSPL control loop method according to one embodiment of the present invention.

FIG. 28B is another embodiment of the flow chart presented in FIG. 28A.

FIG. 29 illustrates the efficiency of a power FET at varying ON times.

FIG. 30 illustrates the equivalent energy of a cycle skipping pulse method compared to that of pulses which do not employ cycle skipping.

FIG. 31 is a flow chart of a VSPL control loop method according to one embodiment of the present invention.

FIG. 32 shows the relationship between time and the coil current of a switching power converter wherein a synchronous regulator FET pulse is longer than optimal.

FIG. 33 shows the relationship between time and the coil current of a switching power converter wherein a synchronous regulator FET pulse is shorter than optimal.

FIG. 34 is a flow chart of an example of a method to improve the efficiency of a synchronous switching power converter.

FIG. 35 is a schematic wherein a linear regulator controls the propagation delay of a monitored circuit.

FIG. 36 is an example of a switched-capacitor resistor as used in the circuit of FIG. 35. PRIOR ART.

FIG. 37 is an example of a circuit to provide complementary, non-overlapping clocks as used in the circuit of FIG. 35.

FIG. 38 shows a voltage applied to a temporal process monitor, voltage from a linear regulator, and the resulting signals provided to a linear regulator during a common time period.

FIG. 39 is an enlargement of the signals of FIG. 38 during a shorter time period.

FIG. 40 is a simulation of a monitor and a reference signal during a stable time period.

FIG. 41 is a simulation of a monitor and a reference signal during a recovery time period.

FIG. 42 is an enlargement of a reference signal and a temporal process monitor signal during a common time period wherein the temporal process monitor signal is changing period.

FIG. 43 shows the concepts of a control loop in an analog embodiment of the present invention.

DESCRIPTION OF SOME EMBODIMENTS

| | |
|---|---|
| CCM | Continuous Coil Current Mode |
| Coss | FET output capacitance |
| DCM | Discontinuous Coil Current Mode |
| dX | Change in value of X, where X may be any parameter |
| | such as I, V, Tp, Ts, etc. |
| IC | Integrated circuit |
| Icoil | Coil current |
| TCS | Temporal Control Signal |
| Tdbh | TCS period dead band maximum value |
| Tdbl | TCS period dead band minimum value |
| Tdb | TCS period dead band width; equals (Tdbh − Tdbl) |
| PFM | Pulse Frequency Modulation |
| Ttar | TCS period target value |
| Ttcs | Period of the TCS |
| P_{TCSN} | Period of next TCS time cycle |
| LTtcs_{N} | Period of last (previous) TCS time cycle |
| Tp, tp | Time period during which a control (“high side”) FET |
| | is turned on. |
| TPC | Temporal power converter |
| Tpd | Propagation delay |
| TPM | Temporal Process Monitor |
| Ts, ts | Time period during which a synchronizing (“low side”) FET |
| | is turned on, or during which a corresponding diode conducts. |
| Tx | A digital time value corresponding to a variable Px. |
| VdbhP | Instant voltage Vo corresponding to Pdbh |
| VdblP | Instant voltage Vo corresponding to Pdbl |
| VdbP | Instant voltage Vo corresponding to P_{DB}; equals |
| | (VdbhP − VbdlP) |
| Vo | Output voltage of a power supply |
| VtarP | Instant voltage Vo corresponding to Ttar |

The embodiments described in this section illustrate but do not limit the invention. The invention is not limited to any particular circuitry, software, voltage, current values, power supply type, frequency, semiconductor process, time, or other parameters.

### Section 1—Overview

The present invention regulates the propagation delay of a digital circuit. The propagation delay of the circuit is continuously monitored and compared to a predetermined reference value. The output voltage of a power supply is controlled to maintain the propagation delay within a prescribed range. Some embodiments quantize a signal representative of the propagation delay, the quantized value used by a control loop to control the representative signal to within the limits of any quantization error and the power supply resolution. Some embodiments use an analog technique to control the power supply output voltage in response to a difference between the representative signal and a reference signal. In some embodiments the propagation delay of a single monitored circuit is regulated, whereas other embodiments monitor the propagation delay of a plurality of circuits and control a common power supply such that the maximum propagation delay of all monitored circuits is less than a predetermined maximum.

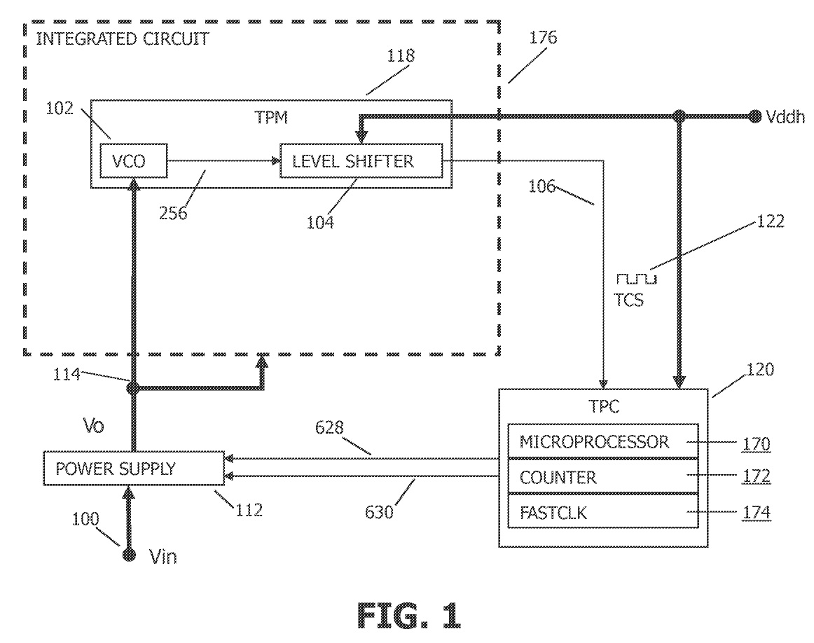

Referring to FIG. 1, a “Temporal Process Monitor” (TPM) 118 associated with a clocked product is placed in the power supply distribution circuit of the clocked product. For the purpose of illustration, the description herein will disclose one embodiment of the present invention wherein the TPM is incorporated into an integrated circuit (IC). One skilled in the art will recognize that the invention can be practiced using other products comprising digital logic. The TPM 118 provides a “Temporal Control Signal” (TCS) 122 on a line 106 to a “Temporal Power Converter” (TPC) 120 wherein the period of the TCS 122 corresponds to a performance parameter of the TPM 118. In one embodiment the period of the TCS 122 is responsive to the voltage applied to the TPM 118. The TPC 120 measures a parameter of the TCS 122, for example its period, and compares the value of the parameter to a predetermined value. The TPC 120 controls a power supply 112, the output voltage “Vo” of which at terminal 114 is provided to the TPM 118 and to the integrated circuit within which the TPM 118 is located. The TCS 122 is responsive to the voltage V0 supplied to the TPM 118 and the integrated circuit. The TPC 120 controls the power supply 112 such that the parameter of interest of the TCS 122 is approximately the same as the predetermined value.

The power supply 112 may be a switching power converter of a buck, boost, or buck/boost topology of the synchronous or non-synchronous type. In some embodiments the power supply 112 is a regulator with a set point controlled by a DAC, the DAC controlled by the TPC 120. In one embodiment the power supply 112 and the TPC 120 are replaced by a linear regulator, configured to control the parameter of interest of the TCS 122 relative to a reference parameter.

The partitioning of the system is arbitrary. The TPM 118 is formed within the integrated circuit. In the embodiment exemplified by FIG. 1 the TPC 120 is an external device which receives the TCS 122 but is not otherwise physically connected with the integrated circuit. With proper level shifting (either in the TPM 118 or the TPC 120) the TPC 120 may have a different operating voltage than that of the integrated circuit/TPM 118. In another embodiment the TPC 120 is located within the integrated circuit. Other partitionings may be used to practice the invention.

In some embodiments the TPM 118 comprises a VCO 102 and a level shifter 104. The VCO 102, being manufactured within the integrated circuit, is therefore influenced by the same factors such as supply voltage, temperature, and manufacturing parameters as is the integrated circuit. The clock output signal of the VCO 102 on line 256 is conditioned by a level shifter 104 to square up oscillation signals from the VCO 102 and to level shift the oscillation signals such that the output signal from the level shifter 104 is an approximately square wave TCS 122 with a voltage swing suitable to drive the TPC 120, for example zero to 2.5 volts.

Some embodiments of the TPC 120 include a microprocessor and means for evaluating the parameter of interest of the TCS 122, providing a response in accordance with a microprocessor program. The microprocessor program may provide any of several control strategies. In one embodiment the TPC 120 includes a time base “FASTCLK” 174 that is faster, for example one hundred times faster, than the frequency of the TCS 122 signal. FASTCLK clocks a counter 172 within the TPC 120 wherein the counter 172 begins counting when an edge of the TCS 122 is received by the TPC 120. The value of the counter 172 is saved in memory when a next second edge of the TCS 122 is received (defining the period of the TCS 122 signal), then the counter 172 is reset and begins counting during the period of the instant TCS 122 signal, thereby continuously repeating the process of counting the number of cycles of FASTCLK during each period of the TCS 122 and saving each result in memory. In some embodiments the counter 172 comprises two counters, each clocked by the signal FASTCLK. One counter begins counting on a rising edge of the TCS 122 and continues until the next rising edge, defining a period of the TCS 122, while the other counter begins counting on a falling edge of the TCS 122 and continues to count cycles of the signal FASTCLK until the next falling edge, defining another period of the TCS 122. Using two counters provides for a more current measurement of the period of the TCS 122 to be available when the TCS 122 period measurement is needed by the control logic. In another embodiment, wherein the TPM 118 provides a TCS 122 that has a fifty percent duty cycle, the period of the TCS 122 is determined by measuring the most current half cycle.

The TPC 120 compares the most recent value of the count of the FASTCLK 174 cycles that was saved into memory to a predetermined value, the predetermined value corresponding to a target for the period of the TCS 122. The TPC 120 controls the power supply 112 in response to the comparison of the count of the FASTCLK 174 cycles to the predetermined value. For example, if the period of the TCS 122 is greater than that of the predetermined period (that is, the count of FASTCLK 174 cycles is greater than the predetermined value) the TPC 120 controls the power supply 112 to increase the power supply 112 output voltage V0. The increase in voltage V0 increases the frequency of oscillation of the VCO 102, thereby reducing the period of the TCS 122.

Thus a control loop is formed wherein the period of oscillation of the TPM 118 is controlled within a certain range, thereby controlling the propagation delay of the integrated circuit monitored by the TPM 118. The result is performance by the integrated circuit that is relatively insensitive to variations in such factors as temperature, manufacturing processing parameters, and any other factors which may affect propagation delay and, thereby, performance. Another result is lower power consumption by the integrated circuit in certain operational conditions. In some embodiments the TPC 120 is responsive to the TCS 122 parameter of interest using analog circuits without a processor/program.

### Section 2—Temporal Process Monitors

A Temporal Process Monitor (TPM) 118 monitors the propagation delay of a digital device. The TPM 118 is placed within and manufactured in common with the monitored device. The TPM provides a signal corresponding to the propagation delay of the monitored circuit.

Three embodiments of a TPM 118 are disclosed. In one embodiment, one TPM 118 monitors one device and the TPM 118 provides a signal corresponding to the propagation delay of the device to the Temporal Power Converter (TPC). The TPC 120 responsively controls the power applied to the monitored device. In another embodiment, one TPM 118 is located within each of a plurality of devices and a signal corresponding to the slowest propagation delay amongst all of the monitored devices is provided to the TPC 120. The TPC 120 responsively controls the power provided in common to all of the monitored devices in response to the signal corresponding to the slowest monitored device. Finally, in one embodiment a plurality of TPMs are located at various locations in a single device, each in a section of interest of the device. A signal corresponding to the individual TPM 118 sensing the slowest propagation delay is provided to the TPC 120. The TPC 120 responsively controls the power provided to the monitored device in response to the signal corresponding to the slowest monitored section of the device.

### Section 2.1—One Temporal Process Monitor in One Monitored Device

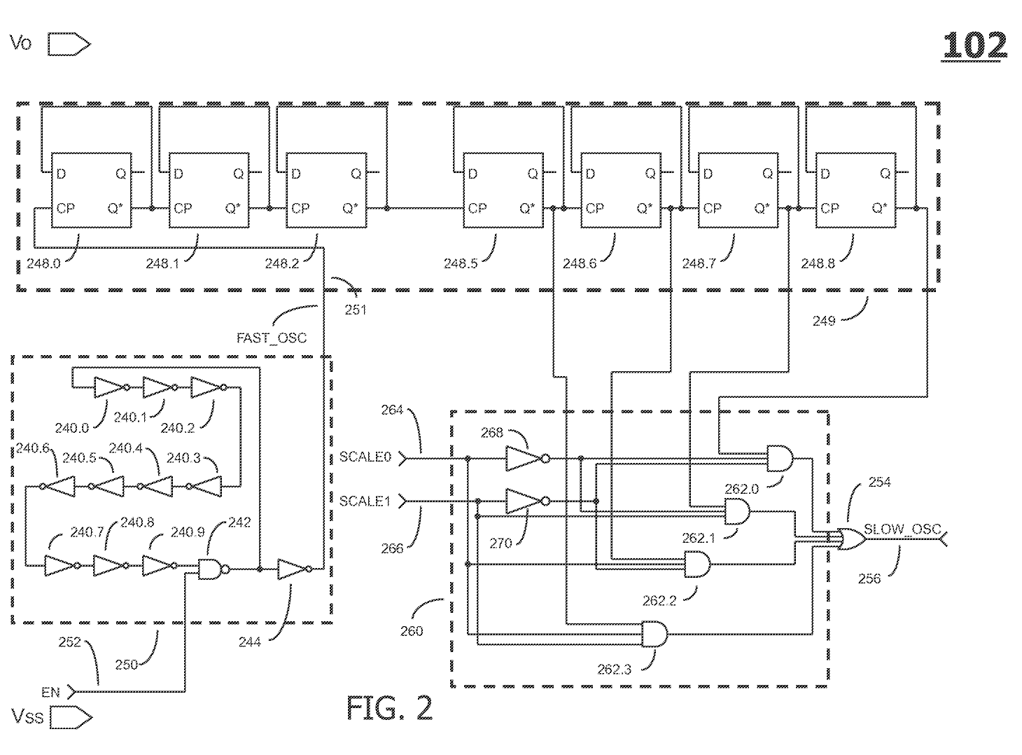

FIG. 2 is an example of one embodiment of a VCO which may be used for the VCO 102 within the TPM 118. In the example of FIG. 2, the VCO 102 comprises a ring oscillator 250, a divider 249, and a scaler 260. The ring oscillator 250 generates a high frequency signal FAST_OSC. The signal FAST_OSC is divided by the divider 249. The scaler 260 selects a certain divisor value of the divider 249. The VCO 102 output signal, SLOW_OSC, is a version of the signal FAST_OSC.

A ring oscillator is formed from elements representative of the digital circuitry of the monitored integrated circuit. In the example of FIG. 2, ring oscillator 250 is formed by an odd number of inverting elements such as inverters 240.0 through 240.9 plus a NAND gate 242. The NAND gate 242 may have one terminal tied HIGH to provide continuous operation, or in one embodiment the terminal is connected to an enable signal “EN” on a line 252, providing means for disabling the ring oscillator 250. In one embodiment the EN signal is held low during a power up condition until a certain minimum voltage is attained. The ring oscillator 250 output signal is isolated and strengthened by a buffer 244. The ring oscillator 250 output signal comprises an oscillation signal “FAST_OSC” on line 251. The period of the signal FAST_OSC is directly related to the sum of the propagation delays of the inverting elements forming the ring oscillator 250.

The ring oscillator 250 is representative of the digital circuitry of the integrated circuit within which the ring oscillator 250 is placed, the ring oscillator 250 frequency of oscillation thereby being affected by the same fabrication process parameters, manufacturing variations, temperature, power supply voltage and any other factors affecting propagation delay as is similar circuitry within the integrated circuit. The ring oscillator 250 frequency of oscillation corresponds to the accumulated propagation delays (Tpd) of the inverting elements forming the ring oscillator 250. Thus, controlling the frequency of oscillation of the ring oscillator 250 also controls the Tpd of the inverting elements comprising the ring oscillator 250, as well as the Tpd of similar digital elements comprising the integrated circuit.

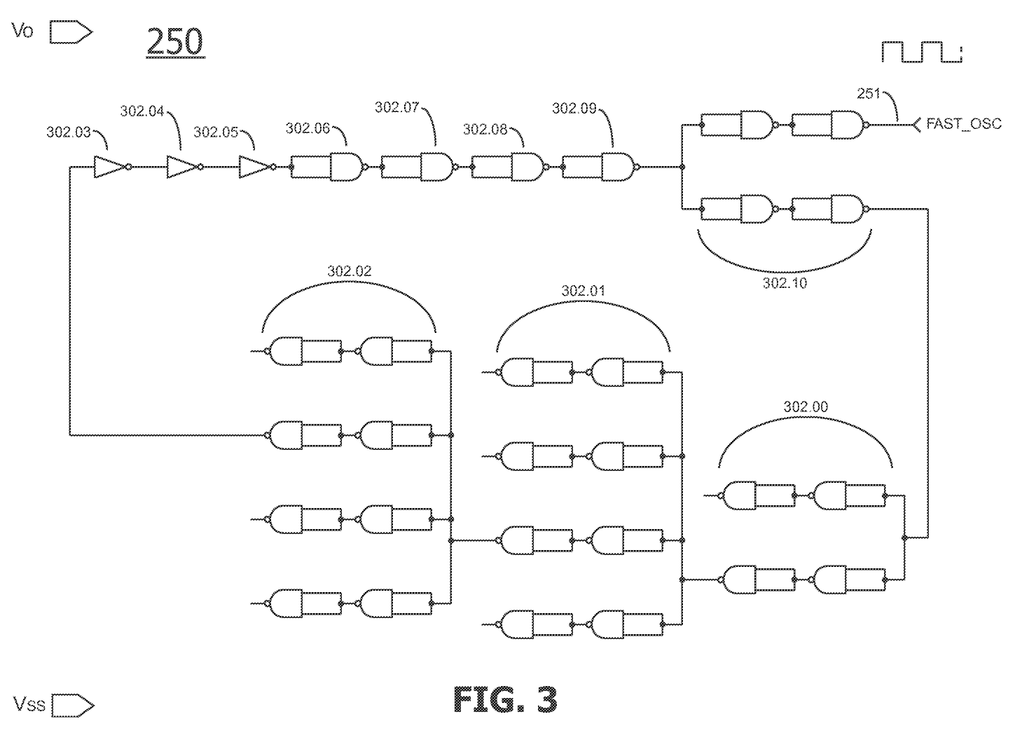

In some embodiments the ring oscillator 250 is formed from inverting elements representative of certain corresponding elements of interest in the monitored product. FIG. 3 is an example ring oscillator 250 comprising inverter stages 302.00 through 302.10, wherein each element is provided supply voltage V0. Some elements have more or less fan out (loading) than others. The designer of an integrated circuit to be monitored in accordance with the present invention provides an inverter set configuration that is representative of the target integrated circuit critical circuit(s). In some embodiments the elements of the ring oscillator 250 are selected to correspond to a specific circuit element of interest. For example, a ring oscillator may be formed from sense amplifiers for the RAM, ROM, EEPROM or other memory elements of the integrated circuit. In an embodiment wherein the ring oscillator 250 comprises ROM memory sense amplifiers, the TPM 118 is placed near the ROM section of the integrated circuit, thereby experiencing manufacturing, temperature, and voltage conditions closely approximating that of the ROM section of the integrated circuit.

In one embodiment (referring again to FIG. 2), the VCO 102 further comprises a divider 249, for example the D flip-flops 248.0 through 248.8, to divide down the FAST_OSC signal frequency. In the example shown, nine D flip-flops are configured to toggle on the rising edge of their clock inputs, thereby dividing the frequency of the FAST_OSC signal by 2̂9 (512d). Scaling down the signal FAST_OSC may reduce the area required on the integrated circuit to implement the VCO 102 function.

In one embodiment the number of dividing stages of divider 249 is fixed. In some embodiments the number of dividing stages is modified during operation. For example, the scaler 260 shown in FIG. 2 includes a two-bit control word SCALE[1:0] on a bus comprising two lines 264, 266. For this example the LSB of control word SCALE[1:0] is denominated SCALE[0] and the MSB is denominated SCALE[1]. The output signal from the scaler 260 comprises the Q*signal from any one of the last four stages of the divider 249 as selected by SCALE[1:0], the four output signals from AND gates 262.0, 262.1, 262.2, and 262.3 being OR'd together by OR gate 254. Four possible division scenarios are detailed in Table 2.

TABLE 2
Scale Factors Resulting From Various Values of SCALE[1:0]

| | AND | AND | AND | AND | Dividing | |
|---|---|---|---|---|---|---|
| SCALE[1:0] | 262.3 | 262.2 | 262.1 | 262.0 | Stages | Divisor |
| 00 | 0 | 0 | 0 | 1 | 9 | 512 |
| 01 | 0 | 1 | 0 | 0 | 7 | 128 |
| 10 | 0 | 0 | 1 | 0 | 8 | 256 |
| 11 | 1 | 0 | 0 | 0 | 6 | 64 |

For example, for SCALE[1:0]=10b, only AND 262.1 will be enabled. AND 262.1 passes the toggling output signal of the eighth D flip-flop 248.7, providing an output signal SLOW_OSC on line 256, which has a frequency equal to the FAST_OSC signal frequency divided by 256.

The ring oscillator 250, divider 249, and scaler 260 provide the signal SLOW_OSC on line 256. The TCS 122 has the same period as the signal SLOW_OSC. In one embodiment the signal SLOW_OSC has a frequency of approximately 1 MHz with an impressed voltage V0 of 1.4 volts and SCALE[1:0]=00b. For SCALE[1:0]=00b, the divisor is 512d, therefore for a SLOW_OSC frequency of one MHz we know that FAST_OSC needs to be approximately 512 MHz; a period of 1.95 nSeconds.

The example ring oscillator 250 of FIG. 2 has eleven inversion stages; therefore each is designed for a propagation delay (Tpd) of 177.6 pSeconds, calculated by 1.95 nSeconds divided by eleven. The specific design of the inverting elements to provide a Tpd of 177.6 pSeconds depends upon the design rules, wafer fabrication process, and anticipated operating conditions of the integrated circuit. If the integrated circuit requires inverters with a different Tpd, the design of the divider 249, scaler 260, and/or the (odd) number of inverters in the ring oscillator 250 can be changed to provide the signal SLOW_OSC at the target of 1 Mhz. The voltage V0 does not affect the timing of the divider 249 or the scaler 260 (assuming the logic elements used have been designed for nominal operation).

The TPC 120 (FIG. 1) has no knowledge of the number of stages of the divider 249 which are dividing the ring oscillator 250 signal FAST_OSC to provide the signal SLOW_OSC. The TPC 120 strictly compares the period of the resulting TCS 122 (TCS 122 has a period identical to the period of SLOW_OSC) to the predetermined period. Thus the period of TCS 122 may be modified to control the power provided by the power supply as controlled by the TPC 120. Consider an example wherein the control word SCALE[1:0] is changed from 00b to 10b. Per Table 2, the divisor becomes 256d from 512d, thereby providing a TCS 122 to the TPC 120 with a period that is half as long as before the change in divisor. The TPC 120 responds with commands to the power supply 112 to lower the voltage V0 so that the period of the ring oscillator signal FAST_OSC increases as does the period of the TCS 122, until the voltage V0 provides for a TCS 122 period which is again approximately equal to the predetermined period.

By changing the value of the divisor the power provided to and the performance derived from the monitored circuit may be dynamically changed. In one embodiment the bus for the control word SCALE[1:0] is connected external to the monitored circuit, allowing a host, another IC, or other controllers to command a change in the monitored circuit. In some embodiments SCALE[1:0] is ccontrolled by the monitored circuit itself, providing means to put itself into certain modes, for example low power or burst modes.

In another embodiment the scaler 260 is a reloadable counter which counts the cycles of FAST_OSC. The overflow or underflow signal of the counter toggles the SLOW_OSC signal with a period according to the reload value of the counter. One skilled in the art will know of other means for selectively dividing the FAST_OSC signal frequency, thereby providing means for controlling the performance and power consumption of the integrated circuit within which the TPM 118 is instantiated.

The OR gate 254 (FIG. 2) receives the output signal of the scaler 260 to drive the signal SLOW_OSC on line 256. The OR gate 254 also provides buffering. If no scaler 260 is employed in a particular implementation a buffer is substituted for the OR gate 254. The lead carrying the divided FAST_OSC signal is connected to the buffer input lead.

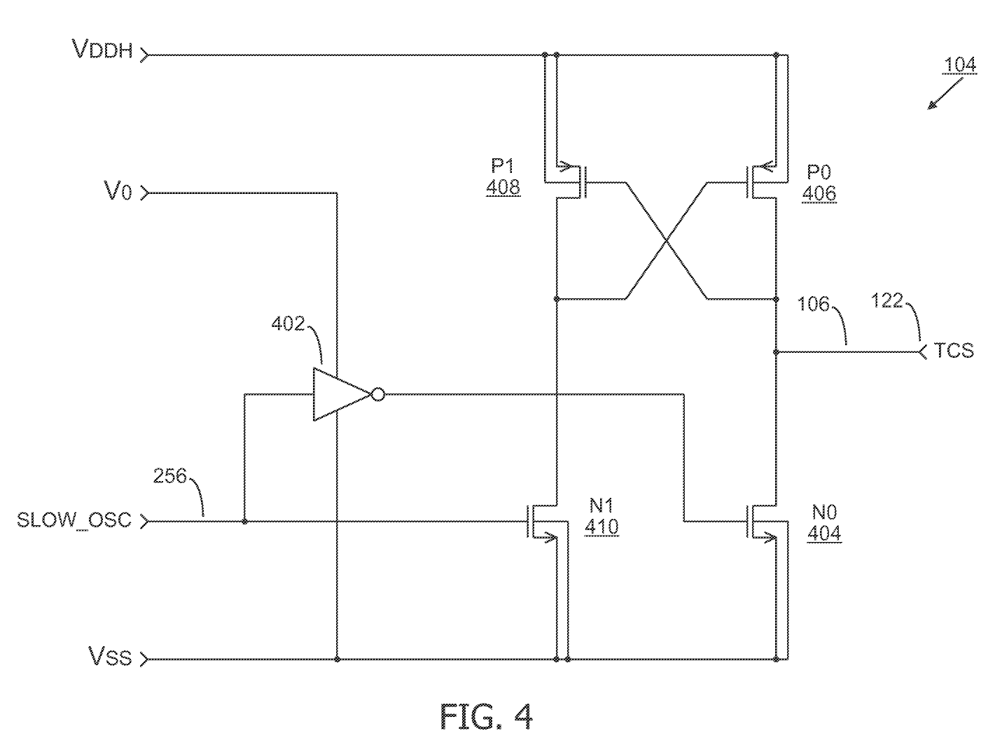

The output signal SLOW_OSC is a reasonably square waveform, switching between ground and Vo. The minimum high output voltage of SLOW_OSC may be less than the minimum logical high input voltage required by the TPC 120. Accordingly, in some embodiments the VCO 102 output signal SLOW_OSC is provided on the line 256 to a level shifter 104. The circuitry of level shifter 104 is shown in FIG. 4. The signal SLOW_OSC is provided to an inverter 402. The output signal of the inverter 402 is applied to the gate of the NMOS pull down transistor N0 404 while the noninverted signal SLOW_OSC is provided to the gate of the other NMOS pull down N1 410. This insures that only one of N0 and N1 will be turned on at any time. The sources of PMOS transistors P1 408 and P0 406 are tied to the voltage Vddh. The gates of P1 408 and P0 406 are cross connected to the drains of P0 406 and P1 408, respectively. The drain of P0 406 is connected to line 106 which carries TCS 122. The cross-connected gates of P0 406 and P1 408 provide the gain that assures that the TCS 122, when high, swings to the positive rail.

When the SLOW_OSC is high on the line 256, N1 410 turns ON, which causes the gate of P0 406 to go to ground (Vgs<0) turning on pull up P0 406, providing a high voltage level Vddh on line 106. Correspondingly, N0 404 is OFF, and the voltage Vddh from line 106 gives P1 408 a Vgs of zero volts; thus P1 408 is OFF.

When the signal SLOW_OSC is low (=VSS), N0 404 is turned ON, pulling line 106 to system ground VSS. The low voltage on line 106 gives P1 408 a negative Vgs, thus P1 408 is turned on. N1 410 is OFF, thus the voltage on the node between N1 410 and P1 408 will be at Vddh. Thus P0 406 has Vgs=0, turning it off. As is seen, then the TCS 122 follows SLOW_OSC but with voltage swings between Vss and Vddh.

The circuit of FIG. 4 thus forms a regenerative circuit whose input signal on lead 256 responds to a voltage swing (of the SLOW_OSC signal) wherein the high level can be almost as low as the threshold voltage of the NMOS transistors N0 404 and N1 410 and still provide an output signal that swings from ground to the higher voltage Vddh.

### Section 2.2—Temporal Process Monitors in a Plurality of Devices

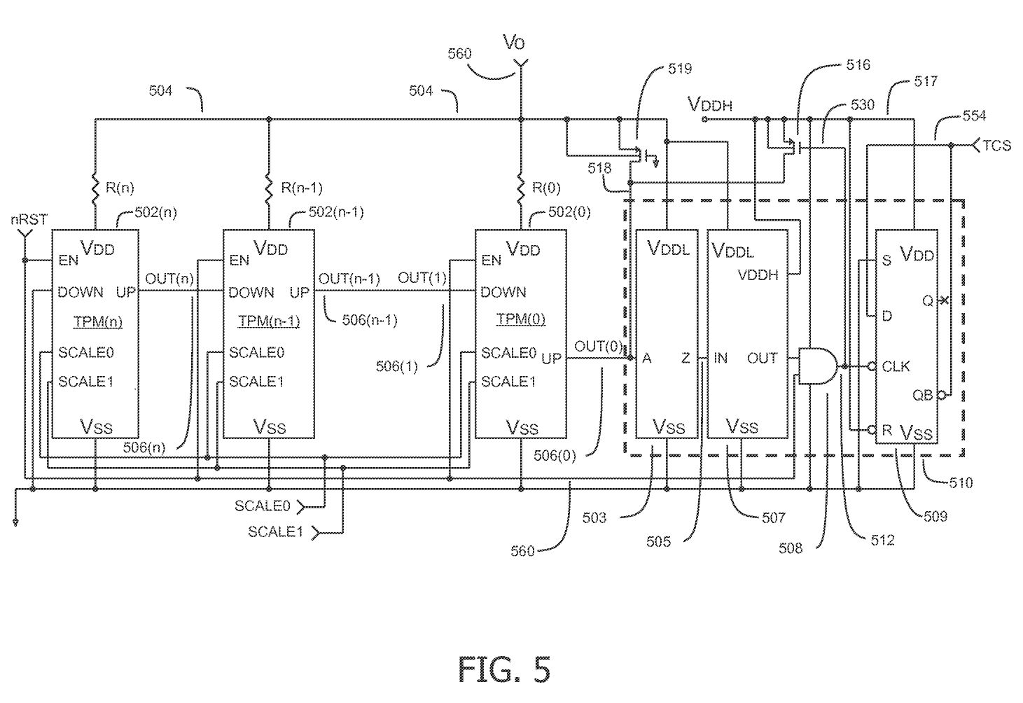

In the embodiment described above, one TPM 118 is located in one monitored device and the TCS 122 is provided to the TPC 120. In another embodiment a plurality of clocked components, for example integrated circuits have a TPM 118 located within and manufactured in common with the digital section of each the components. The plurality of components, all powered by a common power supply, have their corresponding TCSs interconnected, forming a common TCS 122 to be provided to an interface circuit, wherein the completion of one cycle of the common TCS represents the longest individual TCS provided by any of the components so connected. A TPM 118, as shown in FIG. 1, may include a level shifter 104. For the purpose of this discussion the TPMs of FIG. 5 either do not require level shifting or it is not shown. Thus the term “TPM” here refers to a VCO similar to the VCO 102 of FIG. 2, the VCO providing a TCS 122, whether or not level shifted.

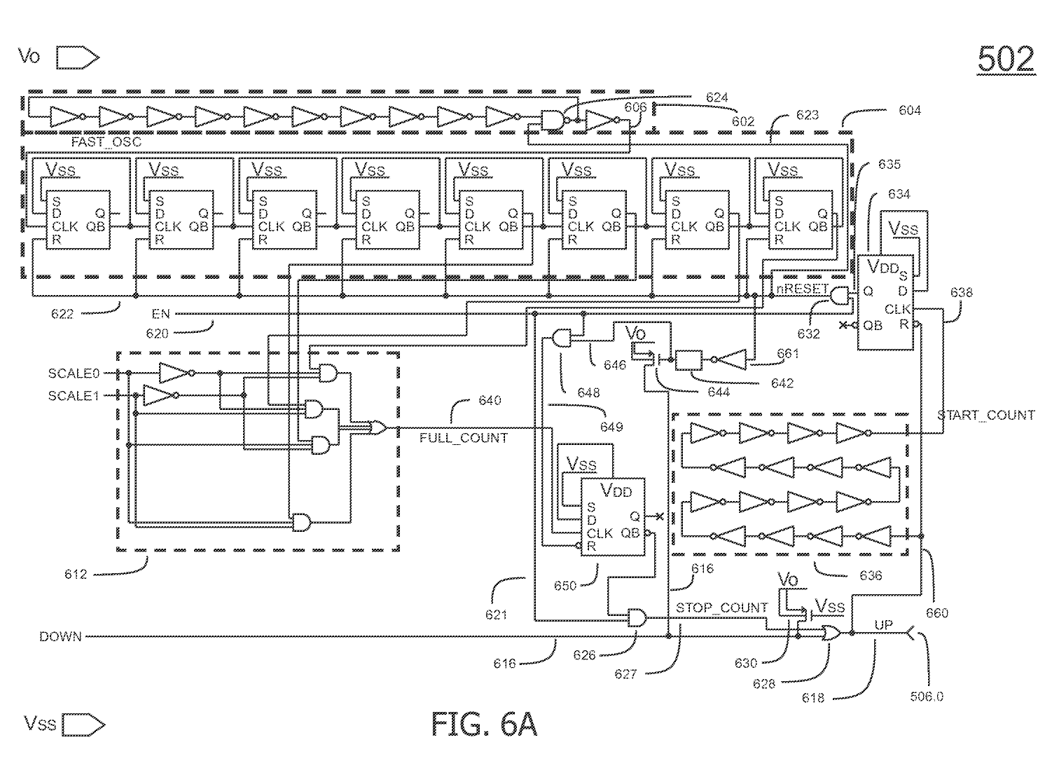

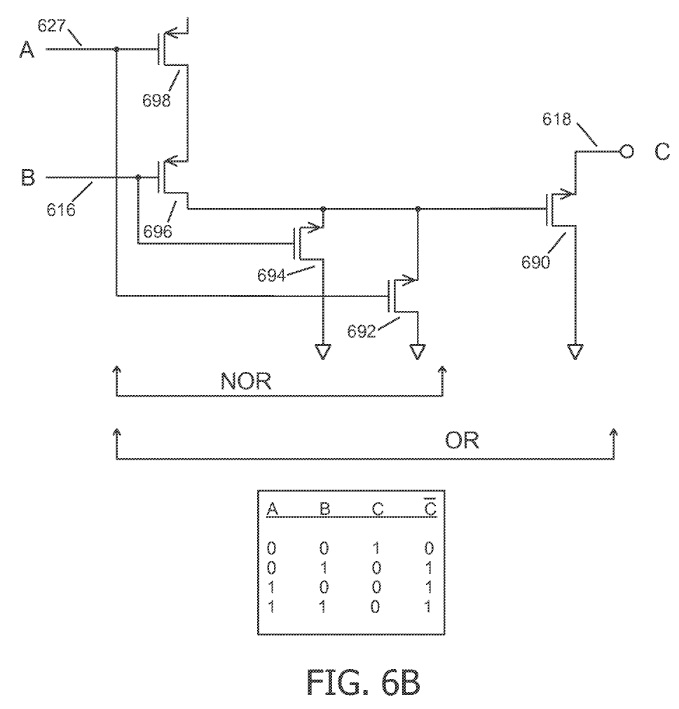

FIG. 5 is an embodiment wherein a plurality of “n” TPMs 502, shown as TPM(0) 502(0) through TPM(n) 502(n), are connected by lines 506(1) through 506(n) to form a daisy chain. The “n” TPMs are located in “n” individual circuits. FIG. 6A is an individual TPM 502 from FIG. 5. TPM 502 is similar to TPM 118 described in FIG. 2, with the addition of control circuitry. The control circuitry provides for interaction between all “n” connected TPMs 502. All of the TPMs 502 are provided power from the same power supply 112 output voltage. The TPM(0) 502(0) signal OUT(0) is connected by line 506(0) to an input terminal A of an interface circuit 510. Interface circuit 510 comprises a negative one-shot 503, a level shifter 507, an AND gate 508, and a flip-flop 509. The interface circuit 510 provides a TCS 122 on line 554. The interface circuit 510 can be either external to the TPC 120 or incorporated into the TPC 120. The TPC 120 evaluates the time period of the TCS 122 as previously disclosed and, responsive to the period of the TCS 122, controls the voltage V0 provided to terminal 560. As previously described, voltage V0 is also provided to each circuit within which a TPM 502 is located (not shown).

Still looking to FIG. 5, each TPM is shown as having a dropping resistor (R(0) through R(n)), the dropping resistors representing a resistive or reactive part of the load which may cause each TPM to have a slightly different voltage impressed upon it. The dropping resistors are not elements provided by the instant invention, but are used for simulation (and this discussion) purposes to represent such differences amongst monitored circuits as different power line lengths, different interconnect resistances, processing parameters (for example sheet resistance, metal width, contact resistance), and design rules.

FIG. 6A illustrates an embodiment of one TPM element amongst a plurality of TPM elements such as shown in FIG. 5. The TPM of FIG. 6A is very similar to the VCO 102 of FIG. 2. The differences will be discussed here. The scaler 612, corresponding to the scaler 260 of FIG. 2, drives signal FULL_COUNT onto line 640. Signal FULL_COUNT is a representation of the propagation delay of the individual inverting elements comprising the ring oscillator block 602.

The divider 604 has one less flip-flop than that of the corresponding divider 249 (FIG. 2). All other things being equal, FULL_COUNT will have a period of approximately half the period of SLOW_OSC on line 256. As explained later, the interface 510 (FIG. 5) has an additional flip flop, which effects a divide by two, providing a final TCS 122 with the same period as previously discussed, for example one microsecond.

As is described throughout this disclosure, all TCSs are generated with a target period of one microsecond. All TCSs having a common target period, each responsive to the propagation delay of its respective TPM, may make system level control more efficient and provide an interface standardization that is economically advantageous. The invention may be practiced with any arbitrarily chosen TCS 122 period providing adequate information bandwidth (i.e., fast enough to allow a transient response that is adequate for the instant design) for a given component and TPC 120 combination. When a plurality of TPMs are provided power by a common power supply 112 output, the period of the TCS from each TPM has the same target period.

A specific TPM circuit is configured to provide an output signal FULL_COUNT with the same target period as that of the other interconnected TPMs, but may do so with different elements. For example, the ring oscillator 602 could have fewer inverters and additional flip flops in the divider 604 to provide the same 500 nSec period for FULL_COUNT. If a scaler 612 is employed, changes in the divisor are coordinated by providing the control word SCALE[1:0] (See discussion of Table 2) external to all TPMs in parallel. Alternatively, a command may be given to each monitored circuit (via an I2C bus, USB, RS-232, RF or by any other communications means) for action. The overriding requirement is that each FULL_COUNT signal so generated be targeted for the same period, for example 500 nanoseconds.

To understand the operation wherein a plurality of TPMs are connected, we first look at a single TPM in accordance with this embodiment. Consider the TPM shown in FIG. 6A. For the purpose of this discussion, we assume this is the only TPM connected to the interface 510, which is to say the TPM is TPM(0) 502(0). During power up (or reset) of the circuit being monitored by the TPM 502(0) the signal EN (a version of the circuit RESET signal) on line 620 is held low. The signal EN is a low input signal to one terminal of a two-input AND gate 632. The AND gate 632 drives the signal nRESET on line 622 low. nRESET holds the flip flops in divider 604 in reset. nRESET is also connected to a two-input NAND gate 624 by lines 622 and 623, the NAND 624 gate providing one of the inverters of the ring oscillator 602. With nRESET low, the output signal of the NAND gate 624 stays high, and the ring oscillator 602 does not oscillate. The signal EN is also connected to a two-input AND gate 626 by lines 620 and 621. The output signal of AND gate 626 (the signal STOP_COUNT) is low and is connected to a two-input OR gate 628 by line 627. OR gate 628 is an open-drain type, the circuitry of which is shown in FIG. 6B. The other input signal to OR gate 628 is the signal DOWN on line 616. For a single TPM system (or, as will be seen, for the TPM farthest from the interface block 510 in a daisy chain arrangement), the signal DOWN is tied to ground (Vss). With both input signal s on input leads 616 and 627 low, the OR gate 628 drives the signal UP low onto lead 618. The low signal UP is connected to the nR input lead of a flip-flop 634 by line 660, holding the flip-flop 634 in reset. An even number of inverters in a delay block 636 (operation described later) will propagate the signal UP to the signal START_COUNT. The signal UP is held until the signal START_COUNT is also low.

The EN signal on line 620 is also connected to an input terminal of a two-input AND gate 648. The AND gate 648 drives a low signal onto line 649, connected to the nR lead of flip-flop 650, holding flip flop 650 in reset. Looking at FIG. 5, a negative one-shot 503 output signal on line 505 is high and is connected to an input lead of a level shifter 507 (operation of these will be discussed later). The level shifter 507 output signal is high and is connected to an input terminal of a two-input AND gate 508. The other input lead 560 to AND gate 508 carries a signal which is a version of the same integrated circuit reset signal which has been described as driving the signal EN such that the input signal on lead 560 is low when the system reset signal is active low. The AND gate output signal on line 512 is therefore low. While the signal EN is held low, then, the output signal UP is low and nothing in the TPM 502(0) is toggling.

Returning to FIG. 6A, when the circuit reset signal nRST (see FIG. 5, line 560) is released, the EN signal on line 620 goes high as does nRST. The output signal from AND gate 508 (FIG. 5) goes high and thus drives a high signal to the gate terminal of a PFET pull up 516 on line 530, turning the PFET 516 off. At approximately the same time, the high signal on the EN port of the TPM (FIG. 6A) and the high signal on the QB output lead of flip-flop 650 (which was reset by the initial low on EN, making its Q output signal low and its QB output signal high) drive the signal STOP_COUNT on line 627 high. The high voltage on line 627 turns off the pull-down path in open-drain OR gate 628, regardless of the state of the signal DOWN on line 616. This permits a weak PMOS pull up 519 in FIG. 5 to pull up the output signal of OR 628 (the signal UP on line 618, which is connected to lines 506.0 and 660) thereby releasing the nR input of the flip-flop 634. An even number of inverters in timing delay block 636 drives the signal START_COUNT of the same polarity as the signal UP, after the signal UP propagates through delay block 636. The delay block 636 drives the signal START_COUNT on line 638, which is connected to the CLK input lead of the flip-flop 634 by line 638. The delay block 636 is configured with enough inverters, for example sixteen, to hold the signal START_COUNT low until the flip-flop 634 reset release time specification is satisfied. When the signal START_COUNT on line 638 goes high the Q output signal of the flip-flop 634 drives a high level on line 635, connecting the Q output lead from flip flop 634 to one of the input terminals of the two-input AND gate 632. Both input signals to AND gate 632 are now high, causing AND gate 632 to drive signal nRESET on line 622 high. With nRESET high, the AND gate 624 of the ring oscillator 602 is released to toggle and the divider block 604 is released to count the cycles of the signal FAST_OSC on line 606. The ring oscillator 602 oscillates, and the divider block 604 begins counting the toggling output signal FAST_OSC from the ring oscillator 602 on line 606. Depending upon the values of SCALE0 and SCALE1 (whose operation was discussed earlier), the signal FULL_COUNT on lead 640 toggles at a rate-divided version of the signal FAST_OSC.

The high nRESET signal is also connected to an inverter 661. When the output signal from AND gate 632 goes high, the inverter 661 drives a low signal to the input lead of a negative one shot 642. The negative one shot 642 drives a low pulse to the control gate of a PFET pull up 644, which is connected between Vo and the line 616. For a single TPM system (or the farthest TPM of a daisy chain) the line 616 is tied low. For a multiple TPM system the line 616 carries the signal DOWN. The signal DOWN corresponds to the signal UP from the previous TPM in the daisy chain. For a multiple TPM system the PFET pull up 644 overcomes the low signal of the open drain OR (corresponding to the OR 628) of the previous TPM (see FIG. 5). The pull up effect of PFET 516 (FIG. 5) is to pull lines 618 and 660, thereby to release from reset the flip-flop 634 in each interconnected TPM. As a result each TPM 502 restarts counting toggles of the signal of its oscillator 602 denominated as FAST_OSC on line 606. Of importance, the NFET 690 is a stronger transistor than PFET pullup 630, thereby allowing NFET 690 to pull down the signal on line 618 which is connected to line 616 of the next following TPM. For the last TPM (designated as TMP(0) 502(0) in FIG. 5) NFET 690 is a stronger transistor than PFET pullup 519 but weaker than the combined strength of PFET 519 in parallel with PFET 516.

The negative pulse from the negative one shot 644 also connects to an input terminal of AND gate 648 on line 646. AND gate 648 drives a low signal on line 649 to reset flip-flop 650. The signals on the Q and QB output leads of flip-flop 650 do not change, but flip-flop 650 is now set to retrigger when the signal FULL_COUNT again has a rising edge at the CLK input lead of the flip-flop 650.

The signal STOP_COUNT on line 627 is provided to one input terminal of OR gate 628. The other input signal to the OR gate 628 is the signal DOWN on line 616 which, for a single TPM implementation, or for the first TPM in a series of TPMs, is tied low. When FULL_COUNT is TRUE (high), STOP_COUNT on line 627 goes low. This results in the output signal UP on lead 618 from the OR gate 628 going low if the signal DOWN on lead 616 (the UP signal from the previous TPM identical to, but in series with, the TPM shown in FIG. 6A) is low. If the signal DOWN on lead 616 is not low, then the signal UP on lead 618 cannot go low and remains pulled high by the weak PFET 630. When all leads 616 in all of the TPMs 502 connected in series (FIG. 5) carry a low signal DOWN, which occurs only after the signal FULL_COUNT on lead 640 in each of the TPMs 502 connected in series (shown as TPMs 502(0) to 502(n) in FIG. 5) goes high then all TPMs in series have each provided a measure of the period of the signal from their corresponding oscillator 602 (FIG. 6A).

Thus signal FULL_COUNT on lead 640 goes high to indicate that the temporal process monitor 502 has obtained a measure of the period of the signal from oscillator 602. In the embodiment shown, FULL_COUNT going high represents a measure of 2̂n periods of the signal from oscillator 602, where “n” is the number of stages in divider 604, the output signals from which are changed by the signal from oscillator 602 before the signal FULL_COUNT on lead 640 goes high. The number of stages in divider 604, the output signals of which are changed before the signal FULL_COUNT goes high is determined by the scale signals SCALE0 and SCALE1 (FIG. 6A). In the structure of FIG. 6A, if these signals are 00, then “n” is 5, if 01 then “n” is 6, if 10 then “n” is 7j, and if 11 then “n” is 8.

When signal FULL_COUNT on lead 640 goes high, the signal on output lead QB from flip-flop 650 goes low, driving the signal STOP_COUNT on lead 627 low. This forces the signal UP on output lead 618 from OR gate 628 to go low.

FIG. 6B shows the circuitry of OR gate 628. In FIG. 6B, series-connected P-channel transistors 696 and 698 are connected between Vdd and two parallel-connected N-channel transistors 692 and 694. The output signal from OR gate 628 on lead 618 is taken from the drains of parallel-connected N-channel transistors 692 and 694. Lead 618 is output from N-channel transistor 690 which, when on (driven by a high signal on its gate) pulls the voltage on lead 618 low to ground. When N-channel transistor 690 is off, lead 618 is pulled high by the P-channel FET 630 in the next following TPM.

The OR gate 628 has an open drain output, thus the OR gate 628 can only drive the signal UP low. The OR gate 628 and the pull up 519, both connected to line 618, are such that the pull up 519 is weaker than the output signal of the OR gate 628, allowing the OR gate 628 to drive the signal UP on line 618 to a low level.

We now consider the interaction between two or more TPMs. The nRESET signal of each TPM provided power by a common power supply, which is to say all circuits monitored by the TPMs connected in series to a given interface block 510 input, are released at the same time (discussed later). Each TPM is configured to provide the same target period of the signal FULL_COUNT. The output signal UP from one TPM is the input signal DOWN on line 616 of another TPM such that each TPM has only one UP output lead connected to only one DOWN input lead. The DOWN input lead of the first TPM (the one farthest away from the interface block 510, such as TPM(n)) is tied low. The UP output lead of the TPM(0) is connected to the input lead of the interface block 510. Within each TPM, the OR gate 628 output signal UP on line 618 is pulled up by the weak pull up 630 of the next TPM (or the weak pull up 519 in the case of TPM(0)) until both the signal DOWN on line 616 and the signal STOP_COUNT on line 636 are low, at which time the signal UP on line 618 is driven low. The result is that, since all of the TPMs begin counting at the same time, the output signal UP on line 618 that is provided to the input lead of the interface block 510 (also shown as OUT(0) in FIG. 5) represents the longest period of the FULL_COUNT signals amongst all of the TPMs associated with a common line 618.

OUT(0), which is also the UP signal on line 618 from TPM(0), is connected to the A input lead of the negative one-shot 503 in the interface block 510. The negative one-shot 503 output signal on line 505 is connected to a level shifter 507. The level shifter 507 provides an interface to the AND gate 508 wherein the logical high level from the negative one-shot 503 is a lower voltage than Vddh. For one example of a level shifter, refer to the level shifter of FIG. 4. One skilled in the art will know of various ways to interface the signal OUT(0) to the interface block 510. The level shifter 507 output lead is connected to one input terminal of a two-input AND gate 508. The other input terminal of the AND gate 508 is connected to the nRST signal of the monitored circuits. The signal nRST will hold the output signal from AND gate 508 low until nRST is released. Thereafter the output signal from AND gate 508 on line 512 is responsive to the input terminal connected to the level shifter 507 by line 505.

The output signal from the AND gate 508 is connected to the CLK input lead of a flip-flop 509 by line 512. The flip-flop 509 provides two functions. The output TCS from the flip-flop 509 is twice the period (half the frequency) of the signal OUT(0) from TPM(0), thus providing a TCS 122 on line 554 which is at the typical design frequency of 1 MHz for the example design shown. Secondly, the flip-flop 509 provides an output TCS that is an approximately 50/50 square wave, whereas the signal OUT(0) is not. A TCS that is a 50/50 duty cycle provides the control loop (discussed elsewhere) the option to rely upon half of the TCS period to determine what instant response is required, thereby improving the response time of the control loop.

The output signal from the AND gate 508 on line 512 is also connected to a strong PFET pull up 516. The low-going pulse (responsive to the signal OUT(0)) from the AND gate 508) drives the gate of the pull up transistor 516, connecting the voltage rail Vo on line 517 briefly to the line 518. Line 518 is connected to the line 618 of TPM(0), thus a pulse of positive voltage Vdd of a pulse width determined by the negative one-shot 503 overrides the low signal UP on line 618. The transistor 516 is capable of overdriving the output lead of the OR gate 628 of TPM(0).

### Section 2.3—a Plurality of Temporal Process Monitors within a Given Device

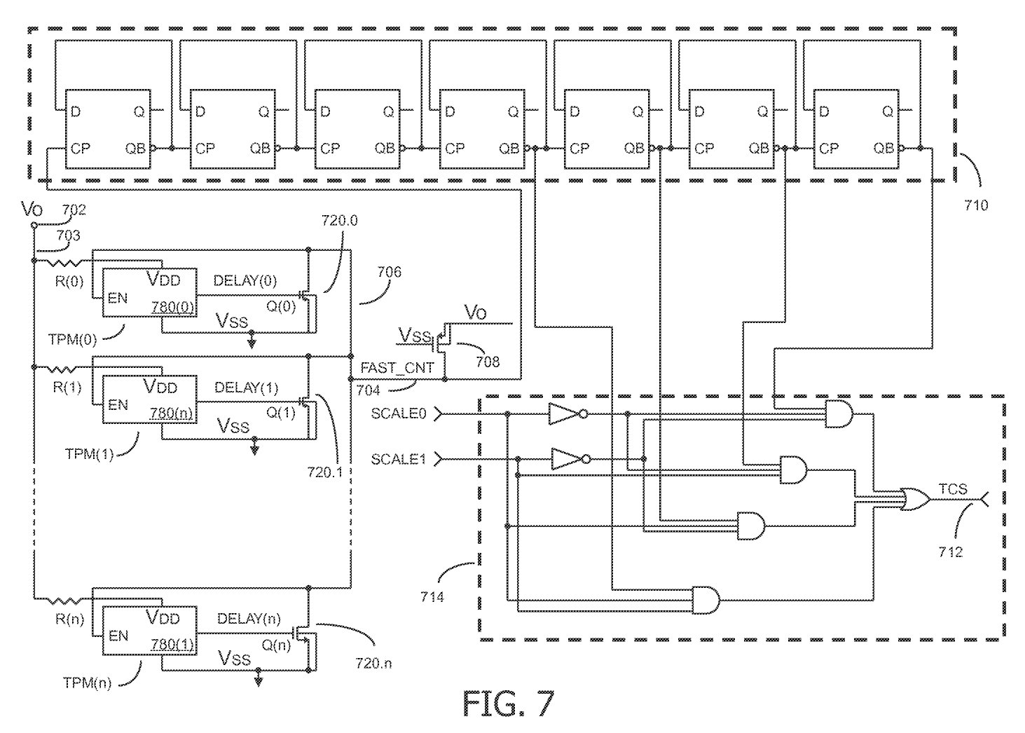

In other embodiments multiple TPMs are incorporated into a single monitored device and a TCS 122, responsive to the worst-case (longest) propagation delay amongst the plurality of TPMs, is provided to the TPC 120. In the circuit of FIG. 7, multiple TPMs (TPM(0) 780(0) through TPM(n) 780(n)) are each located within the same device. The voltage V0 from power supply 112 is provided to the monitored device and to a power line 703 at terminal 702, the power line 703 further connected with each TPM. Each TPM monitors the propagation delay at a different point of interest within the monitored device. For example, one TPM may comprise memory sense amplifiers for its ring oscillator and be physically located near a memory block while another TPM comprises high speed inverters which are representative of a certain operation within the monitored device and is located near the section of the monitored device wherein the operation of interest is performed. In some embodiments the TPMs all comprise the same inverter element types, the TPMs placed at various points of interest of the monitored device to monitor various factors, for example localized heating or the effect of different power line matrix routing lengths. As discussed previously, resistors R(0) through R(n) represent resistive effects that may affect each TPM differently and are shown for the purpose of simulation and this discussion. The voltage V0 is carried by line 703, across “resistor” R(x), to the Vdd input lead of each TPM(x).

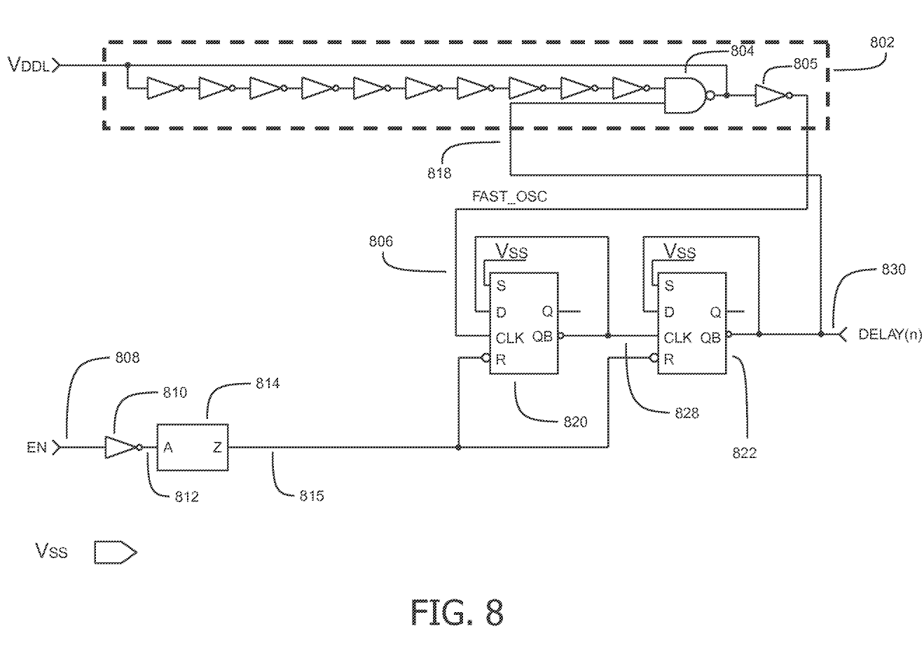

FIG. 8 details one TPM from FIG. 7. The various TPMs may have different inverting elements comprising a ring oscillator 802 but are otherwise the same. Each TPM comprises an even number of inverting elements and a NAND gate forming a ring oscillator 802; a buffer 805; a negative one-shot 814; and a two-bit counter comprising two D flip-flops, 820 and 822. The voltage from Vo on line 703, after any power matrix resistance drop is provided to the ring oscillator 802 on input terminal Vddl. The output lead of NAND 804 is connected to the input lead of a buffer 805. The output signal FAST_OSC of buffer 805 is provided to the CLK input terminal of flip-flop 820 on line 806. The enable signal EN (not associated with the reset signal of the monitored circuit) is carried to an input terminal of an inverter 810 by line 808. The output signal of inverter 810 is provided to the input lead A of a negative one-shot 814. The output signal of negative one-shot 814 is carried by line 815 to the nR input terminals of the D flip-flops 820 and 822.

When the signal EN on line 808 is pulled high by a pull up 708 (FIG. 7) the input signal of negative one-shot 814 is driven low by an inverter 810, producing a logical low pulse at the output lead Z of the one-shot 814. The low signal pulse on line 815 resets the two flip-flops 820, 822 driving the signal DELAY(n) and one of the input signals of the NAND gate 804 high. While the DELAY(n) input signal to a terminal of the NAND gate 804 is low, the output signal of NAND 804 and the other input signal of NAND gate 804 are high. The transition to a high level by the input signal DELAY(n) to the NAND gate 804 drives the NAND gate 804 output signal low and the CLK input signal of flip-flop 820 high.

The QB output signals of both flip-flops 820, 822 are high, so the first falling transition of the NAND gate 804 output signal clocks a high signal onto the D input lead of flip-flop 820. The flip-flop 820 drives a low output signal at the QB output lead. At the next low transition of the output signal of the NAND gate 804, the flip-flop 820 is clocked again and the flip-flop 820 QB output signal toggles to a high, clocking the flip-flop 822 and resulting in a low signal DELAY(n) on the flip-flop 822 QB output lead. Line 818 carries the low signal DELAY(n) to an input lead of the NAND gate 804. The low signal DELAY(n) at an input terminal of NAND 804 prevents NAND 804 output signal from toggling, thus the ring oscillator 802 stop oscillating.

Again looking to FIG. 7, the voltage V0 is provided to the monitored device and to each TPM at terminal 702 by power supply 112. Each TPM element is shown with a dropping resistor (R(0) through R(n)) from the power rail to represent the possibility that the voltage impressed at the physical location of an individual TPM may vary slightly from that of another TPM on the same power rail as previously discussed.

The output signal DELAY of each TPM as described in conjunction with FIG. 8 is further connected to the control gate of an NFET, shown in FIG. 7 as Q(0) 720.0 through Q(n) 720.n. The NFETs 720.x provide open drain output leads connected in parallel to a common line 706. Any of the NFETs 720.x can drive a low signal onto line 706 but not a high signal. The line 706 carries the signal on line 706 to the EN input lead of each TPM. A pull up 708 tries to pull up the signal on line 704, line 704 connected to line 706, but cannot until each TPM has released the drive to the control gate of the TPM's respective NFET 720.x. The NFET 720.x of each TPM is strong enough that just one of them can override the pull up 708 and can hold the signal on line 706 low. The pull up 708 is not strong enough to override any one TPM open drain output 720.x, but is strong enough to pull the signal on line 704 (thereby line 706) to a high state when all TPM output signals are released before the TPMs pull the signal on line 706 down again.

All TPMs begin counting FAST_OSC transitions at the same time; when the signal on line 706 is pulled up by pull up 708. All NFETS 720.x then drive a low signal onto line 706 at the same time. The signal on line 706 stays low until the last, i.e. the slowest, TPM releases its open drain output lead. Thus the signal FAST_CNT on line 704 corresponds to the slowest instant TPM propagation delay.

The toggling signal FAST_CNT is carried by line 704 to the input lead of a counter 710. The counter 710 comprises a number of flip-flops, for example seven. In one embodiment the TPMs (which provide the signal FAST_CNT), the divider 710, and the scaler 714 are configured to provide a TCS 122 on output lead 712 wherein the TCS 122 target period is the same as the other TCSs 122 described elsewhere herein.

Control and operation of the scaler 714, responsive to the control word SCALE[1:0], has been disclosed elsewhere herein and is not repeated. The TCS at terminal 712 is provided to the TPC 120 which, as previously described, controls the power supply 112 to provide the voltage V0 as necessary to maintain the period of the TCS 122 within a predetermined time period, thus controlling the propagation delay of the monitored device.

A large number of TPMs in parallel may result in a large capacitance as seen by the PMOS pull-up 708. The capacitance may result in a slow rise time of the signal FAST_CNT on line 704. A stronger PMOS pull up transistor 708 might prevent an NMOS transistor (Q(0)-Q(n), FIG. 8) with a relatively low gate drive from pulling the signal FAST_CNT low. In one embodiment the PMOS pull up 708 is formed by multiple transistors in parallel. The monitored device enables a number of transistors any one time to match the number of TPMs enabled at the same time.

In some embodiments one or more TPMs configured in accordance with FIG. 7 are located in different devices wherein all of the devices are provided power by the same power supply 112 output voltage. The open drain output lead of each TPM is connected to a common line, the common line connected to a separate interface including a pull up transistor. The interface may be incorporated into the TPC 120. Said differently, this configuration provides for monitoring multiple devices using the embodiment of FIG. 7 and FIG. 8 instead of the embodiment of FIG. 6A and FIG. 8.

### Section 2.4—Dynamic Voltage and Frequency Control Using a Temporal Process Monitor

In a system using a TPM 118, the VCO 102 is an analog of a monitored device. Controlling the voltage applied to the TPM 118 controls the propagation delay of the monitored device, but only inferentially so. Importantly, the monitored device's clock essentially remains fixed (for example, being crystal controlled with little influence of applied voltage), while only the propagation delay of the rest of the monitored device is sensed by the TPM 118 and controlled by the TPC 120 in response to the TCS 122. Thus, voltage is being controlled beneficially, but the clock of the monitored device is not tracking with the instant and varying propagation delay of the rest of the circuit.

In one embodiment of the present invention the VCO 102 is configured to provide a version of its output signal FAST_OSC to the monitored device, the monitored device using the version of the signal FAST_OSC as the clock of the monitored device. For example, looking to FIG. 2, in one embodiment the buffer 244 provides a 512 MHz signal FAST_OSC to the divider block 249 and also to the clock matrix of the monitored device. The monitored device may have control of the control word SCALE[1:0] on lines 264 and 266. The function of the control word SCALE[1:0] was previously described. By changing the value of SCALE[1:0], the period SLOW_OSC is changed, thereby changing the period of the control TCS 122. In turn the voltage V0, provided by the power supply 112 at terminal 114, will be changed by the TPC 120 to control the period of TCS 122 (Ttcs) to conform to the predetermined target period Ttar 2100. In response to the change in Vo, FAST_OSC changes, thereby also changing the clock frequency of the monitored device. As a result, the propagation delay and the clock frequency of the monitored device change cooperatively. In some embodiments a slower version of FAST_OSC may be provided to the monitored device by, for example, buffering a Q* output signal from one of the flip-flops within divider block 249. For example, the Q* output signal of flip-flop 248.0 would provide a clock signal of a frequency (FAST_OSC/2).

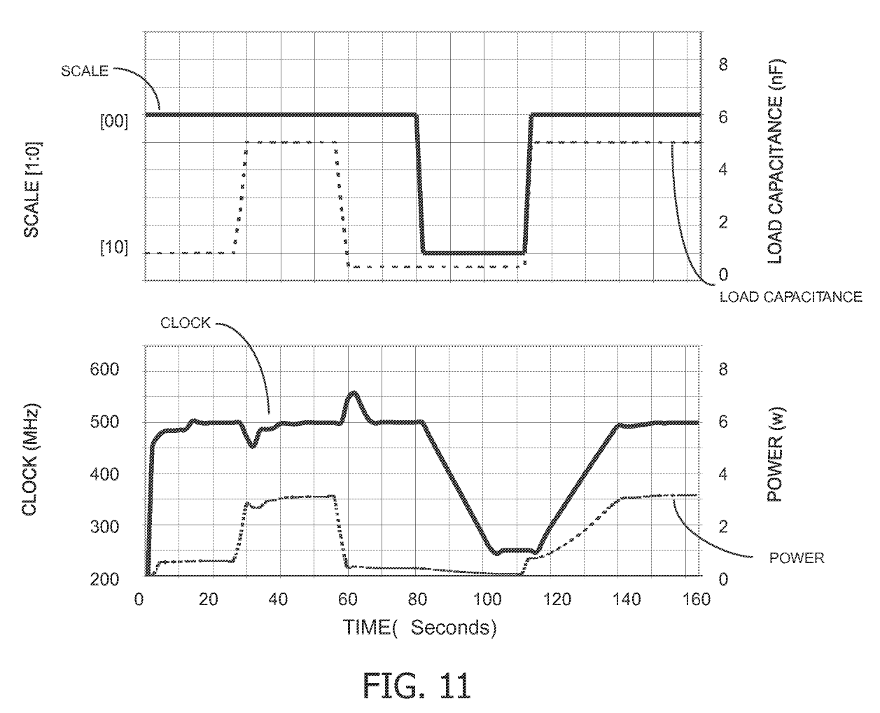

The simulation of FIG. 11 illustrates the result of providing FAST_OSC to the monitored device as its clock. At approximately 20 uSeconds the load increases, causing a brief dip in the clock frequency. The dip in the clock frequency corresponds to the brief increase in the propagation delay of the TPM 118 from which the clock of FIG. 11 is derived. At approximately 55 mSeconds the reverse case is shown as the load decreases.

At 80 mSeconds we see the result of a command, for example from the monitored device, changing the data word SCALE[1:0] provided to the TPM 118. A lower divide-by value causes the period of the TCS 122 to be shorter. In response, the TPC 120 lowers the voltage V0 provided to the TPM 118. The propagation delay of the VCO 102 increases, providing a corresponding decrease in the frequency of the signal FAST_OSC, a version of which is provided to the monitored device as its clock. As shown in FIG. 11, the clock frequency decreases during the time period from approximately 82 mSeconds to 105 mSeconds, then stabilizes. During this period the power also decreases. At approximately 112 mSec both the load and the data word SCALE[1:0] are changed and the clock frequency and power level increase correspondingly.

Changing the clock frequency to the monitored device in concert with the rest of the monitored circuit provides a simple method of power management by monitored devices wherein a complex scheme to coordinate clock and voltage management is not necessary. Additionally, glitches corresponding to sudden changes in clock frequency and/or power levels are diminished and setup and hold timings track with the voltage and frequency.

### Section 3—Digitization of a Temporal Control Signal

For a control loop to control the period of the TCS 122 the period of the TCS 122 must be known to the control loop. The period is digitized so that the control loop may include a numerical version of the TCS 122 period in control loop calculations. In one embodiment the TPC 120 includes a counter 172 and a high speed time base signal FASTCLK 174 to digitize the TPC period. By counting the oscillations of FASTCLK 174 during a period or half period of the TCS 122 one knows the period of the TCS 122 to within the resolution of FASTCLK 174.

In one embodiment the signal FASTCLK 174 is generated by an accurate oscillator, for example a crystal oscillator (not shown). For example consider a FASTCLK period of 10 nSec and a target period for the TCS 122 of one microsecond. Other periods for FASTCLK 174 and/or for the TCS 122 may be used to practice the invention. The shorter the period of FASTCLK 174 relative to the period of the TCS 122, the greater the possible resolution of the TCS period when digitized, thereby minimizing quantization error. However, generation of the signal FASTCLK 174 requires more power as the period is decreased (frequency increased).

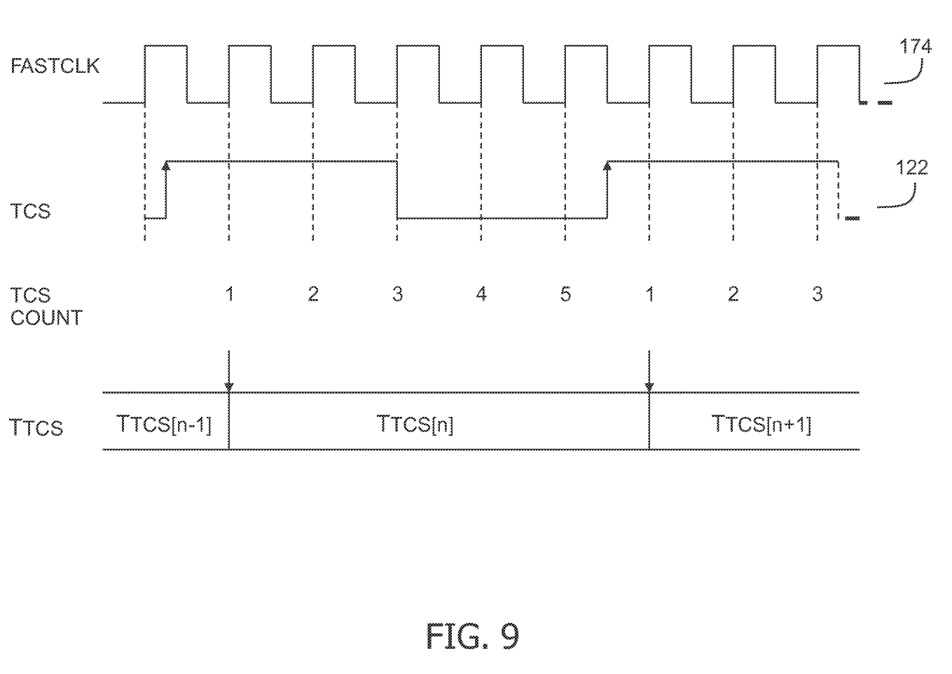

Looking to FIG. 9, a toggling signal FASTCLK 174 is shown relative to TCS 122. For the purpose of illustration, FASTCLK 174 in FIG. 9 is only slightly faster than TCS 122. In this example a single register counter 172 counts the rising edges of the signal FASTCLK 174 during a period of the TCS 122. In the example of FIG. 9, the counter 172 returns a count of five for the instant TCS 122 period. Each time the TCS 122 rising edge occurs the counter 172 resets to the count of one. Clearly if FASTCLK were a much higher frequency than the frequency of the TCS 122, for example one hundred times higher, the error introduced in the count returned by counter 172 would be smaller. Said differently, if FASTCLK 174 has a very small period compared to the period of TCS 122, smaller differences in the period of TCS 122 may be detected and digitized. In FIG. 9 the annotation Ttcs[n] corresponds to the period of the instant TCS as seen by the counter 172. Ttcs[n] may vary from the actual period of the TCS 122 (i.e, quantization error), the degree of error depending upon the relative frequencies of FASTCLK 174 and TCS 122 and their instant phase relationship.

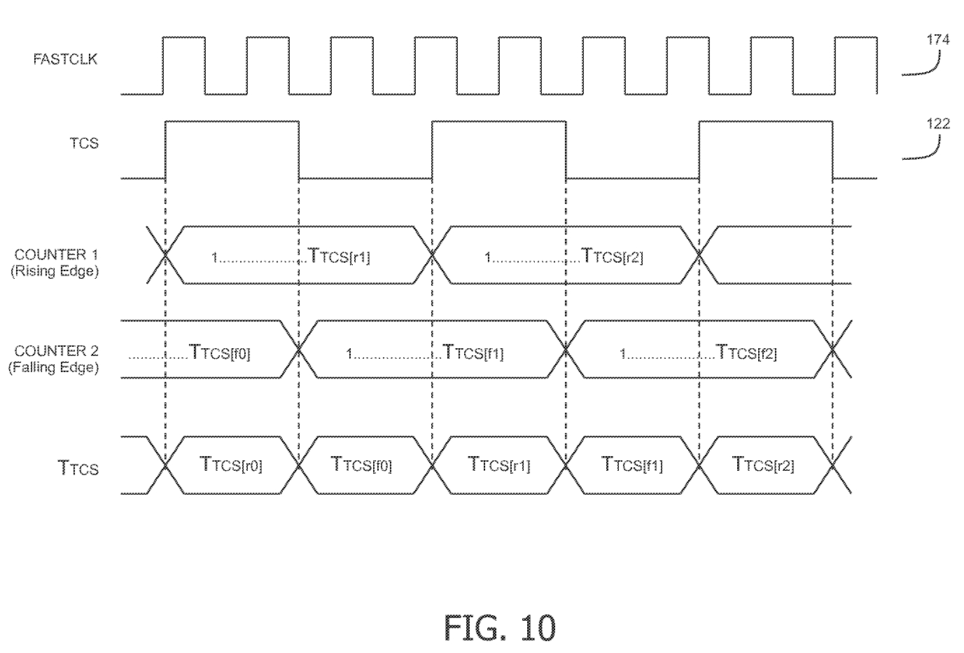

Some embodiments use two counters, one counting from rising edge to rising edge of TCS 122 and the other counting from falling edge to falling edge of TCS 122. In another embodiment, wherein the TCS 122 is known to be a 50/50 symmetrical signal, one or more counters count the transitions of FASTCLK 174 for a half period of TCS 122. FIG. 10 is an example of an embodiment including two counters (both using the same FASTCLK 174 time base) to digitize the period of TCS 122. In an embodiment using one counter the instant value Ttcs may be nearly a complete TCS period old. Using two counters, one counting FASTCLK oscillations from TCS 122 rising edge to rising edge and the other counter counting FASTCLK oscillations from TCS 122 falling edge to falling edge the instant value Ttcs is a maximum of a half period of TCS 122 old.

As shown (FIG. 10), Counter 1 counts the number of cycles of FASTCLK 174 during a rising edge to rising edge period of TCS 122 while Counter 2 counts the number of cycles of FASTCLK 174 during a falling edge to falling edge period of TCS 122. The most recent count to complete is stored, for example in a holding register. The controller 170 does not need to know which counter is most current, it simply reads the stored value from a static address. Other strategies for keeping the most current value of Ttcs may be used, such as having two holding registers and a pointer that is updated to indicate which register holds the most recent value of Ttcs.

The register which holds the count Ttcs must be wide enough to accommodate the maximum anticipated count of FASTCLK 174 during a TCS 122 period. For the example periods of FASTCLK 174=10 nSec and TCS 122=1 uSec the nominal count of Ttcs is 100. For a control system (TPC 120) configured to control the period of TCS 122 to within ten percent, the maximum anticipated count of Ttcs is (1.1 mSec/0.01 mSec) or 110. A seven bit counter would be wide enough to accommodate a count of 128d, corresponding to a TCS 122 period of 1.28 mSec (28%). In some embodiments a standard eight bit counter is used, and the maximum Ttcs count is 256d, representing a TCS 122 period of 2.56 mSec.

Execution of a control loop (discussed hereinafter) is initiated at regular intervals, for example a certain count of FASTCLK cycles. Because TCS 122 has a variable period, TCS 122 and execution of the control loop will be asynchronous. The control loop uses the most recent digitized value of the TCS 122. The frequency of the control loop is fixed, accepting some phase-related error in the value of TCS 122 due to phase related lag. In another embodiment the phase lag between digitization of the TCS 122 and execution of the control loop is reduced to nearly zero by triggering execution of the control loop on an edge of the TCS 122. Because TCS 122 is somewhat variable, the time between cycles of the control loop will also vary, potentially introducing some error in time-related calculations. However there is little phase error in the value of TCS 122 itself because the value in the counter will have instantly completed counting cycles of FASTCLK for a period (or a half period) of the TCS 122.

### Section 4—Power Supplies for Propagation Delay Control

Before describing control loop methods we first describe embodiments of the power supply 112. The power supply 112 is controlled by the TPC 120 in accordance with the control loop employed. Power supply 112 may be any controllable power supply suitable for the application at hand. For example, in one embodiment the power supply 112 is a linear regulator wherein the reference voltage which controls the output voltage of the linear regulator is provided by a DAC within the TPC 120, the DAC output signal carried to the power supply 112 on a line. In another example power supply 112 is a switching power converter wherein the TPC 120 provides control signals to the switching power converter, the control signals controlling the duty cycle of the switching power converter.

### Section 4.1—A Buck Switching Power Supply

In accordance with the method of the invention, Vo and Vin are not known. However one cannot disregard the characteristics and capabilities of the power supply 112. Clearly the power supply 112 must be adequate for providing the needed voltage V0, even thought the value of that voltage is not known to the control loop.

To facilitate an analysis of a voltage providing apparatus (i.e., power supply 112) in terms of a time period (such as Ttcs) we define voltage terms as a voltage required to provide a certain oscillating signal period at a stated condition. For example, “VtarP” is defined as the voltage V0 at terminal 114 when Ttcs equals Ttar 2100, “VdblP” is defined as the voltage V0 at terminal 114 when Ttcs equals Tdbl 2104, and so on. The relationship between two terms (as in the example of VtarP and Ttar) for a given physical power supply may be determined by simulation or laboratory bench data.

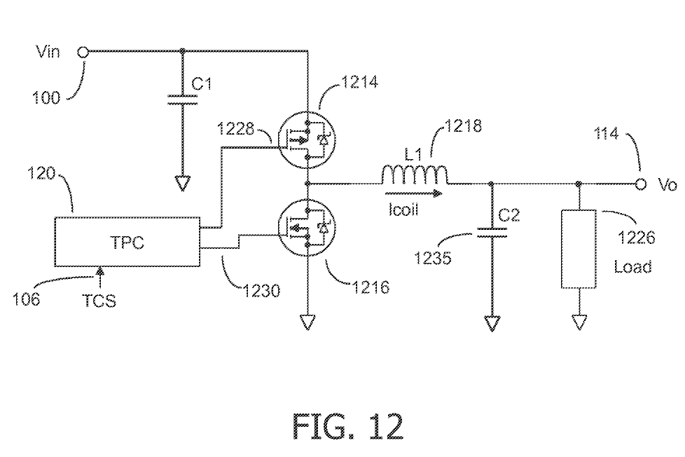

Referring to FIG. 12, a power supply 112 (FIG. 1) comprising a buck switching power converter is shown. The basic operation of a buck switching power converter is the intermittent connection between an input voltage “Vin” at input terminal 100 and inductor L1 1218 by a control FET 1214 for a time termed “Tp”. At the end of time Tp, control FET 1214 turns off and synchronous regulator FET 1216 is turned on for a time termed “Ts”. This is accomplished by TPC 120 supplying conduction control signals to the FETs via lines 1228 and 1230 which are connected to the gates of FETs 1214 and 1216 respectively. When FET 1214 turns on, current flows through inductor L1 to the load 1226, the load 1226 comprising the combined loads supplied to the integrated circuit 176 (FIG. 1) and the TPM 118. Output voltage V0 is smoothed by a capacitor C2 1235. FET 1216 may be replaced by a diode to form a non-synchronous buck supply, in which case line 1230 is not needed. In the FIG. 12 topology, Ts is the time during which current from inductor L1 continues to flow after FET 1214 is turned off. Said differently, it is the time required for the coil current to return to zero after time Tp is completed. The method of the present invention may be applied to any switching power converter topology, including but not limited to buck, boost, and buck/boost wherein any of these topologies may be implemented as synchronous or non-synchronous designs.

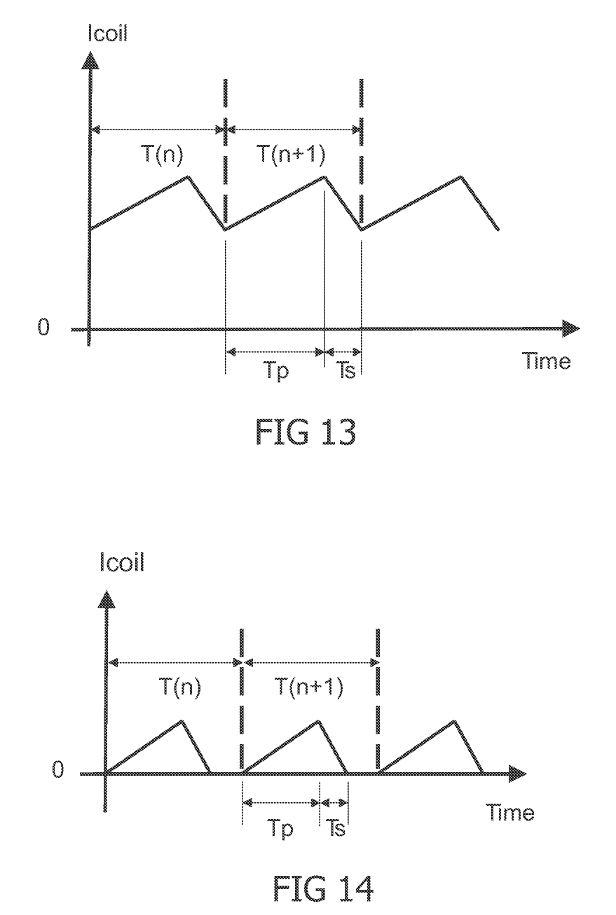

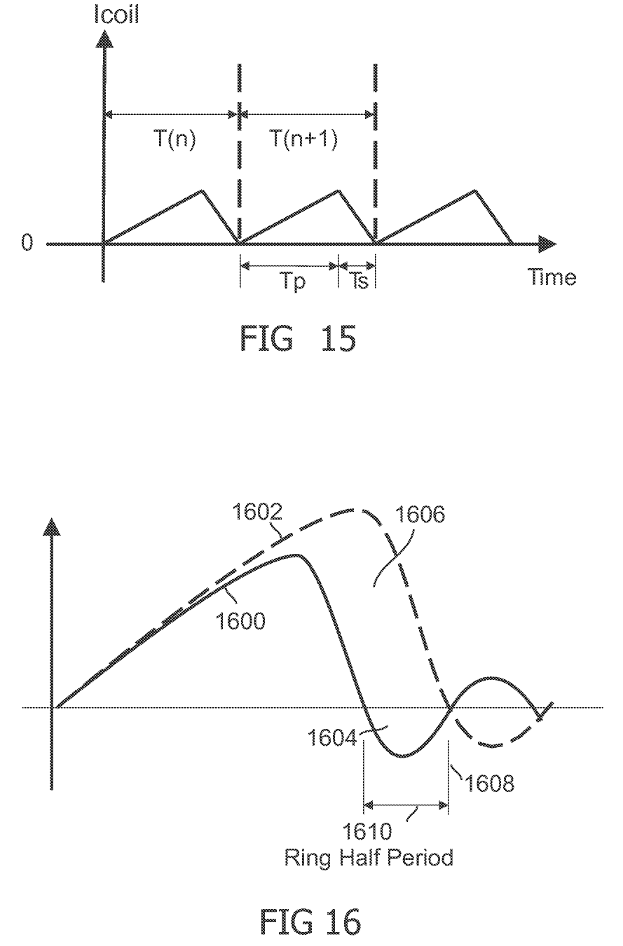

Buck operation may be viewed as having two modes: continuous coil current operation and discontinuous coil current operation relative to the current of coil L1 1218. As shown in FIG. 13, continuous coil current mode (“CCM” is defined as that condition wherein there is always current being delivered by the coil 1218, though not necessarily at a steady value. In discontinuous coil current mode (“DCM”), illustrated in FIG. 14, the current from coil 1218 returns to zero during each duty cycle event (i.e. each time period Tn, Tn+1, etc.) in which Tp>0. The condition wherein the coil 1218 current returns to zero just as another duty cycle event starts defines the maximum current that can be delivered in DCM, and is termed the “critical conduction state”, shown in FIG. 15. A variation of DCM occurs when the load demand is very small such that the pulse required for the control FET 1214 is so narrow that it would be inefficient to turn the FETs 1214, 1216 on and off. In this case a certain number of T cycles are skipped altogether, i.e. transistors 1214 and 1216 remain off during the certain number of cycles, and the pulse width Tp in the next duty cycle event is increased. This operation is termed “cycle skipping mode.”

In DCM operation the current through coil 1218 always returns to zero within one time period T (where T is the general notation for the cycles Tn, Tn+1, etc., also denoting the length of each cycle; these cycles are of equal length in some embodiments). Thus, coil 1218 does not integrate any current from the prior duty cycle event. There is no history to comprehend.

### Section 4.2—Insuring Monotonic Control

In one embodiment power supply 112 is a switching power converter operating in DCM. To overcome potentially non-monotonic operation, wherein Vo, hence Ttcs, changes in a direction counter to the direction of a change in Tp, one must take into account the specific design parameters and capabilities of the power supply 112. In the method of the present invention the instant Vo (and Vin) are not known. The following is an example of a method, denominated “Gain Method A” for insuring a monotonic relationship between a change in Tp and a corresponding change in Ttcs without knowing Vo and/or Vin.

A challenge of DCM is ringing that occurs as the current returns to zero. The ringing is caused by the output terminal capacitances (“Coss” of FET 1214 and FET 1216 against the inductance of coil L1 1218. The ringing magnitude can be significant, and can cause a non-monotonic response. In other words, if the duty cycle in some cycle Tn increases, the total charge flowing into coil 1218 in the next cycle T(n+1) could decrease, or vice versa.

Ringing is illustrated in FIG. 16. The coil L1 1218 current of a pulse 1600 is seen to ring. The energy (measured as the charge) of the ringing is represented by the area 1604. The area beneath the axis Icoil=0 represents energy removed from load 1226 (FIG. 12), that is, energy subtracted from the energy provided by the pulse 1600. Pulse 1602 represents the coil L1 1218 current pulse of the next duty cycle, shown here superimposed upon the pulse 1600. In this example the Tp adjustment is positive. The energy difference between pulse 1602 and pulse 1600 is the area 1606. Note that neither the phase of the ringing nor its magnitude at any point in time is known to microprocessor 170. Thus the start of the adjusted pulse 1602 is asynchronous to the ringing. The area 1604 is independent of the timing of the next pulse (1602), whereas the area 1606 is a function of the difference in (Tp+Ts) for pulse 1602 compared to that of the previous pulse (1600). If a Tp adjustment were made such that the area 1606 is less than the area 1604, and if the adjusted pulse 1602 were to begin at the time shown as point 1608, the resulting change in energy in pulse 1602 (hence, in voltage V0 at terminal 114) would be negative (change in charge equals the area 1606 minus the area 1604), though the microprocessor 170 anticipated an increase. In some embodiments TpVGain (the minimum quanta (count) by which Tp is changed when using the VSPL method) is set to a value that will insure that the minimum adjustment dTp is guaranteed to result in a change in Ttcs in the desired direction. This insures Vo responses will always be monotonic for any given adjustment, though sometimes in excess of the minimum required.

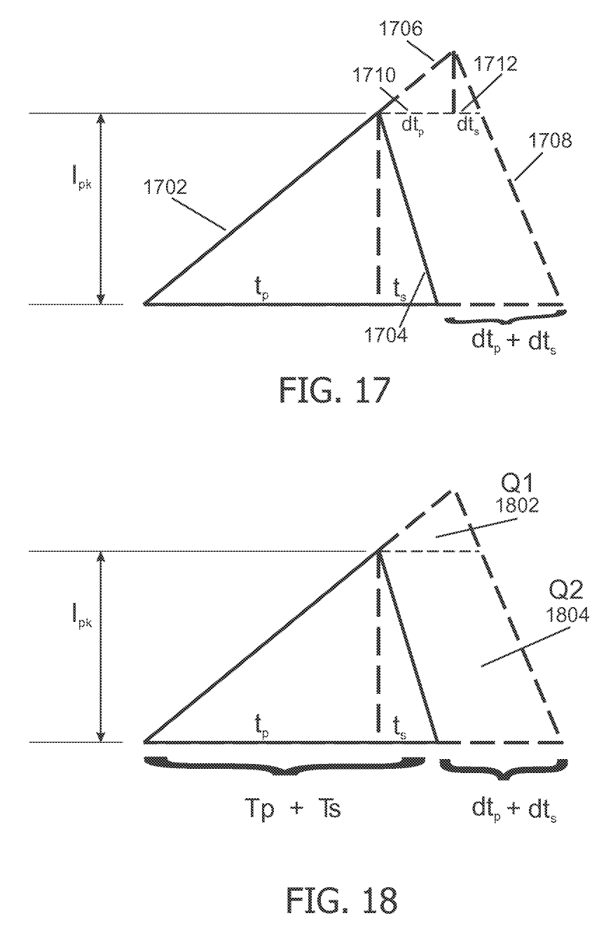

FIG. 17 is an idealized representation of a duty cycle event. Numerals 1702 and 1704 represent the current through the coil in an instant duty cycle, wherein the power and sync times are Tp and Ts, respectively. Numerals 1706 and 1708 represent the current after the application of adjustments dTp 1710 and dTs 1712 to the respective control signal drive times Tp and Ts. The pulse 1706, 1708 is shown superimposed upon the instant pulse 1702, 1704. The total time of the second (adjusted) pulse is (Tp+Ts+dTp+dTs). The gain of the second pulse, relative to the first, is dTp. The peak current Icoil of the instant pulse is termed “Ipk”. As shown in FIG. 17, the difference in charge between the two pulses is equal to the difference in area under their respective curves, disregarding any effects from ringing.

The difference in charge between the two pulses is the area Q1 1802 (the area above Ipk in FIG. 18) plus the area Q2 1804, or

$$dQ = {Q}_{1} + {Q}_{2} \\ dQ = {I}_{PK} ( {dT}_{P} + {dT}_{S} ) + \frac{( {V}_{IN} - {V}_{O} ) ( {dT}_{P} + {dT}_{S} ) {dT}_{P}}{2 L} \qquad [ 1 ]$$

We know that

$${I}_{PK} = \frac{( {V}_{IN} - {V}_{O} ) {T}_{P}}{L} , and {T}_{S} = \frac{( {V}_{IN} - {V}_{O} ) {T}_{P}}{{V}_{O}} , therefore \\ ( {T}_{P} + {T}_{S} ) = ( \frac{{V}_{IN}}{{V}_{O}} ) {T}_{P} . \\ Similarly , {dT}_{S} = \frac{( {V}_{IN} - {V}_{O} ) {dT}_{P}}{{V}_{O}} and ( {dT}_{P} + {dT}_{S} ) = ( \frac{{V}_{IN}}{{V}_{O}} ) {dT}_{P}$$

By substitution, rewrite [1] as:

$$dQ = ( {dT}_{P} + {dT}_{S} ) [ \frac{( {V}_{IN} - {V}_{O} ) {T}_{P}}{L} + \frac{( {V}_{IN} - {V}_{O} ) {dT}_{P}}{2 L} ] , or$$

$$dQ = [ \frac{{T}_{p}}{L} * \frac{{V}_{IN}}{{V}_{O}} * ( {V}_{IN} - {V}_{O} ) ] * {dT}_{P} * [ 1 + \frac{{dT}_{P}}{2 {T}_{P}} ]$$

The maximum energy of the ring is the energy stored in the Coss capacitance of the FETs 1214, 1216, thus

Q_{RING}=2CV_{O},

where C is the effective (charge average) Coss at Vo. Therefore the minimum time gain (dTp) to insure monotonicity is found by

$$dTp ( 1 + \frac{{dT}_{P}}{2 {T}_{P}} ) > \frac{2 {CV}_{O}}{( \frac{{T}_{P}}{L} ) ( \frac{{V}_{IN}}{{V}_{O}} ) ( {V}_{IN} - {V}_{O} )} , or$$

$$dTp ( 1 + \frac{{dT}_{P}}{2 {T}_{P}} ) > ( \frac{2 LC}{{T}_{P}} ) ( \frac{{V}_{O}^{2}}{{V}_{IN} ( {V}_{IN} - {V}_{O} )} )$$

Assuming dT_{P}<<2T_{P}, we have

$${dT}_{p} > \frac{2 {LC ( {V}_{O} )}^{2}}{{T}_{P} * {V}_{IN} ( {V}_{IN} - {V}_{O} )} , or \\ {dT}_{P ( MIN )} > \frac{2 LC}{{T}_{P}} {( \frac{{V}_{O}}{{V}_{IN}} )}^{2} ( \frac{1}{1 - ( {V}_{O} / {V}_{IN} )} ) . \qquad [ 2 ]$$

In the present invention the instant Vo and Vin are not known, therefore a value for dT_{P(MIN)} which will be effective across all design conditions must be predetermined. For a buck switching power converter Vo can never exceed Vin. Examining equation [2], we see that the worst case is the condition of maximum Vo and minimum Vin (comprehending temperature, process parameters, and load), and that dTp will become extremely large as Vo approaches Vin. This may be avoided by the system designer by, for example, insuring the design of the power supply 112 is such that Vin is always comfortably higher than Vo. Ringing is only a potential problem when there is no cycle skipping. In one embodiment there is always at least one cycle skipped, which allows any ringing to dampen out during the skipped cycle, in which case consideration of a minimum dTp is not necessary. However ripple is increased compared to no cycle skipping. In some embodiments a value of dT_{P(MIN)} is predetermined by the designer that is less than that required by equation [2] for the most extreme conditions, accepting that non-monotonic operation may sometimes occur.

The gain dTp must not exceed a value wherein unstable operation may result. Standard stability analysis techniques, such as Bode plots, may be used for this purpose. The worst case condition, for which the maximum gain should be determined, is with small values for L and C, low output voltage V0, and high load current. So gain is determined by the system designer, insuring that it is greater than the right-hand side of [2] and that the gain times the number of increments of adjustments is less than the maximum determined by stability analysis. The gain so derived is termed “TpVGain”. Gain Method A, then, insures that a correction of Tp will have a monotonic response.

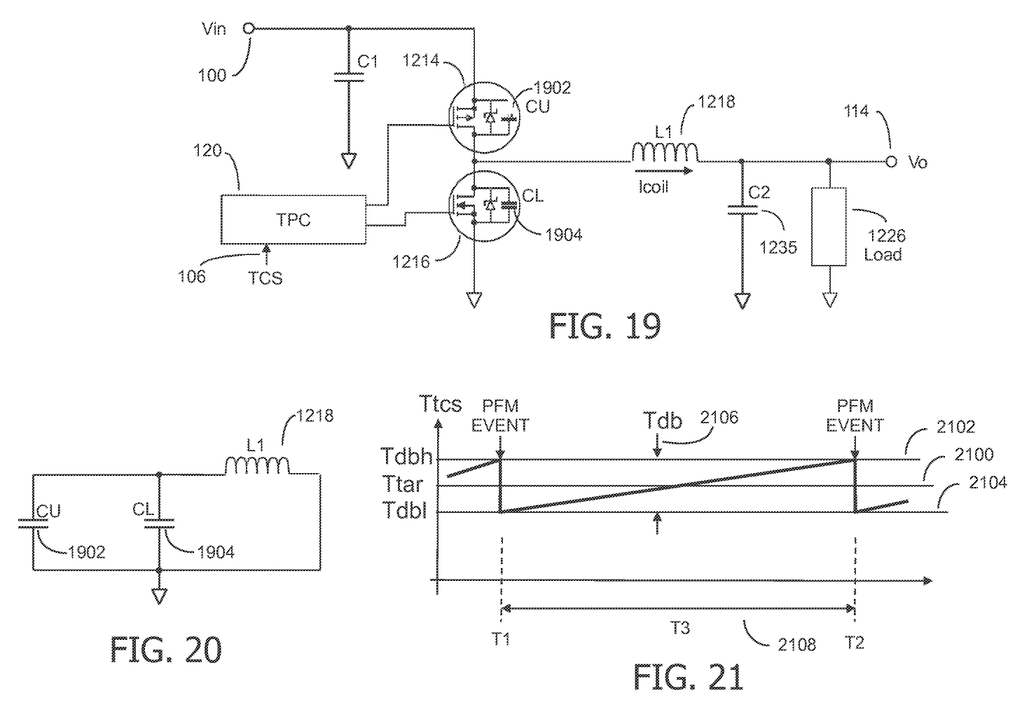

In another embodiment of the present invention, the minimum gain is found by examining the parasitics of the drive circuit. This method is denominated “Gain Method B”. FIG. 12 is redrawn in FIG. 19. The capacitors CU 1902 and CL 1904 represent the Coss of the FETs 1214 and 1216. The Coss of a specific FET can be found on the datasheet of the manufacturer. It is typically stated as the worst case, leading to a conservative analysis.

When the time Ts is complete the voltage across the coil is (Vo−Vss)=Vo. FIG. 19 is redrawn as FIG. 20. Disregarding resistive effects, the natural frequency of the circuit of FIG. 20 is known to be:

$$ω = 2 π f = \sqrt{\frac{1}{LC}}$$

where L is the inductance of the coil L1 1218 and C is the sum of the two parallel Coss capacitors CU 1902 and CL 1904. The response, then, when the coil current crosses zero is an oscillation with a half-period of:

$$Ring halfperiod = \frac{1}{2 f} = \frac{π}{\sqrt{\frac{1}{LC}}} .$$

This half period is represented by numeral 1610 (FIG. 16). As with Gain Method A, previously presented, using the ring half period as the minimum dTp (TpVGain) insures a monotonic response of Vo to a minimum change in Tp. Note that the period is a function of the inductance and Coss; it is independent of Vin, Vo, Tp, and Ts. Thus for any given design implementation the ring half period is a constant. At extremely narrow values of Tp, the energy of the ring (driven by Vo) may exceed the energy of the pulse during (Tp+Ts), a condition to be avoided. If TpVGain is less than the minimum change in Tp supported by the system hardware design (for example, one period of FASTCLK) then the hardware minimum is used for TpVGain.

### Section 4.3—Power Supply Startup

When the power supply 112 is first powered up the voltage V0 will be very low, thus the period of the TCS 122 will be very long. A control loop does not take control until Ttcs has decreased to a predefined level “Tstart” for the first time. A control loop, for example PFM or VSPL, takes over thereafter. In one embodiment a fixed pulse time for Tp is used during startup. In one embodiment a startup method using DCM is used. There are two constraints to consider when using a DCM startup method: (Tp+Ts) must be less than T (else in CCM by definition) and Tp must at least be able to provide a nominal TCS 122 period when a load is connected to the power supply 112 as Tstart is reached. For simplicity of illustration a nonsynchronous buck converter is assumed, wherein FET 1216 is replaced by a diode (or line 1230 to the control gate of FET 1216 held low by the TPC 120).

To avoid CCM operation Tp_max is determined for the condition wherein (Tp+Ts)=T, Vin is Vin_{MAX}, Vd is the diode voltage drop, and Vo=0. Thus we find:

$$Tp\_max = \frac{Vd}{( {Vin}_{max} + Vd )} * T .$$

To provide adequate power to the load when Tstart is attained and the load is connected to the terminal 114 (FIG. 1), Tp_min is found for the condition wherein Vo is approximately the voltage (V_{TAR}P) required to provide Ttar 2100, input voltage Vin is Vin_{MIN}, and the coil current is the anticipated current of the load I_{LOAD}. Accordingly, the minimum fixed Tp time is found by:

$$Tp\_min = \sqrt{2 {LTI}_{LOAD}} \sqrt{\frac{( {V}_{TAR} P + Vd )}{( {Vin}_{MIN} - {V}_{TAR} P ) ( ( {Vin}_{MIN} + Vd )}} .$$

In one embodiment the voltage ramp during startup is controlled to provide an approximately constant current, which would also provide an approximately linear voltage ramp. An approximation of the input voltage Vin in conjunction with a target current I_{START} and known parameters is used to determine Tp:

$$Tp = \sqrt{2 {LTI}_{START} \sqrt{\frac{( pVo + Vd )}{( Vin - pVo ) ( Vin + Vd )}}} ..$$

Vin is the assumed input voltage, Vd is the diode voltage, and pVo is the predicted Vo, where pVo is recalculated for each time frame T using:

pVo(n+1)=pVo(n)+(I_{START}*T/C)

The maximum value of Tstart must be less than the maximum count that the counter employed can hold for Tstart to be detectable (the relationship between maximum count and the counter bit width was addressed in the description of digitizing the TCS 122).

In some embodiments the determination of operation within the operating range, such that a control loop may begin control, is alternatively determined. For example, if the Vo which will provide a nominal value for Ttcs is known, an analog to digital converter may be used to determine when Tstart is attained by monitoring Vo at terminal 114 during startup.

### Section 5—Control Loops

In one embodiment the TPC 120 includes a microprocessor 170. The microprocessor 170 may implement a control loop, wherein historical, instant, and/or anticipated values of the TCS 122 period are compared to a target and action taken to correct any errors in the TCS 122 period in accordance with the method of the control loop. The control loop methods disclosed herein include “Pulse Frequency Modulation” (PFM) and “Very Simple Proportional Loop” (VSPL). The PFM method provides a single pulse from the power supply 112 when (and only when) the period of TCS 122 exceeds a certain maximum period. The VSPL method makes corrections to the output voltage V0 of the power supply 112 considering the TCS 122 instant period and direction of change of the TCS 122 period relative to certain limits, using a correction quanta scaled by the magnitude of error of the TCS 122 period.

For a given switching power supply design the highest power condition is in CCM. For the lowest power demands PFM may be used. For power demands between CCM and PFM, a DCM method according to some embodiments of the present invention may be used. In some embodiments, a DCM control loop uses the VSPL method.

### Section 5.1—Pulse Frequency Modulation

In accordance with one embodiment of the present invention, PFM control is utilized by the TPC 120 to control the power supply 112. Some embodiments of the PFM method as utilized for regulation of a voltage are disclosed in previously-stated commonly assigned U.S. patent application Ser. No. 11/030,688 filed on 5 JAN 2005 by Kent Kernahan and Milton D. Ribeiro. In the present invention the PFM method is modified to control the period of a monitoring signal, for example the TCS 122, by varying the voltage V0 provided to the monitored device in response to the TCS 122 period.

The PFM method comprises comparing a parameter to a predetermined utmost value; responding only if the parameter is in excess of the utmost value; resume comparing the parameter to the utmost value. In the PFM method, according to one embodiment of the present invention, the TPC 120 repetitively compares the period of the TCS 122 (Ttcs) to a predetermined maximum (Tdbh). If Ttcs>=Tdbh 2102, the TPC 120 controls the power supply 112 to inject a predetermined charge into the smoothing cap 1235. The charge injected into the capacitor 1235 by the power supply 112 raises the voltage V0, thereby reducing the duration of Ttcs. The TPC 120 resumes comparing Ttcs to Tdbh 2102, taking no action until Ttcs is again equal to or greater than Tdbh 2102.

The elapsed time between corrective actions (“PFM events” is variable, depending upon, for example, the load; leakage of the capacitor 1235; and the magnitude of the charge injected into the capacitor 1235. In one embodiment the value of Ttcs is determined immediately after the power supply 112 injects the predetermined charge into the capacitor 1235 and the value of the predetermined charge adjusted for the next PFM event if required.

The PFM method is particularly advantageous when used in a system in which the load is relatively small and stable, in which case Ttcs will change slowly, requiring response by the TPC 120 infrequently.

The PFM control method in accordance with the present invention is illustrated by FIG. 21, wherein Ttcs increases to an upper dead band limit “Tdbh” 2102 at time T1. The TPC 120 takes corrective action, controlling the power supply 112 to inject a predetermined charge into the smoothing capacitor C2 1235 sufficient to decrease Ttcs to a lower limit “Tdbl” 2104. This period swing is “Tdb” 2106 which equals (Tdbh−Tdbl). Tdbh 2102 and Tdbl 2104 are defined relative to the desired TCS 122 target period “Ttar” 2100. As the load removes charge from the smoothing capacitor C2 1235, power supply 112 output voltage V0 decreases. As the voltage V0 provided to the load 1226 decreases over time, Ttcs will increase over time T3 (also indicated by reference character 2108) until again reaching Tdbh 2102 at time T2, when the TPC 120 again takes corrective action by turning on PMOS transistor 1214 (FIG. 12) to recharge capacitor C2 1235.

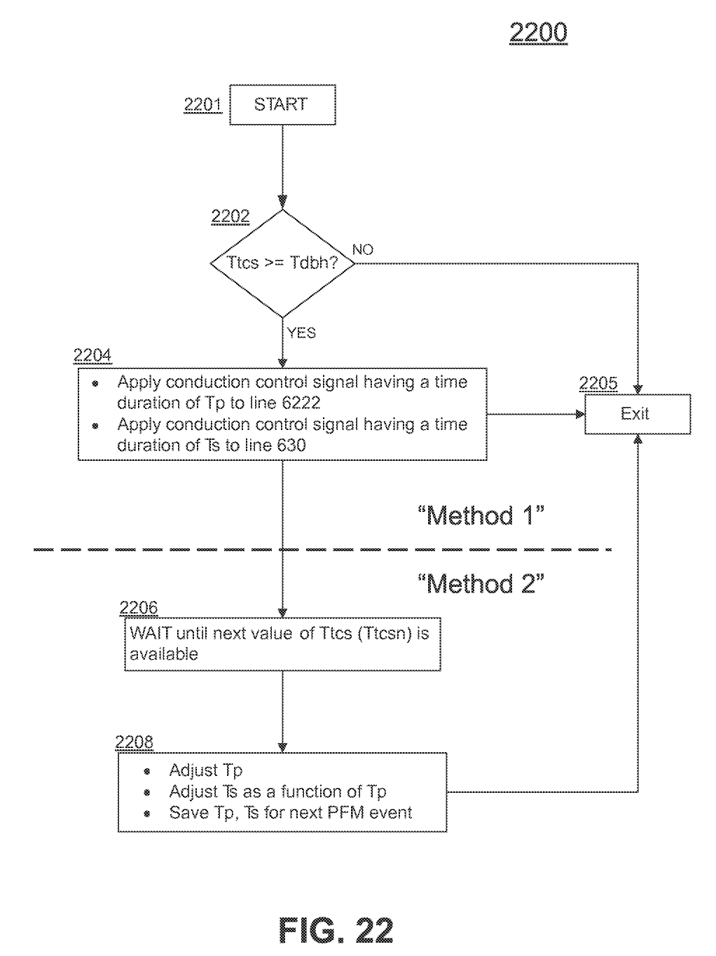

The PFM method of the present invention is represented by the flow chart of FIG. 22. Flow 2200 is called at regular intervals, upon completion of each TCS 122 digitization step, or at other times as discussed herein previously. In one embodiment the TPC 120 reads the period Ttcs at step 2201 from memory. At step 2202 the instant Ttcs is compared with Tdbh 2102. If Ttcs is not greater than or equal to Tdbh 2102, we exit at step 2205 and wait for flow 2200 to be called again. If step 2202 returns TRUE, that is that Ttcs is equal to or greater than Tdbh 2102, the process moves to step 2204. At step 2204, a conduction control signal of time period Tp is applied to control FET 1214 by the TPC 120 via line 1228. Thereafter, a conduction control signal of time duration Ts is applied to FET 1216 via line 1230. In the synchronous circuit of FIG. 12, FET 1216 is driven for the time Ts. In a non-synchronous topology, for example, a circuit of the type shown in FIG. 12 but with FET 1216 replaced by a diode, Ts represents the time during which current will continue to flow from the coil toward load 1226 after the control FET 1214 is turned off. With a non-synchronous topology Ts is not calculated nor saved; it will just happen. The PFM control process then exits at step 2205.

In one embodiment fixed pulse times Tp and Ts are predetermined by the system designer. In such an embodiment step 2204 returns to step 2201. This embodiment is termed “Method1”. In such an embodiment Ttcs may over or undershoot the desired period Tdbl 2104 following step 2204. In some embodiments, termed “Method2”, the process continues from step 2204 to step 2206 and waits for the TPC 120 to determine the period Ttcs of the next TCS 122 cycle termed “Ttcsn”. When the next actual value of Ttcsn is available, step 2208 scales the next value of Tp per:

Tp=Tp*(Ttcsn/Tdbl).

Other techniques may be used for adjusting Tp at step 2208. For example, in one embodiment the adjustment is weakened by halving the correction. The correction, then, becomes:

Tp=Tp*(Ttcsn+Tdbl)/(2*Tdbl)).

### Other strategies may be used, such as using a rolling average of Ttcsn to dampen the reaction of the adjustment to Tp for the next PFM event.

In this manner (Method 2) the charge pulse to be supplied at the next PFM event is ongoingly adjusted to provide an improved estimate of the charge that will move Ttcs from Tdbh to Tdbl 2104 as a result of a PFM event. In some embodiments the value of Ts is modified in response to any modification of Tp. For example, a fixed ratio between Tp and Ts may be used to scale Ts based upon the instant value of Tp. The updated values of Tp and Ts are saved in memory (step 2208) for use at the next PFM duty cycle event (step 2204), then the process exits at step 2205.

During the operation of the PFM method as practiced using the apparatus of FIG. 12, the instant input and output voltages, as well as temperature, are unknown. The actual processing parameters of a specific integrated circuit, for example the integrated circuit 176, are also unknown. The only measured metric is Ttcs and the only control mechanism utilized to control Ttcs is the change in output voltage V0 determined (mostly) by the time Tp. However it is useful to understand the relationship of input voltage Vin, output voltage V0, coil L1 1218 current Icoil, the switching power supply duty cycle (Tp/(Tp+Ts)) and the period Ttcs of the TCS 122. This understanding is useful in configuring the power supply 112 to practice the present invention.

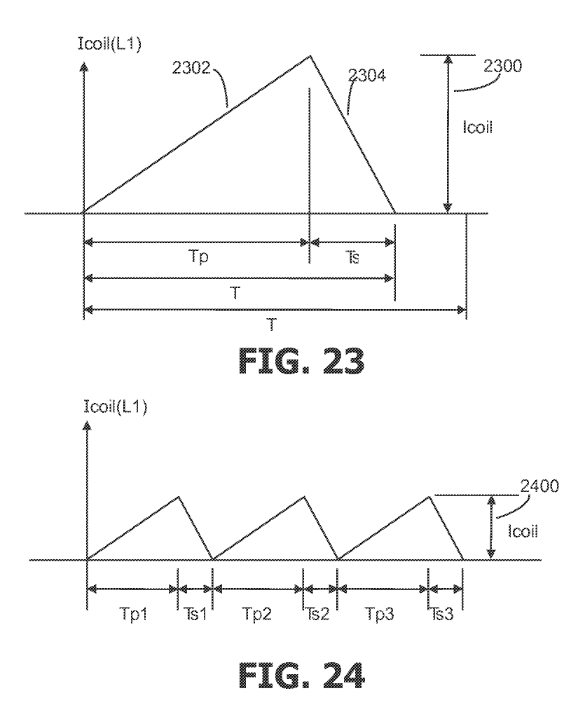

FIG. 23 shows the current through inductor L1 1218 over time. Coil 1218 current Icoil rises as indicated by reference character 2302 with a slope of V1/L for the time Tp and falls as indicated by reference character 2304 with the slope V2/L for the time Ts, where V1 is the voltage across the inductor L1 during Tp, V2 is the voltage across the inductor L1 during Ts, and L is the inductance of inductor L1 1218. The following relationship is derived from the principle of conservation of charge:

$$Δ Q = \frac{1}{2} \cdot ( {T}_{p} + {T}_{s} ) \cdot Δ I = \frac{1}{2} \cdot Δ T \cdot Δ I = C 2 \cdot Δ V$$

$$V = \frac{\int i d t}{C 2} = \frac{Q}{C}$$

$$V = L \frac{d i}{d t}$$

$$V = Ri$$

However, considering that the inductor L1 1218 current starts at zero and returns to zero, this provides:

$$\frac{{V}_{1} \cdot {T}_{p}}{L} = \frac{{V}_{2} \cdot {T}_{s}}{L} ⇒ {V}_{1} \cdot {T}_{p} = {V}_{2} \cdot {T}_{s} . \qquad [ 3 ]$$

Expanding the equation, results in:

$$Δ t = {T}_{p} + {T}_{s} = {T}_{p} + \frac{{V}_{1}}{{V}_{2}} \cdot {T}_{p} = {T}_{p} \cdot ( 1 + \frac{{V}_{1}}{{V}_{2}} ) .$$

The peak coil current ΔI 2300 is:

$$Δ I = \frac{{V}_{1} \cdot {T}_{p}}{L} = \frac{{V}_{1} \cdot Δ t}{L \cdot ( 1 + \frac{{V}_{1}}{{V}_{2}} )} .$$

Therefore, using the relationship previously obtained:

$$\begin{matrix}C \cdot Δ V = \frac{1}{2} \cdot Δ t \cdot Δ I \\ = \frac{1}{2} \cdot Δ t \cdot \frac{{V}_{1} \cdot Δ t}{L \cdot ( 1 + \frac{{V}_{1}}{{V}_{2}} )} \\ = \frac{1}{2 \cdot L} \cdot Δ {t}^{2} \cdot \frac{{V}_{1} \cdot {V}_{2}}{{V}_{1} + {V}_{2}} \\ = \frac{Δ t 2}{2 L} ( \frac{{V}_{1} {V}_{2}}{{V}_{1} + {V}_{2}} ) .\end{matrix}$$

Finally, we have:

$$Δ V = \frac{Δ {t}^{2}}{( 2 \cdot L \cdot C )} \cdot \frac{( {V}_{1} \cdot {V}_{2} )}{( {V}_{1} + {V}_{2} )} , or \text{:} \\ Δ t = \sqrt{2 \cdot L \cdot C} \cdot \sqrt{Δ V \cdot \frac{( {V}_{1} + {V}_{2} )}{( {V}_{1} \cdot {V}_{2} )} .} \qquad [ 4 ]$$

In the use of the PFM method to control voltage (which can be measured) within a voltage dead band, for example as disclosed in the aforementioned U.S. patent application Ser. No. 11/030,688, Vdbh and Vdbl refer to the maximum and minimum voltages defining a voltage dead band (Vdb) of Vo. In the context of the present invention, wherein voltage is not regulated or even known to an absolute voltage value, VdbhP is defined as that voltage V0 which provides a TCS 122 period Ttcs of Tdbh 2102 at the instant condition of temperature. Likewise, we define VdblP as that voltage V0 which provides a TCS 122 period Ttcs of Tdbl 2104; VtarP corresponds to Ttar 2100, and VdbP corresponds to Tdb 2106.

For the topology of FIG. 12:

ΔV=V_{dbh}−V_{dbl}

V₁=Vᵢₙ−Vₒᵤₜ=Vᵢₙ−Vₜₐᵣ

V₂=Vₒᵤₜ=Vₜₐᵣ

Therefore, combining equations [3] and [4], and solving for Tp and Ts provides:

$$\begin{matrix}{T}_{p} = \sqrt{2 \cdot L \cdot C} \cdot \sqrt{\frac{( {V}_{dbh} - {V}_{dbl} ) \cdot {V}_{tar}}{{V}_{i n} \cdot ( {V}_{i n} - {V}_{tar} )}} and & [ 5 ] \\ {T}_{s} = \frac{{V}_{i n} - {V}_{tar}}{{V}_{tar}} \cdot {T}_{p} - {GB}_{1} - {GB}_{2} , & [ 6 ]\end{matrix}$$

where GB1 is the time guard-band between the end of the conduction control signal provided to FET 1214, and the beginning of the conduction control signal provided to FET 1216, and GB2 is the guard-band between the end of the conduction control signal provided to FET 1216 and the beginning of the next conduction control pulse to be provided to FET 1214. It is of course desirable to avoid overlapping conduction of the control FET 1214 and the synchronous regulator FET 1216. Guard band duration is a function of the turn on and off times of the FETs used for FET 1214 and FET 1216 in the target system, as determined from their data sheet specifications.

With the PFM method practiced according to Method1, a predetermined, fixed Tp is used under all conditions. With a fixed Tp pulse the expected dead band Tdb 2106 that can be maintained over temperature and the specific manufacturing variances of the integrated circuit 176 is expected to be larger than the dead band of the PFM method according to Method2. With a fixed Tp pulse width Ttcs may overshoot Tdbl 2104 at cold temperatures, leading to higher power consumption by the load 1226 than necessary for proper operation. Ttcs may undershoot Tdbl 2104 at high temperatures, leading to some inefficiency due to more frequent PFM events. In the case of Method2, the initial Tp is not critical, in that the scaling step (step 2208, FIG. 22) alters Tp such that Ttcsn moves more closely to Tdbl 2104 at each PFM event time, excepting after a significant load transient between PFM events.

To apply equation [5] for the control of Ttcs, we substitute VdbP for Vdb; VtarP for Vtar, VdblP for Vdbl, and VdbhP for Vdbh. The result is:

$${T}_{p} = \sqrt{2 \cdot L \cdot C} \cdot \sqrt{\frac{( - {V}_{dblP} + {V}_{dbhP} ) \cdot {V}_{tarP}}{{V}_{i n} \cdot {V}_{i n} + {V}_{tarP}}} \qquad [ 5 A ]$$

The values of VdbhP and VdblP may change significantly with temperature. However they are influenced by temperature in the same direction, accordingly the difference between the two will be small compared to Vin and VtarP across a range of temperatures (recalling that voltages in this context refer to the voltages which provide for a certain Ttcs at instant conditions). To be conservative, equation [5A] is evaluated towards a wide Tp pulse. Thus the minimum Vin and maximum VtarP are used. Vin is relatively insensitive to temperature, especially to the temperature of integrated circuit 176. Minimum Vin, then, is taken from the specification of the power source, for example a battery. VtarP is directly influenced by temperature and will be at its maximum value when the TPM 118 is at the highest design temperature. That is, VtarP is Vo when Ttcs=Ttar 2100 at the maximum design temperature of the TPM 118. Likewise (VdbhP−VdblP) is determined across temperature and the largest difference used. In one embodiment the TPM 118 is simulated for maximum junction and environmental temperature, providing VdbhP, VdblP, and VtarP values. In another embodiment a physical TPM 118 is evaluated in a laboratory environment and VdblP, VdbhP, and VtarP found experimentally by exposing the TPM 118 to the appropriate temperatures.

The resulting value of Tp, found according to Method1 equation [5 A] may be used for the initial value of Tp for use according to Method2.

The synchronizing pulse Ts is an important design parameter for a buck converter. If an instant Ts is too long, such that coil L1 1218 current becomes negative, the efficiency loss can be significant. If the pulse Ts is too short (that is, coil 1218 current continues to flow through the body diode of FET 1216 after FET 1216 has been turned off by the signal on line 1230) there will be some efficiency loss due to the FET 1216 diode drop, but the loss will be less significant than having a pulse Ts that is too long. Thus, Ts is evaluated such that a minimum pulse width is found. As with Tp, this will result from using the minimum Vin and maximum VtarP per simulation or laboratory investigation. Again, we substitute VtarP for Vtar into equation [6] to provide a method to determine Ts for controlling Ttcs to obtain equation [6A]:

$${T}_{s} = \frac{- {V}_{i n} + {V}_{tarP}}{{V}_{tarP}} \cdot {T}_{p} - {GB}_{1} - {GB}_{2} \qquad [ 6 A ]$$

In some embodiments wherein Method2 is used, the initial Tp pulse length is determined using [3A] as evaluated for Method1. However, Tp will be adjusted at the next PFM event and other PFM events thereafter (see FIG. 22). In one embodiment the Ts pulse width according to Method2 is the same fixed value found per Method1[6A]. In some embodiments the Ts pulse is also adjusted in conjunction with PFM events using Ts=k*Tp−GB1−GB2, wherein k is defined as (Vin−VtarP)/VtarP as evaluated for the case of Method1, GB1 and GB2 values are as previously described, and Tp is the updated (scaled) value of Tp propositioned for the next PFM event.

In some designs, a single conduction control signal of length Tp could cause the maximum current in the coil L1 1218 to exceed a maximum acceptable, such as the maximum current rating of the inductor L1 1218. The inductor may have, for example, been selected for a small physical size or other requirements of the end design. FIG. 24 illustrates an embodiment wherein the time required for Tp (per equation [5] or as adjusted) is broken up into multiple, shorter time periods, separated by the appropriate Ts periods, to yield the required charge. In this example Tp is applied in time periods Tp1, Tp2, Tp3, and Ts in time periods Ts1, Ts2, and Ts3, resulting in a lower ΔIcoil 2400. That is ΔIcoil 2400 is less than ΔIcoil 2300. This embodiment may be applied to any of the PFM methods and topologies herein described.

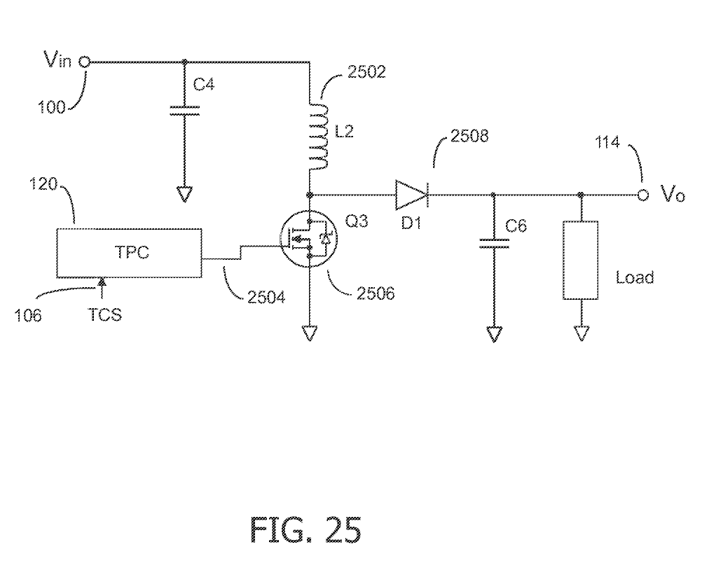

In another embodiment, the PFM control method is utilized with a non-synchronous boost converter, such as shown in FIG. 25. The TPC 120 provides a conduction control signal on line 2504 to FET Q3 2506, thus permitting current to flow in the inductor L2 2502 for a length of time Tp. Thereafter the conduction control signal is terminated and the current of inductor L2 flows through diode D1 2508 for a length of time Ts.

The width of the control pulse Tp may be determined according to Method1 or Method2, wherein Method2 includes the adjustment of Tp in response to the value of Ttcsn as previously described (step 2208, FIG. 22).

Vin is assumed to be within a restricted range of voltages:

Vᵢₙ₍ₘᵢₙ₎≦Vᵢₙ≦Vᵢₙ₍ₘₐₓ₎. Looking at FIG. 23, we have the following relationship derived from the principle of conservation of charge:

$$Δ Q = \frac{1}{2} \cdot {T}_{s} \cdot Δ I = C \cdot Δ V$$

$$Δ V = \frac{\int i d t}{C} = \frac{Δ Q}{C}$$

However, considering that the current in inductor L2 starts at 0 and returns to 0, this provides:

$$\frac{{V}_{1} \cdot {T}_{p}}{L} = \frac{{V}_{2} \cdot {T}_{s}}{L} ⇒ {V}_{1} \cdot {T}_{p} = {V}_{2} \cdot {T}_{s}$$

where V1 is the voltage across the inductor L2 during time Tp and V2 is the voltage across the inductor L2 during time Ts.

The peak current in inductor L2 (ΔI) is:

$$Δ I = \frac{{V}_{2} \cdot {T}_{s}}{L} = \frac{{V}_{1} \cdot {T}_{p}}{L}$$

Therefore, using the relationship previously obtained:

$$C \cdot Δ V = \frac{1}{2} \cdot {T}_{s} \cdot Δ I = \frac{1}{2} \cdot \frac{{V}_{1} \cdot {T}_{p}}{{V}_{2}} \cdot \frac{{V}_{1} \cdot {T}_{p}}{L}$$

$$Now Δ V = \frac{{T}_{p}^{2}}{2 \cdot L \cdot C} \cdot \frac{{V}_{1}^{2}}{{V}_{2}} , or$$

$${T}_{p} = \frac{1}{{V}_{1}} \cdot \sqrt{2 \cdot L \cdot C \cdot Δ V \cdot {V}_{2}} .$$

For the implementation of FIG. 25, and using voltage terms corresponding to the control of Ttcs, this provides:

ΔV=V_{dbhP}−V_{dblP},

V₁=Vᵢₙ, and

V₂Vₒᵤₜ+V_{D}−Vᵢₙ=V_{tarP}+V_{D}−Vᵢₙ,

where V_{D} is the drop across diode D1 2508. Thus Tp, the only control parameter for a non-synchronous implementation, can be calculated as

$${T}_{p} = \frac{\sqrt{2 \cdot L \cdot C \cdot ( {V}_{dbhP} - {V}_{db 1 P} )}}{{V}_{in}} \cdot \sqrt{{V}_{tarP} + {V}_{D} - {V}_{in}} .$$

As was seen in the earlier discussion, Tp according to Method1 or as the initial value according to Method2, is determined using the maximum VtarP, which corresponds to Vo when Ttcs=Ttar at maximum temperature, Vin is the minimum per the specification of the power source, and (VdbhP−VdblP) is found by bench analysis or by simulation.

### Section 5.2—Very Simple Proportional Control Loop

In one embodiment of the present invention a control loop method denominated “very simple control loop” or “VSPL” is used. Some embodiments of the VSPL method as utilized for regulation to a target voltage are disclosed in previously-stated commonly assigned U.S. patent application Ser. No. 11/030,585 filed on 5 JAN 2005 by Kent Kernahan and Milton D. Ribeiro. In the present invention the VSPL method is modified to control the period of a monitoring signal, for example the TCS 122, by varying the voltage V0 provided to the monitored device in response to the TCS 122 period.

The VSPL method comprises comparing a parameter to a predetermined range of values of the parameter. If the parameter is within the predetermined range, no action is taken. If the parameter value is outside of the predetermined range, the parameter is compared to a previous value of the parameter to determine the direction of change in the value of the parameter. If the parameter is moving towards the predetermined range no action is taken. If the parameter is moving away from the predetermined range, corrective action is taken. The magnitude of the corrective action is proportional to the manatude of the displacement of the parameter from the predetermined range.

In one embodiment of the present invention, the TPC 120 digitizes the period of the TCS 122 (Ttcs) in consecutive time periods. The digital value (Ttcs) corresponds to the period of the TCS 122 (Ttcs). In accordance with the VSPL method, the instant (Ttcs) and previous (LTtcs) digital values of the TCS period determine what, if any, action is taken. The logic of the VSPL method may be implemented by a programmed microprocessor, for example microprocessor 170. The programmed microprocessor 170 computes the times of the control signals Tp and Ts and the TPC 120 generates the corresponding signals on lines 1228 and 1230 (FIG. 12).

### Section 5.3—VSPL Control Regions

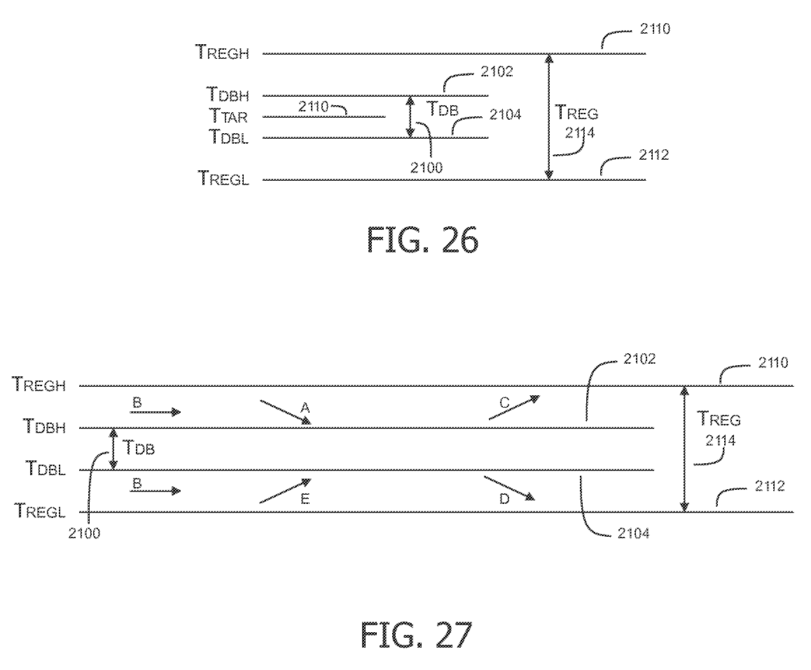

Referring to FIG. 26, for the VSPL control loop we define an additional region termed the “regulation band” (“Treg” 2114) wherein Treg=(Tregh−Tregl). Tregh 2110 and Tregl 2112 are respectively the maximum and minimum period of the TCS 122 (quantified as Ttcs) within which the VSPL method is utilized. Details are shown in FIG. 26, wherein the vertical axis is time or counts of FASTCLK 174. In the method of the VSPL control loop, no action is taken whenever a TCS period Ttcs is within the region of Tdb 2106. VSPL makes adjustment decisions when Ttcs is in the region within Treg 2114 exclusive of the region Tdb 2106. Other methods are used when Ttcs is greater than Tregh 2110 or less than Tregl 2112.

The values of Tregh 2110 and Tregl 2112 relative to Ttar 2100 is a design decision based upon the requirements of a specific design insofar as acceptable variability of propagation delay of the controlled (monitored) device is concerned. In some embodiments (Tregh−Ttar) and (Ttar−Tregl) are different values. That is, Ttar 2100 is not required to be half way between Tregh 2110 and Tregl 2112.

The ability to stay below Tregh 2110 is a power supply 112 design consideration, specifically that the power supply 112 in DCM mode be capable of supplying adequate power for the maximum design load (including the effects of temperature and process variations) such that propagation becomes too long.

Tregl 2112 involves the load, in that one solution to Ttcs being less than Tregl 2112 is for the power supply 112 to do nothing, such that the load itself bleeds off the excess power (voltage) from capacitor C2 1235 (FIG. 12). In one embodiment an emergency measure is taken when Ttcs is less than Tregl 2112 wherein the synchronous regulator FET 1216 is turned on while the power FET 1214 is off, thereby connecting the load to ground through the coil 1218. In the method of this emergency measure, FET 1214 is not first turned on to supply charge to the smoothing capacitor 1235; FET 1216 is turned on to remove charge from capacitor 1235 through coil 1218 to ground.

The power requirement of a system is less when the control loop need not make adjustments to Tp and Ts. We define a “dead band” (or, “non-regulation band”) “Tdb” 2106 within Treg 714 wherein no adjustments are made. The size of Tdb 2106 is such that there is always a solution for Tp such that Ttcs can be brought into the region Tdb 2106. We have already discussed the need to avoid ringing when there is no cycle skipping (notated as CS=1) by determining a minimum step size to Tp, denominated TpVGain. To insure that Tdb 2106 is specified such that there will always be a solution possible wherein Ttcs can be brought into the region of Tdb 2106 we determine the largest change in Ttcs as a result of a single minimum change dTp to Tp.

To relate a change in TCS 122 to a change in Vo we evaluate

$$TCSGain = \frac{\partial {T}_{TCS}}{\partial Vo} \cdot \frac{\partial Vo}{\partial Tp} \qquad [ 7 ]$$

which may be determined by simulation, math modeling, or bench analysis. To be effective under all design conditions the worst case conditions are used, for example the fast/fast process corner at minimum temperature. The result is the largest change in TCS 122 that is anticipated for a minimum change in Tp. In some embodiments Tdb 2106 is set at 2*TCSGain*TpVGain, wherein Tdbh=Ttar+TCSGain*TpVGain and Tdbl=Ttar−TCSGain*TpVgain.

In some embodiments the region Tdb 2106 is defined to be larger than 2*TCSGain*TpVGain, which may lead to lower power due to less frequent adjustments to Tp and Ts, but more Vo ripple. The dead band limits as used by the VSPL control loop may be different from the dead band limits used by the PFM control loop.

The VSPL method works exclusively with the magnitude of Ttcs and the signed displacement of Ttcs relative to Tdb 2106, making decisions based upon the position of Ttcs relative to Tdb 2106 and Treg 714 and the direction of change of Ttcs compared to its value at the time of the previous duty cycle event. The duty cycle of the switching power converter is changed only if the instant Ttcs is outside of the region Tdb 2106 and is moving away from Tdb 2106, shown as condition “C” or “D” in FIG. 27. If the instant Ttcs is moving towards Tdb 2106, annotated as condition “A” or “E” (or is within Tdb) no change is made in the Tp and Ts control signal times. In some embodiments, illustrated as condition “B” in FIG. 27, Ttcs is not allowed to be stable (that is, no change from sample to sample) within the regulation zone Treg 2114 (but outside of Tdb) beyond a predetermined amount of time.

### Section 5.4—Control Loop Logical Flow

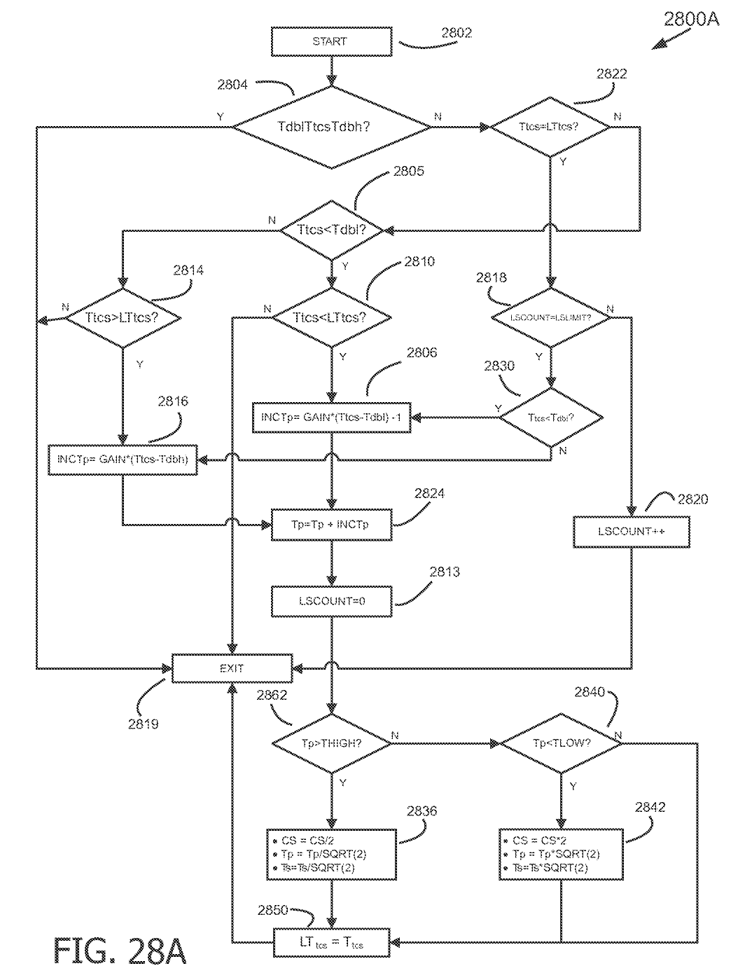

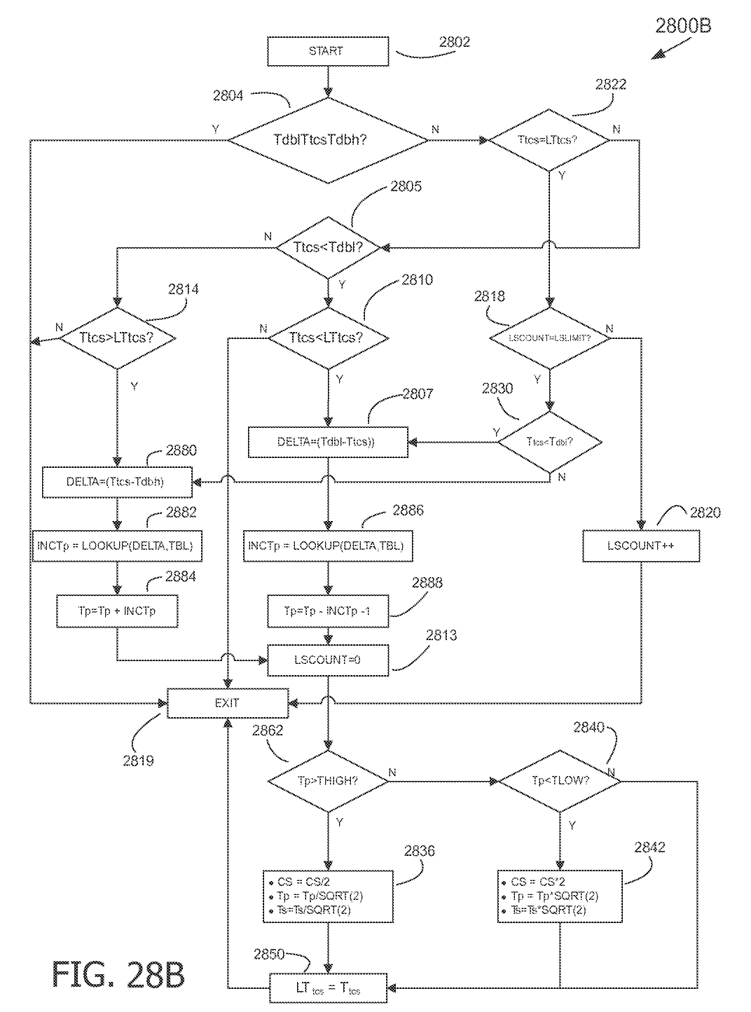

FIG. 28A is an example of a VSPL logic flow 2800A in accordance with one embodiment of the present invention. The flow is described in terms of counts corresponding to time or period. For example, Ttcs corresponds to the count (of periods of FASTCLK 174 into counter 172) during a period of TCS 122. In one embodiment of the present invention the logic is implemented by a random logic circuit. In some embodiments the method is implemented as a program for a microprocessor, for example the microprocessor 170 in the TPC 120. For the purpose of illustration we will describe the method as a program executed by microprocessor 170. The program may be called periodically at uniform times, for example every two microseconds, and enters at step 2802. Step 2804 tests for Ttcs within the dead band region by comparing the instant Ttcs to be above or equal to Tdbl 2104 and below or equal to Tdbh 2102. If the test is TRUE we exit to step 2819 and flow 2800A is complete for the instant iteration. If outside of the dead band region (step 2804 is FALSE), step 2822 tests for local stability by comparing the instant value of Ttcs to the previous value of Ttcs (LTtcs). LTtcs is the value of Ttcs saved in the previous iteration of flow 2800A at step 2850. If the test at step 2822 is TRUE we take step 2818 to check if a local stability counter LSCOUNT equals a predetermined maximum value LSLIMIT. This tests for a local stability condition, wherein Ttcs is outside of Tdb 2106, within Treg 2114, and not changing beyond a predetermined maximum time (i.e., counts of LSLIMIT).

LSLIMIT is predetermined by the system designer. A low value for LSLIMIT, for example 2, will provide very short local stability conditions. In one embodiment there is no test for local stability; that is, the condition is allowed to persist indefinitely, in which case step 2822 is not used (and steps 2818, 2830, 2820, and 2813 are eliminated; step 2824 proceeds to step 2862), and 2804 proceeds directly to step 2805 if FALSE. If LSCOUNT does not equal LSLIMIT at step 2818 we go to step 2820 to increment LSCOUNT before exiting at step 2819. If at step 2818 LSCOUNT=LSLIMIT, we take action to destabilize Ttcs; to move it towards Tdbl 2104. Step 2830 tests for Ttcs less than Tdbl 2104 to determine whether to adjust Ttcs higher or lower. If step 2830 is FALSE we know Ttcs is above Tdbh 2102 (we know the instant Ttcs is not in the dead band region, and not less than Tdbl 2104, therefore Ttcs must be above Tdbh) and branch to step 2816 for the appropriate correction. If step 2830 is TRUE we know the instant Ttcs is below Tdbl 2104, and branch instead to step 2806 for correction. Corrections to Tp and Ts are explained below.

If Ttcs is changing (that is, not equal to LTtcs) step 2822 will return FALSE and control passes to step 2805 to determine if Ttcs is above or below the region Tdb 2106 (we already know Ttcs is not within Tdb 2106 from step 2804). If Ttcs is below Tdbl 2104, step 2805 returns TRUE and we go to step 2810. Step 2810 compares Ttcs to LTtcs to determine if Ttcs is moving towards or away from Tdbl 2104. If the test at step 2810 returns FALSE (we already know from step 2822 that Ttcs is moving) we know that Ttcs is moving towards Tdbl 2104 (condition “E” on FIG. 27) so no change is made, exiting at step 2819. If step 2819 returns TRUE, then Ttcs is lower than Tdbl 2104 and moving lower (away; condition “D” on FIG. 27) so a correction is made.

We define a term

GAIN=(1/TCSGain)

which relates the change in Tp required to provide one quanta change in Ttcs. In accordance with the method of the present invention, corrections are made in proportion to the displacement (error, in quanta) of Ttcs from the nearest limit of the region T from the nearest limit of the region Tdb 2106. The correction in general is:

Error×GAIN=INCTp

wherein INCTP is the number of increments of TpVGain to be applied to the previous value of Tp to form the new value of control signal Tp on line 1228 (FIG. 12). That is, the new value of Tp is found by Tp=Tp+INCTp. At step 2806 the error is shown as (Ttcs−Tdbl). Tdbl 2104 is larger than Ttcs, making the error term negative. At step 2816 the error term is (Ttcs−Tdbh), which will be a positive number. Step 2824 is a signed addition, calculating the corrected Tp. In some embodiments the error term (steps 2806, 2816) is (Ttcs−Ttar), resulting in more gain by always calculating a larger error term.

In some embodiments, such as the example in FIG. 28A at step 2806, the adjustment INCTP is altered by one quanta such that the gain in one direction is not the same as the gain in the other direction. Thus the flow “explores” corrections (gains) until a solution is found which provides a Ttcs within the dead band region Tdb 2106. In one embodiment the adjustment is made at step 2816 instead of at step 2806. In some embodiments the adjustment is +1 vice −1. Other adjustment sizes may be used.

In one embodiment, as shown in FIG. 28B, the computations of step 2816 and 2806 are simplified by using a lookup table, thereby reducing the power requirement of the computations. An example lookup table is shown as Table 3.

TABLE 3

| DELTA | INCTp |
|---|---|
| 0 | 0 |
| 1 | 1 |
| 2 | 2 |
| 3 | 3 |
| 4 | 5 |
| 5 | 9 |
| 6 | 17 |
| 7 | 33 |
| 8 | 65 |
| 9 | 129 |
| 10 | 150 |
| 11 | 150 |
| 12 | 150 |
| 13 | 150 |
| 14 | 150 |
| 15 | 150 |

The input to the table, DELTA, is a positive number representing the offset of Ttcs from the nearest limit of Tdb. The predetermined table value of each INCTP corresponding to an offset (DELTA) is equivalent to the product of GAIN*(Offset) (steps 2816 and 2806 in FIG. 28A). A table lookup method provides means to predetermine a different gain value for each DELTA, if desired. For example, in some embodiments a lower gain is used for low DELTA values and a higher gain for very high DELTA values. The relationship between table entries need not be linear; for example the relationship between INCTP values may be logarithmic.

For the condition “C” (FIG. 27), DELTA is calculated as (Ttcs-Tdbh) at step 2880. The value of INCTP from Table 3 (step 2882) is added to Tp at step 2884 to increase Tp, thereby decreasing Ttcs. For the condition “D” (FIG. 27) DELTA is calculated as (Tdbl-Ttcs) at step 2886. The value of INCTP from Table 3 (step 2886) is subtracted from Tp at step 2888 thereby increasing Ttcs. In some embodiments an additional count is subtracted at step 2888 to provide an asymmetrical gain as a function of direction of change of Ttcs, as explained previously. In some embodiments steps 2882 and 2886 are the same step, implemented as a subroutine call in the program of microprocessor 170. Steps 2884 and 2888 bot proceed to step 2813 to clear the counter LSCOUNT. The reset of flow 2800B is the same as the flow 2800A, and not discussed further here.

Returning to FIG. 28A, step 2816 (FIG. 28A) is replaced by the steps 2880 and 2882. Step 2880 calculates the difference between Ttcs and Tdbh, setting DELTA equal to the result. The value of DELTA is then used at step 2882 to find INCTP by looking up DELTA in Table 3 and returning the value for INCTP from the corresponding entry

Returning to step 2805, if the test returns FALSE (therefore Ttcs is above Tdbh), control passes to step 2814, where Ttcs is compared to LTtcs. If the test at step 2814 is FALSE we know that Ttcs is above Tdbh 2102 and is moving (down) towards Tdbh 2102 (condition “A” on FIG. 27) so no change is made and we exit at step 2819. If step 2814 returns TRUE we know that Ttcs is above Tdbh 2102 and moving up (condition “C” on FIG. 27) so we calculate INCTP at step 2816 and go to step 2824.

Step 2824 calculates a new Tp for the next duty cycle. The local stability counter LSCOUNT is cleared at step 2813. In some embodiments step 2813 goes directly to step 2850. That is, steps 2862, 2836, 2840 and 2842 are not implemented. In particular, some embodiments of the present invention adjust the scheduling of activations of the drive circuit (the circuit that couples the input power source to the load) such that the drive circuit is used efficiently across a wide range of load values.

In some embodiments, the drive circuit is controlled to operate in proximity to its most efficient design point across a very broad range of loads by altering Tp and the skip count (CS) such that the charge delivered to the load is not changed but the ON time of FET 1214 is optimized for efficiency of FET 1214. Some embodiments also provide for control of the frequency of electronic noise such that interference with other circuit elements may be avoided by altering Tp and the skip count such that the charge delivered to the load is not changed but the time between drive events avoids certain predetermined frequencies.

A narrow range of pulse widths, which is obtained in some embodiments due to the input power source coupling durations being near the greatest efficiency value, allows the circuit designer to select components with an ideal combination of switching characteristics, capacitance, and on-resistance (RDS_on). The result is a power converter with good efficiency across a wide dynamic range of output power.

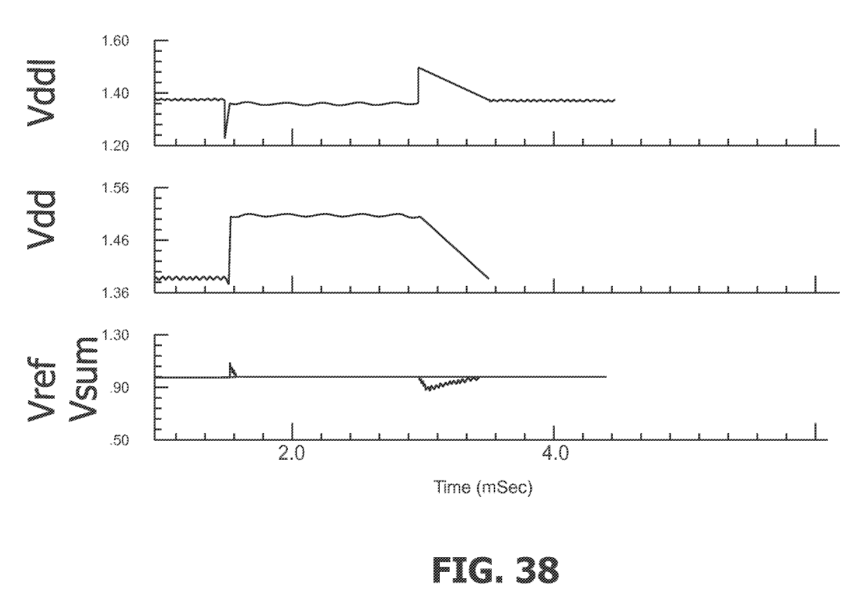

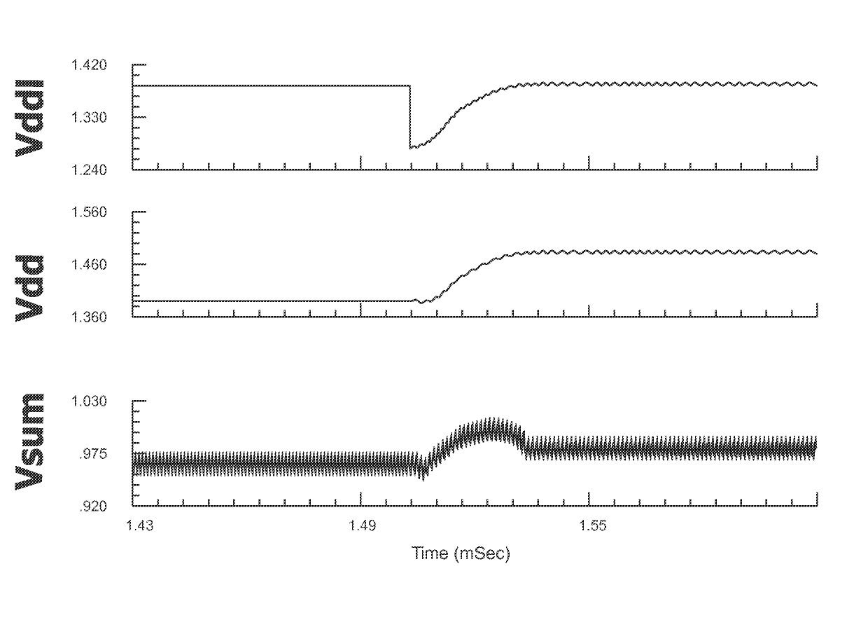

To maximize efficiency (i.e., the least loss from switching and high RDS_on) we determine an optimizing cycle skipping count and Tp combination. We want to avoid a very narrow Tp and Ts and do so by making the duty cycle pulses progressively wider but farther apart, up to a selected maximum skip count. This strategy is designed to maintain coil current pulses within a range that will be efficient for the given drive circuit (which includes transistors 1214 and 1216, coil L1 1218), regardless of the load. FIG. 38 shows the efficiency of an example drive circuit, plotted as line 3804, as a function of the Tp parameter (shown in microseconds). The efficiency is measured as a percentage of the charge provided at terminal 114 per unit of charge provided by a power source. If the range of the load current is very wide, implying Tp and Ts would vary from very narrow to very wide, the efficiency would suffer at those conditions away from a center value. Some embodiments of the present invention optimize the efficiency across a wide range of loads by adjusting the cycle skip count and Tp to keep the Tp pulse times within a narrow range. We predetermine a minimum Tp, termed “TLOW” 2900 and a maximum Tp, termed “THIGH” 2902. Keeping Tp values within this range keeps the drive circuit near its maximum efficiency condition. The cycle skip count is adjusted accordingly so that the energy delivered to the load is correct.

Looking again to FIG. 28A, the method begins with a loop comprised of steps 2862 and 2836 which compares Tp to THIGH 2902 and, if Tp is greater than THIGH, divides Tp and Ts by the square root of 2 (approximated by 1.5) while halving the skip count. (In some embodiments, Tp and Ts are multiplied by 0.75 as an approximation of division by square root of 2. Halving the skip count can be replaced by a right shift by 1 bit. The invention is not limited to specific computations.) This loop lowers the pulse width from that which was previously calculated, while providing approximately the same energy. Following the adjustments of step 2836 we save the instant Ttcs to the variable LTtcs in memory at step 2850, then exit at step 2819.

If Tp is not greater than THIGH 2902 at step 2862 we go to step 2840 to determine if Tp is below TLOW 2900. If TRUE, Tp and Ts are multiplied by the square root of two (i.e. by about 1.5) and the skip count is doubled at step 2842, again keeping the total charge approximately constant. Step 2842 adjusts CS, Tp, and Ts and proceeds to step 2850, saves Ttcs to the variable LTtcs in memory, and exits at step 2819. Only one adjustment is made per iteration of flow 2800A. In some embodiments step 2836 loops back to step 2862 until step 2862 returns FALSE, then step 2862 goes to step 2840. Steps 2840 and 2842 also loop until step 2840 returns FALSE. Such a method insures Tp is above TLOW and below THIGH before exiting flow 2800A.

To ensure that both conditions may be met, one can choose TLOW 2900 and THIGH 2902 such that both are positive numbers and THIGH>TLOW*SQRT(2) (or THIGH>TLOW*f, where “f” is the divisor at step 2836 and the multiplier at step 2842) for all conditions of temperature, voltage, load, and process variations, otherwise the step 2840/step 2842 loop may sometimes exit with Tp higher than THIGH. This condition may lead to a limit cycle. That is, if THIGH and TLOW are closer than a factor of SQRT(2), every iteration of flow 2800A wherein an adjustment is made to Tp (step 2894 is taken) will result in a change in skip count (CS).

In one embodiment TLOW 2900 is determined by the value of Tp wherein (Tp+Ts)>0.6*T and THIGH 2902 is determined by the value of Tp wherein (Tp+Ts)<0.95*T. Other values may be selected by the designer.

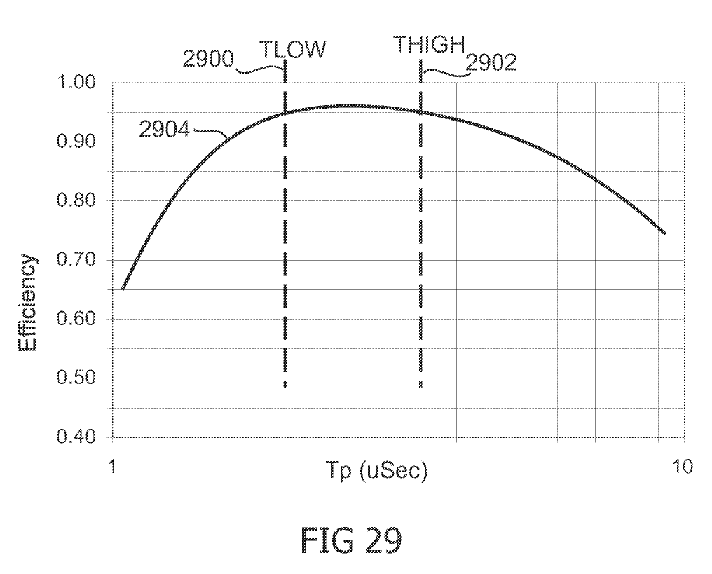

The result of this method is a cycle frequency that is a sub-harmonic of the fastest loop time T corresponding to the frequency of CS=1 (skip count=0). The process of doubling the skip count and scaling Tp and Ts calculates solutions that offer a consistent amount of energy. We are looking for the solution which keeps the pulse widths in the region for which the efficiency of the drive circuit is optimized. In some embodiments the strategy is to first calculate the energy needed (that is, Tp from the VSPL algorithm at step 2824), then change the skip count until the recalculated pulse width is between TLOW and THIGH, which in turn keeps the efficiency high regardless of the load, as FIG. 29 shows.

The designer may wish to limit the maximum skip count. In the case wherein the load would require a skip count in excess of the maximum allowed by the designer, Tp will be less than TLOW. In some such embodiments, when the system requires a skip count in excess of the maximum, PFM is used for the control loop instead of VSPL. Since we are using a sub-harmonic of a known frequency we know the family of frequencies precisely, and can therefore set a maximum skip count to insure we never get down to audio range, hit an IF frequency in a radio, or cause other similar concerns.

As noted above, the invention is not limited to particular computations. In some embodiments, at steps 2862 and/or 2840, the microprocessor 170 checks for a condition that some increasing function of Tp is greater than THIGH or TLOW. The increasing function of Tp can be Tp+Ts, in which case the steps 2862 and 2840 are as follows:
Step 2862: Tp+Ts>THIGH
Step 2840: Tp+Ts>TLOW.

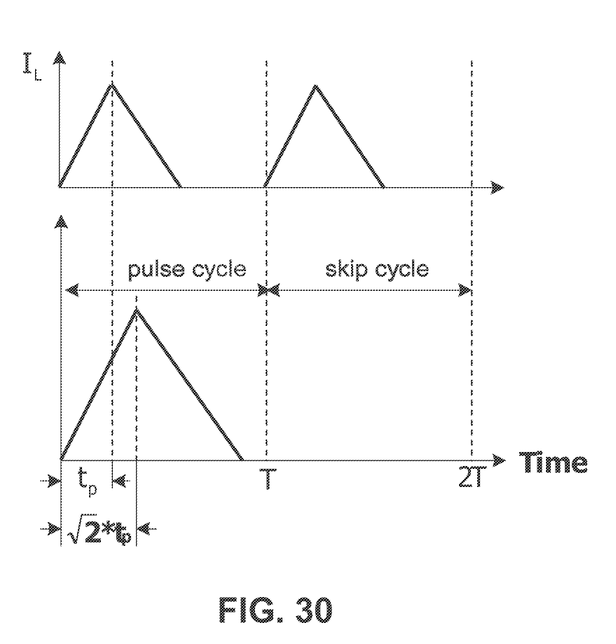

It would be clear to the ordinary artisan that the technique described is beneficial to any drive circuit, especially if the load current varies in a wide range. FIG. 30 illustrates two solutions for a certain energy level wherein the cycle skip counts are different and the pulse times adjusted according to the present invention. A floating point solution is presented.

The invention is not limited to multiplying or dividing Tp or Ts by SQRT(2) and doubling or halving the skip count. For example, Tp and Ts can be multiplied or divided by 2*SQRT(2) to increase or decrease the charge flowing into coil 1218 by a factor of 4, and the skip count can be multiplied or divided by 4. Other computational schemes can also be used to provide efficient operation by changing Tp and/or Ts and adjusting the skip count based on the load conditions.

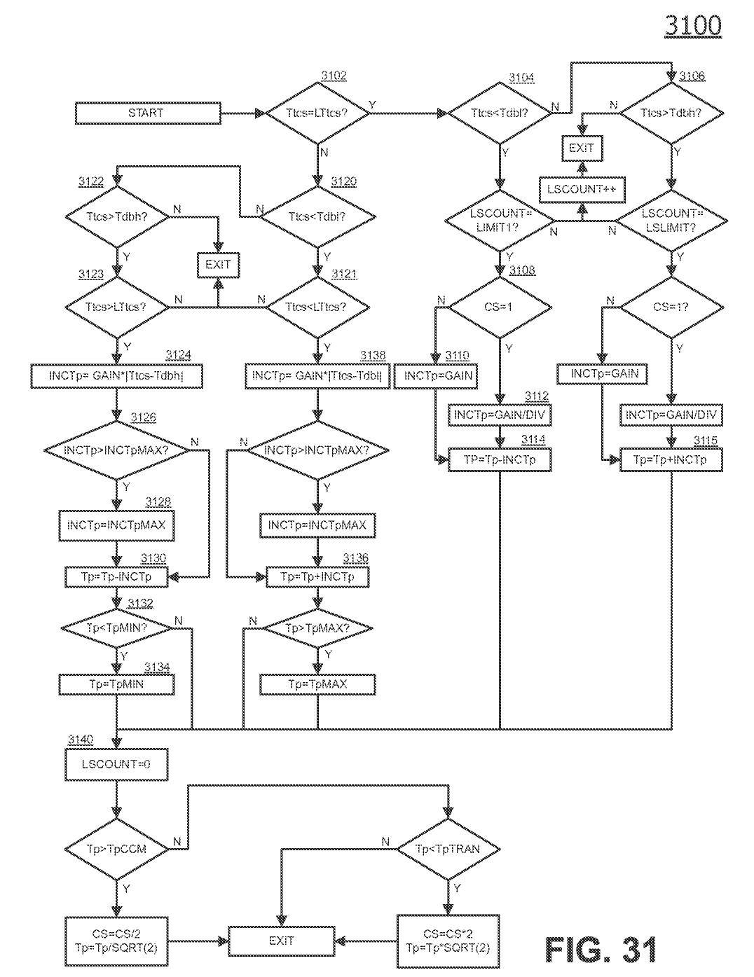

Some embodiments check for local stability before checking for the dead band vice the flow 2800A, wherein according to flow 2800A dead band is tested before local stability. Another embodiment modifies the gain when not cycle skipping. FIG. 31 is an example of an alternative embodiment of a VSPL logical flow. Only the differences from flow 2800A will be discussed.

The first action of flow 3100 is to compare the instant Ttcs to the previous (LTtcs). If equal, steps 3104 and 3106 check for Ttcs to be within Tdb 2106. As with flow 2800A, if Ttcs is outside of Tdb 2106 and not changing a counter LSCOUNT is compared to a maximum LSLIMIT. If the limit has not been reached, LSCOUNT is incremented and the flow exits. If the LSLIMIT has been reached, step 3108 checks for CS=1, which signifies the system is not cycle skipping. If cycle skipping, step 3110 calculates INCTP=GAIN and control passes to step 3114. If cycle skipping, control passes to step 3112 and the GAIN term is reduced by a factor DIV, for example DIV=2, providing more gain when cycle skipping than when not. At step 3114 Tp is changed by -INCTP, thereby moving Ttcs towards Tdbl 2104 (Vo will be reduced, thereby increasing Ttcs). If Ttcs is not below Tdbl 2104 at step 3104 step 3106 compares Ttcs to Tdbh 2102. If not above Tdbh 2102, then Ttcs is within dead band and flow 3100 exits with no further action. If Ttcs is above Tdbh 2102 at step 3106 we follow a sequence similar to the flow below step 3104, but at step 3115 INCTP is instead added to Tp, thereby moving Ttcs towards Tdbh 2102. Both local stability branches (3104, 3106) advance to step 3140. Step 3140 is discussed later.

If at step 3102 we see that Ttcs is not equal to LTtcs we know that Ttcs is changing and control passes to step 3120. Steps 3120 and 3122, as with steps 3104 and 3106, test for Ttcs within Tdb 2106. If so, flow 3100 exits at step 3125 with no further action. If step 3122 or step 3120 returns TRUE, we are outside of the dead band region and next test for above or below Tdb 2106. If Ttcs is below Tdbl 2104 and moving up (FALSE, step 3121) or if above Tdbh 2102 and moving down (FALSE, step 3123) again no action is taken and the flow exits. If Ttcs is above Tdbh 2102 and moving up, then a correction is made. At step 3124 the absolute value of the difference between Ttcs and Tdbh 2102 is multiplied by GAIN to calculate INCTP. Step 3126 tests INCTP in comparison to a predetermined value INCTpMAX and reduces INCTP to INCTpMAX if TRUE at step 3126, otherwise step 3126 is followed by step 3130. The final value of INCTP is subtracted from the instant Tp at step 3130, thereby moving Ttcs down towards Tdbh 2102. Steps 3132 and 3134 insure that the resulting Tp at step 3130 is at least a minimum value Tp_min.

If steps 3120 and 3121 return TRUE, a similar adjustment is made to Tp wherein Tp is increased by the final value of INCTP at step 3136, and the value reduced to a predetermined maximum Tp_max if indicated. All paths that make a change in Tp (3104, 3106, 3120, and 3122) pass control to step 3140, wherein the local stability counter LSCOUNT is cleared. Similar to flow 2800A, Tp and CS (wherein the number of cycles skipped equals CS−1) are adjusted using adaptive cycle skipping to keep Tp between a certain minimum and maximum value, here denominated TpTRAN and TpCCM respectively. In the example of flow 3100 the switching power converter is assumed to be non-synchronous, hence no adjustments to Ts are shown.

### Section 6—Optimizing a Parameter by Modifying a Different Parameter and Observing the Effect

When controlling more than one parameter, for example a power FET control signal Tp and a synchronous regulator FET control signal Ts of a switching power converter, one may not have complete information to directly optimize performance. Another example is the guard band times between driving ON/OFF a switching power converter power FET, and driving off OFF/ON a corresponding synchronous regulation FET. In one embodiment of the present invention a first parameter is changed and the effect on the steady state value of a second parameter is observed, the process repeated until the second parameter is found to be optimized, thereby optimizing the combined effect of both parameters.

In a synchronous regulator type switching power converter, the relationship between the power FET timing, Tp, and the synchronous regulator FET timing, Ts, is termed the “pulse geometry factor” or “K”. K is directly related to the ratio of input and output voltages (Vi/Vo). In particular, for an instant Tp there is a unique value for Ts wherein the coil 1218 current is zero at the end of the time Ts. If Vi and Vo (and the other particulars of the system) are known, the unique value for Ts may be found. However in some embodiments of the present invention the input and output voltages are not known, hence the pulse geometry factor is also not known. Any error in an estimate of the pulse geometry factor results in higher than optimal duty-cycles, defined as Tp/(Tp+Ts). As will be shown, the relationship between duty-cycle and pulse geometry factor has one single minimum (optimal duty-cycle) and is convex, therefore stable.

In this discussion we sometimes use the annotation Tp for tₚ, Ts for tₛ, and K for k interchangeably. Referring to FIG. 12, an example of a synchronous buck switching power converter, for purposes of this discussion we refer to the FET referred to by numeral 1214 as the “upper FET” or “power FET” and to the FET referred to by numeral 1216 as the “lower FET” or “synchronous regulator FET.” Other synchronous topologies may be used to practice the invention, though only that of a buck switching power converter is discussed here. One skilled in the art will be able to extend the teachings of the invention to other topologies.

The value of K is bounded between its maximum and minimum values by the relationship

Vᵢ₍ₘₐₓ₎/Vₒ₍ₘᵢₙ₎=kₘₐₓ≧k≧kₘᵢₙ=Vᵢ₍ₘᵢₙ₎/Vₒ₍ₘₐₓ₎.

In some embodiments the algorithm insures that K does not go outside of these limits. K_{MAX} and K_{MIN} are parameters external to the algorithm, determined by the system designer, wherein the system designer predetermines the referenced voltages.

The pulse geometry factor step size, ΔK, is an external parameter. It is determined such that in all allowable combinations of Vi, Tp, and Vo, a single increment of ΔK will never result in greater than one unit of change in the timing of Tp.

The strategy of the present invention is to determine the value of K that minimizes the control variable Tp when the system is equilibrium. At that point:

$$\frac{d {t}_{p}}{d k} = 0 ⇒ k = \frac{{V}_{i}}{{V}_{o}} .$$

We define the optimum lower FET pulse width Ts(opt) as:

$${T}_{s ( opt )} = ( \frac{{V}_{i}}{{V}_{o}} - 1 ) \cdot {T}_{p} .$$

### Whenever Ts=TS_{OPT} we can show that

$$\frac{d {t}_{p}}{d k} = 0 and k = \frac{{V}_{i}}{{V}_{o}} .$$

Defining the lower FET pulse width error (ΔTs) as:

$$Δ {T}_{s} = {T}_{s} - {T}_{s ( opt )} = {T}_{s} - {T}_{p} \cdot ( \frac{{V}_{i}}{{V}_{o}} - 1 ) ,$$

### ΔTs can be re-written as a function of K:

$$\begin{matrix}Δ {T}_{s} = ( K - 1 ) \cdot {T}_{p} - {T}_{p} \cdot ( \frac{{V}_{i}}{{V}_{o}} - 1 ) \\ = {T}_{p} \cdot ( K - \frac{{V}_{i}}{{V}_{o}} ) \\ = {T}_{p} \cdot \frac{{V}_{i}}{{V}_{o}} \cdot ( K \cdot \frac{{V}_{o}}{{V}_{i}} - 1 )\end{matrix} \qquad [ 8 ]$$

Varying the estimated pulse geometry factor K results in a change in the timing Tp of the upper FET. The change varies depending upon whether K is greater than Vi/Vo or less than Vi/Vo. Consider the condition wherein the estimated pulse geometry factor is larger than optimum. That is, K>Vi/Vo.

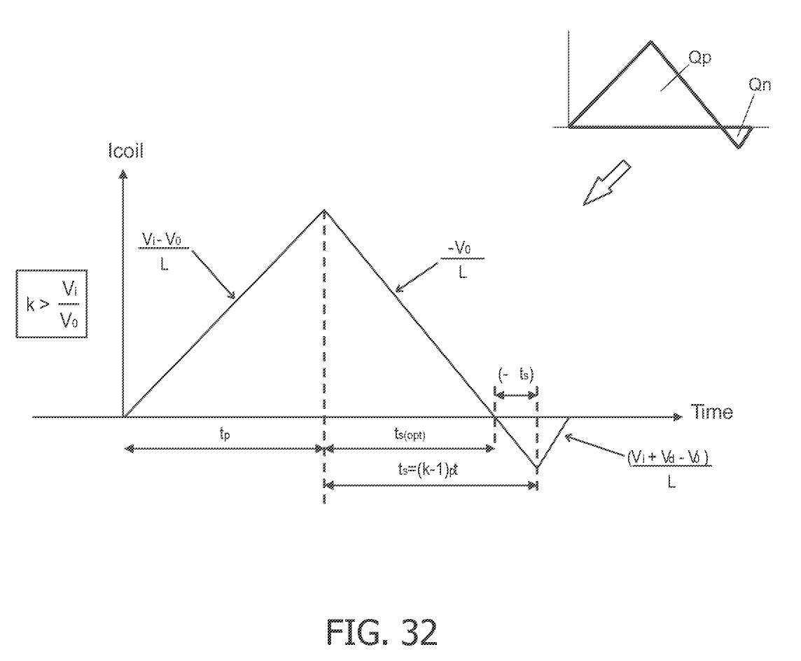

Looking to FIG. 32, the average coil current, which is equal to the load current during equilibrium, can be written as:

$${I}_{coil ( avg )} = \frac{1}{T} \cdot ( {Q}_{p} - {Q}_{n} ) = {I}_{load} , \qquad [ 9 ]$$

wherein T is the period of pulse Tp repetition, Qp is the area under the larger triangle, and Qn is the area of the smaller triangle. In this condition, wherein K is larger than optimum, the lower FET is ON longer than optimum, thus charge is removed from the load when the coil current becomes negative.

The charge injected into the load (Qp) is given by:

$${Q}_{p} = \frac{1}{2} \cdot {T}_{p} \cdot \frac{{V}_{i} - {V}_{o}}{L} \cdot ( {T}_{p} + {T}_{s ( opt )} ) = \frac{{T}_{p}^{2}}{2 L} \cdot \frac{{V}_{i}}{{V}_{o}} \cdot ( {V}_{i} - {V}_{o} ) \qquad [ 10 ]$$

and the charge removed from the load (Qn) is given by:

$$\begin{matrix}{Q}_{n} = \frac{1}{2} \cdot Δ {T}_{s} \cdot \frac{{V}_{o}}{L} \cdot ( Δ {T}_{s} + Δ {T}_{s} \cdot \frac{{V}_{o}}{{V}_{i} + {V}_{d} - {V}_{o}} ) \\ = \frac{Δ {T}_{s}^{2}}{2 L} \cdot \frac{{V}_{o}}{{V}_{i} + {V}_{d} - {V}_{o}} \cdot ( {V}_{i} + {V}_{d} )\end{matrix} \qquad [ 11 ]$$

So, according to equations [9], [10], and [11]:

$$2 LT \cdot {I}_{load} = {t}_{p}^{2} \cdot \frac{{V}_{i}}{{V}_{o}} \cdot ( {V}_{i} - {V}_{o} ) - Δ {t}_{s}^{2} \cdot \frac{{V}_{o}}{{V}_{i} + {V}_{d} - {V}_{o}} \cdot ( {V}_{i} + {V}_{d} ) .$$

Applying equation [8], we have:

$$\begin{matrix}2 LT \cdot {I}_{load} = \begin{matrix}{t}_{p}^{2} \cdot \frac{{V}_{i}}{{V}_{o}} \cdot ( {V}_{i} - {V}_{o} ) - {t}_{p}^{2} \cdot {( \frac{{V}_{i}}{{V}_{o}} )}^{2} \cdot {( k \cdot \frac{{V}_{o}}{{V}_{i}} - 1 )}^{2} \cdot \\ \frac{{V}_{O}}{{V}_{i} + {V}_{d} - {V}_{o}} \cdot ( {V}_{i} + {V}_{d} )\end{matrix} = \\ = {t}_{p}^{2} \cdot \frac{{V}_{i}}{{V}_{o}} \cdot ( {V}_{i} - {V}_{o} ) \cdot \\ [ 1 - {( k \cdot \frac{{V}_{o}}{{V}_{i}} - 1 )}^{2} \cdot \frac{{V}_{i}}{{V}_{i} + {V}_{d} - {V}_{o}} \cdot \frac{{V}_{i} + {V}_{d}}{{V}_{i} - {V}_{o}} ] .\end{matrix}$$

To find the control variable Tp as a function of the estimated pulse geometry factor K we use:

$${T}_{p} = \frac{{T}_{p ( 0 )}}{\sqrt{1 - {T}_{p ( gain + )} \cdot {( K \cdot \frac{{V}_{o}}{{V}_{i}} - 1 )}^{2}}} , \\ where {T}_{p ( 0 )} = \sqrt{2 LT \cdot {I}_{load}} \cdot \sqrt{\frac{{V}_{o}}{{V}_{i}} \cdot \frac{1}{{V}_{i} - {V}_{o}}}$$

$$and {T}_{p ( gain + )} = \frac{{V}_{i}}{{V}_{i} + {V}_{d} - {V}_{o}} \cdot \frac{{V}_{i} + {V}_{d}}{{V}_{i} - {V}_{o}}$$

For K>Vi/Vo, Tp is a monotonic function of K:

$$K > {V}_{i} / {V}_{o} ⇒ \frac{d {T}_{p}}{d K} > 0 ,$$

and it has its minimum at

K=Vᵢ/Vₒ [symbol] tₚ₍ₘᵢₙ₎=Tₚ₍₀₎.

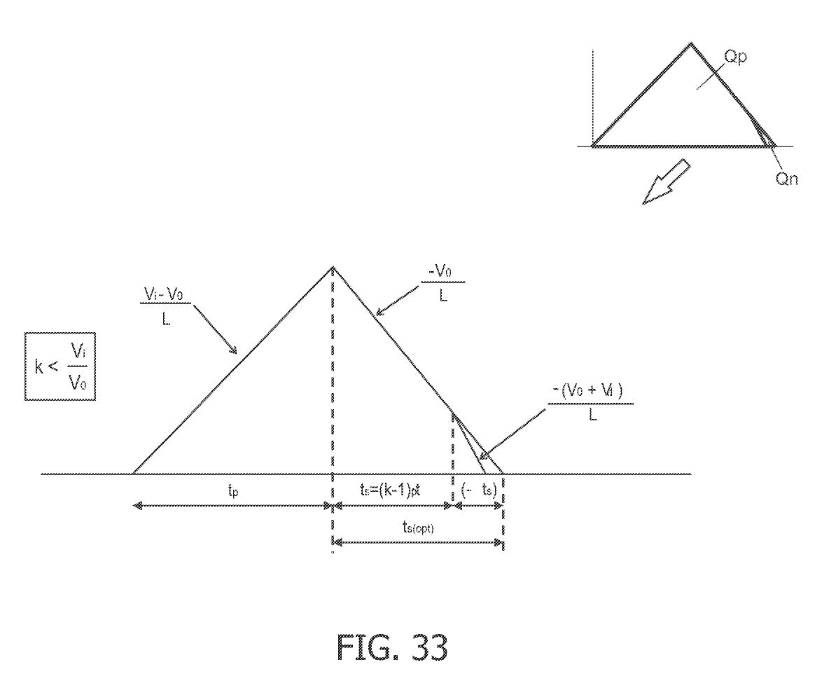

Now consider the condition wherein the estimated pulse geometry factor is smaller than optimum. That is, K<Vi/Vo. In this situation the lower FET is being turned OFF too soon (that is, Icoil has not yet reached zero amps). Referring to FIG. 33, we see that after the time (Tp+Ts) the slope of the falling coil current increases due to the body diode of the lower FET. No charge is removed from the load, but less than optimum charge is injected into the load. The net charge (the area under the Icoil vs. Time curve) can be found by again taking the injected charge Qp as though it were the optimum (that is, the entire outer triangle of FIG. 33) as:

$${Q}_{p} = \frac{{T}_{p}^{2}}{2 L} \cdot \frac{{V}_{i}}{{V}_{o}} \cdot ( {V}_{i} - {V}_{o} ) \qquad [ 9 ]$$

and then subtracting the diminishment of charge (Qn) given by:

$${Q}_{n} = \frac{1}{2} \cdot ( - Δ {T}_{s} ) \cdot \frac{{V}_{o} + {V}_{d}}{L} \cdot ( - Δ {T}_{s} ) \cdot \frac{{V}_{d}}{{V}_{o} + {V}_{d}} = \frac{Δ {T}_{S}^{2}}{2 L} \cdot {V}_{d} \qquad [ 10 ]$$

Applying equations 920, [15], and [16] we find

$$2 LT \cdot {I}_{load} = {T}_{p}^{2} \cdot \frac{{V}_{i}}{{V}_{o}} \cdot ( {V}_{i} - {V}_{o} ) - Δ {T}_{s}^{2} \cdot {V}_{d}$$

Now again applying equation [8] we find

$$\begin{matrix}2 LT \cdot {I}_{load} = {T}_{p}^{2} \cdot \frac{{V}_{i}}{{V}_{o}} \cdot ( {V}_{i} - {V}_{o} ) - {T}_{p}^{2} \cdot {( \frac{{V}_{i}}{{V}_{o}} )}^{2} \cdot {( K \cdot \frac{{V}_{o}}{{V}_{i}} - 1 )}^{2} \cdot {V}_{d} = \\ = {T}_{p}^{2} \cdot \frac{{V}_{i}}{{V}_{o}} \cdot ( {V}_{i} - {V}_{o} ) \cdot [ 1 - {( K \cdot \frac{{V}_{o}}{{V}_{i}} - 1 )}^{2} \cdot \frac{{V}_{i}}{{V}_{o}} \cdot \frac{{V}_{d}}{( {V}_{i} - {V}_{o} )} ]\end{matrix}$$

To find the control variable Tp as a function of the estimated pulse geometry K we look to:

$${T}_{p} = \frac{{T}_{p ( 0 )}}{\sqrt{1 - {T}_{p ( gain - )} \cdot {( K \cdot \frac{{V}_{o}}{{V}_{i}} - 1 )}^{2}}}$$

$$where {T}_{p ( gain - )} = \frac{{V}_{i}}{{V}_{o}} \cdot \frac{{V}_{d}}{( {V}_{i} - {V}_{o} )} .$$

So, for K<Vi/Vo, Tp is a monotonic function of K:

$$K < {V}_{i} / {V}_{o} ⇒ \frac{d {T}_{p}}{d K} < 0$$

and it has its minimum at:

K=Vᵢ/Vₒ [symbol] Tₚ=Tₚ₍ₘᵢₙ₎=Tₚ₍₀₎

Combining the two results we have finally:

$${T}_{p} = \{ \begin{matrix}\frac{{T}_{p ( 0 )}}{\sqrt{1 - {T}_{p ( gain + )} \cdot {( K \cdot \frac{{V}_{o}}{{V}_{i}} - 1 )}^{2}}} , & for K \geq \frac{{V}_{i}}{{V}_{o}} \\ \frac{{t}_{p ( 0 )}}{\sqrt{1 - {T}_{p ( gain )} \cdot {( T \cdot \frac{{V}_{o}}{{V}_{i}} - 1 )}^{2}}} , & for K \leq \frac{{V}_{i}}{{V}_{o}}\end{matrix} \qquad [ 11 ]$$

which is a function of the form presented in Appendix A.

As demonstrated in Appendix A, this function (equation [11]) is convex, with a single minimum at:

$$K = \frac{{V}_{i}}{{V}_{o}} ⇒ {T}_{p} = {T}_{p ( 0 )} .$$

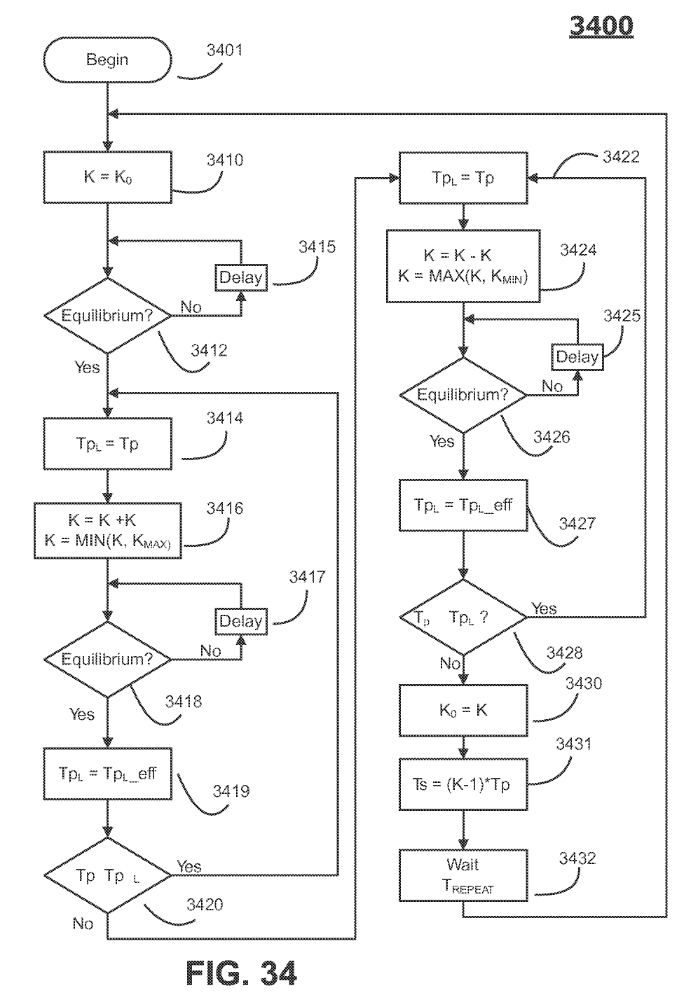

FIG. 34 is an example of a logical flow 3400 (“outer loop”) according to an embodiment of the present invention. We assume that an independent control loop (“inner loop”) is running to control the time value Tp of the power FET, and that the inner loop runs more often than the outer loop 3400. For example, the inner loop may execute every two microseconds and flow 3400 execute every two milliseconds. The actual frequencies will depend upon the performance requirements of the system, expected rate of change of load, temperature, etc. The inner loop makes the value of Tp available to flow 3400. For example, this may be done by using a shared memory location which the independent control loop may update and to which flow 3400 has access. In some embodiments the inner loop stores the value of the instant cycle skip count for use by the outer loop 3400. In one embodiment the inner loop tests for equilibrium and maintains a flag which the outer loop may test.

Flow 3400 is entered at step 3401 when called responsive to an external stimulus, such as a timing loop, a hardware timer, and recognition of a certain condition. At step 3410 we initialize a scaling parameter “K” with the value “Ko”. The designer of a system according to the present invention predetermines an initial value of Ko based upon assumptions of the typical relationship between Vi and Vo, to be used the first time flow 3400 executes. If flow 3400 has been executed previously, the logical flow 3400 will have saved a Ko value in memory for step 3410 (see step 3430).

At step 3412 we test for equilibrium. In one example of testing for equilibrium (applicable at steps 3412, 3418, and 3426), the inner loop sets a flag when the value of Tp has not changed for a predetermined time period, for example ten microseconds. The flag is available to flow 3400, which simply tests the flag at the appropriate time. In another example, at step 3412 or 3426, flow 3400 loops on reading the value of Tp (as read from the memory location shared with the inner loop) for a predetermined time period, and considers the test to be TRUE if Tp does not change during that time. One skilled in the art will know of other appropriate tests for equilibrium. When the equilibrium condition is recognized (step 3412 is TRUE), we go to step 3414, otherwise control returns to step 3412 after a small delay at step 3415, for example ten microseconds. At step 3414 we store the instant value of Tp to TPL so that we may later (step 3420) determine if Tp has increased or decreased as a result of the change in K from step 3416. At step 3416, we increase K by one incremental unit, discussed further below, then advance to step 3418 to again test for equilibrium. As at step 3418, we are again waiting for the inner loop to attain equilibrium. Until equilibrium is determined we loop back to step 3418 with a delay at step 3417 as we did at step 3415. When equilibrium is recognized at step 3418 we compare the instant value of Tp (step 3420) to the value of Tp_{L} that was saved at step 3414.

The maximum efficiency of a switching power converter is attained when Tp is at its minimum value that will provide current equilibrium. Said differently, if Tp is seen to be decreasing at step 3420 we know that we are moving K, hence Ts, in the direction that is improving efficiency, therefore we should continue changing in that direct, so we return to step 3414. If at step 3420 we see that the instant Tp is greater than the previous value of Tp (Tp_{L}), we know to stop increasing K, so go to step 3422. At step 3422 we again save the instant value of Tp to Tp_{L} so that we may continue to determine in which direction Tp is moving, responsive to changes in K. Steps 3424, 3425, 3426 and 3428 correspond to steps 3416, 3417, 3418 and 3420 except that we are now decreasing the instant value of K by one incremental unit (step 3424). Note that at step 3428 we are still looking for Tp to be decreasing, indicating improving efficiency, and loop back to step 3422 so long as Tp continues to decrease. When the test at step 3428 fails we know that we have optimized the value of K, hence Ts, because Tp is at its minimum value and the system is in equilibrium (steps 3426 and 3428). At step 3430 we store the instant value for K at Ko for use the next time flow 3400 executes. At step 3431 we calculate a value for Ts for use by the inner loop. In some embodiments step 3431 is not used; in such embodiments the inner loop uses the most recent value for K to calculate Ts in each iteration of the inner loop. The instant value of K may be stored to a shared memory location which the inner loop can access. We see, then, cooperation between the inner and outer (flow 3400) loops wherein the inner loop optimizes Tp and tests for equilibrium while the outer loop, flow 3400, optimizes the value of K which the inner loop uses to determine the synchronization time Ts.

At step 3432 we wait a predetermined delay period before executing flow 3400 again. As previously discussed, step 3432 may be implemented as any of several optional methods for initiating flow 3400.

In a system wherein flow 3400 was called and Tp was in equilibrium but not at optimum efficiency because the value of K was too high, the flow from step 3410 to 3420 executes only once, then the flow beginning at 3422 executes until optimization is attained. Likewise, if flow 3400 were called and the value of K is too low, the flow to step 3420 loops until the change in Tp started going back up, then the flow beginning at step 3422 executes only once because we had just passed the optimal value for K at step 3420.

In some embodiments the cycle skip count changes (for example, see U.S. patent application Ser. No. 11/030,585 previously cited for a more detailed treatment of adaptive cycle skipping), which would change the value of Tp (and the time period between Tp events) significantly. In one embodiment the outer loop flow 3400 adjusts for a change in cycle skip count at steps 3414, 3419, 3420, 3422, 3427, and 3428 by calculating an effective Tp and comparing to an effective value of Tp.

Defining the cycle skip count as “CS” wherein CS=0 means no cycle skipping, then we define Tp_{EFF} as:

Tp_{EFF}=Tp*SQRT(CS+1). [12]

That is, Tp_{EFF} is a function of Tp and CS, which the inner loop has been previously described as making available to the outer loop 3400. The effect of cycle skipping (and in particular, changes in cycle skipping) is then comprehended in flow 3400 by calculating an effective version of the instant Tp reported by the inner loop at steps 3414 and 3422 using equation [12] and saving Tp_{EFF} as Tp_{L}. Then at steps 3420 and 3428 the instant value of Tp is calculated as an effective value, again using equation [12], for comparison to the effective value of Tp previously stored as Tp_{L}.

The disclosed algorithm can be applied to other synchronous power conversion topologies operating in DCM, such as a boost power converter.

In some embodiments this method, wherein a control parameter, for example Ts, is slowly modified in an outer loop and the results evaluated in a more frequent inner loop to determine the optimum value of the control parameter, is used to optimize other parameters. For example, in one embodiment the technique according to the present invention is used to vary the guard band time between turning off a power FET and turning on a synchronous regulator FET in a switching power converter to optimize the delay time between the two signal edges such that efficiency is optimized. If a guard band time is used that is longer than optimum, some energy is wasted due to the synchronous regulator FET being off while coil conduction is occurring through the (higher resistance) synchronous regulator FET body diode vice through the FET. Conversely, if a guard band time is used that is shorter than optimum, some energy is wasted due to current flowing through the power FET directly to ground through the synchronous regulator FET instead of the coil.

As before, efficiency is determined to be optimized when the time Tp is at a minimum. In some embodiments the technique is used to optimize one parameter, such as Ts, interleaved with optimizing another parameter, such as the FET guard band.

### Section 7—A Temporal Power Converter Using a Linear Regulator

In some embodiments an analog solution provides control of the propagation delay of a monitored device. Two voltages are provided, one controlled by TCS 122, the other controlled by a precision timing signal. The precision timing signal is selected as the target period of the TCS 122, for example 1 microsecond. The two voltages are compared by an error amplifier. The error amplifier includes an output transistor (not shown), selected as appropriate for the power requirements of the load 3552. The error amplifier modifies the voltage provided to the TPM of the monitored device in response to the error, if any, between the voltage controlled by the TCS 122 and the voltage controlled by the precision timing signal, thereby controlling the period of the TCS to approximate the period of the timing signal.

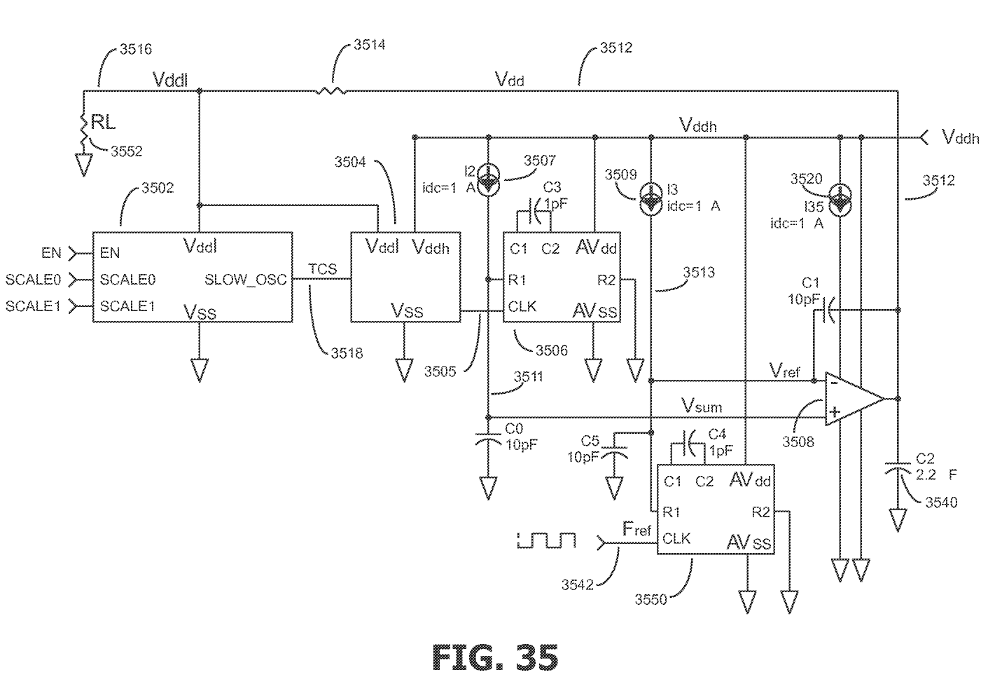

Referring to FIG. 35, a TPM 3502 provides a TCS on line 3518 corresponding to the propagation delay of a load, for example an integrated circuit and the TPM is located within the integrated circuit. The TPM 3502 may be a single monitor or may comprise multiple TPM circuits within the integrated circuit or multiple integrated circuits, as previously disclosed herein. In the example of FIG. 35, a single integrated circuit is shown by way of example. The load of the integrated circuit is represented by the variable load resistor RL 3552 on line 3516. As in earlier discussions resistor 3514 represents the resistance of the power matrix to the integrated circuit. For the example shown, the control circuitry is provided a different voltage (Vddh) than that provided to the integrated circuit (Vddl). A level shifter 3504 provides an interface between the two power domains. The TCS on line 3518 is replicated, level shifted, on line 3505. Line 3505 is connected to the CLK input lead of a switched capacitance resistor 3506. The resistance across the switched capacitor resistor 3506 (and that of switched capacitor resistor 3550) is responsive to the frequency of the signal on its CLK input lead. A current source 3507 provides a constant current to the line 3511. The product of the current from current source 3507 and the resistance of the switched capacitor resistor 3506 develops a voltage Vsum on line 3511. Line 3511 provides the voltage Vsum to the non-inverting input lead of an amplifier 3508. The switched capacitor resistor 3550 is provided an oscillating signal Fref by a precision oscillator (not shown) such as a crystal oscillator. The two switched capacitor resistors 3506, 3550 are identically designed such that their resistances will be equal when provided with signals at their CLK input leads of equal frequencies. A current source 3509 matches the current source 3506. The product of the current from current source 3509 and the resistance of the switched capacitor resistor 3550 develops a voltage Vref on line 3513 which provides the voltage Vref to the inverting input lead of the amplifier 3508. Filter capacitors, for example C0 between line 3511 and ground and C5 between line 3513 and ground, may reduce noise effects on the inputs to the error amplifier 3508.

A current source 3520 provides bias for the amplifier 3508, a standard technique known to one skilled in the art. The amplifier 3508 provides a voltage Vdd on line 3512, wherein the voltage Vdd is responsive to the difference voltage (Vsum−Vref). For example, if Vsum is greater than Vref, the output voltage Vdd of the amplifier 3508 will increase. The increase in voltage Vdd increases the voltage Vddl which lowers the propagation delay of the inverting elements of the ring oscillator of TPM 3502. The lower propagation delay within the TPM 3502 provides a TCS on line 3518 with a correspondingly shorter period Ttcs or, said differently, a higher frequency TCS. The higher frequency signal TCS 122, provided to the CLK input lead of the switched capacitance resistor 3506, decreases the resistance of the switched capacitance resistor 3506 thereby decreasing the voltage Vsum on line 3511, hence the non-inverting input lead of the amplifier 3508. As can be seen the amplifier 3508 operates to drive the period of the TCS to match the period of the precision frequency reference Fref, for example 1 MHz. An integrating capacitor, shown in FIG. 35 as capacitor C1, between the output stage and in inverting input of error amplifier 3508 improves stability.

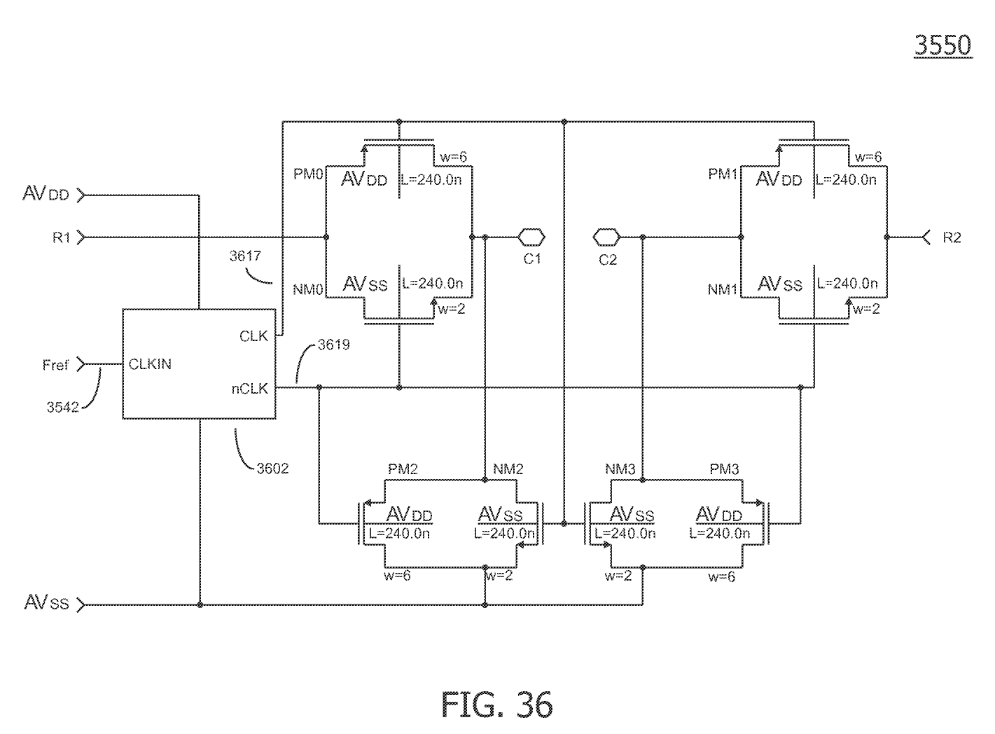

FIG. 36 is an example of the switches for the switched capacitance resistor 3550 (switched capacitance resistor 3506 is of the same circuit) wherein a circuit 3602 is driven at a CLKIN input terminal on lead 3542 by the signal Fref, the circuit 3602 providing complementary, non-overlapping clocks 3617, 3619 to drive the switches as shown. One skilled in the art will be able to provide a switched capacitance resistor wherein the resistance between the nodes R1 and R2 is a function of the CLKIN signal frequency and the size of the capacitor connected between nodes C1 and C2 (R=1/(fC)), for example 1 pF, therefore not further discussed here.

In some embodiments the resistance across the switched capacitor resistor 3506 or 3550 is altered to provide means for changing the power level and the set point for the propagation delay of the integrated circuit monitored by the TPM 122. In one embodiment the capacitors C3 and C4 (across pads C1 and C2 of switched capacitor resistors 3506 and 3550, respectively) are changed in value, for example by switching capacitors of various values in or out of the circuit, thereby changing the transfer function of the resistance as a function of capacitance. For example, increasing the effective value of capacitor C3 (FIG. 35) decreases the resistance of the switched capacitor resistor 3506 for a given frequency of the TCS 122, causing the voltage Vsum to decrease relative to Vref. In response, the error amplifier 3508 provides a lower voltage Vcc to the TPM 3502, thereby increasing the propagation delay and lowering the performance (and power consumption) of the monitored integrated circuit. In one embodiment the capacitor values are controlled by the monitored integrated circuit. In one embodiment the capacitor value is controlled by the monitored integrated circuit itself. In another embodiment, the capacitor value is controlled by an external resource.

Similarly, in one embodiment variable resistors are connected in series with the switched capacitor resistors 3506 and/or 3550. For example, an additional resistance between the switched capacitor resistor 3506 output lead R2 and ground increases the resistance between the switched capacitor resistor lead R1 and ground for a given TCS 122 frequency and capacitor C3 value. The constant current source 3507 then provides for an increase in the voltage drop Vsum, causing the error amplifier 3508 to increase Vdd

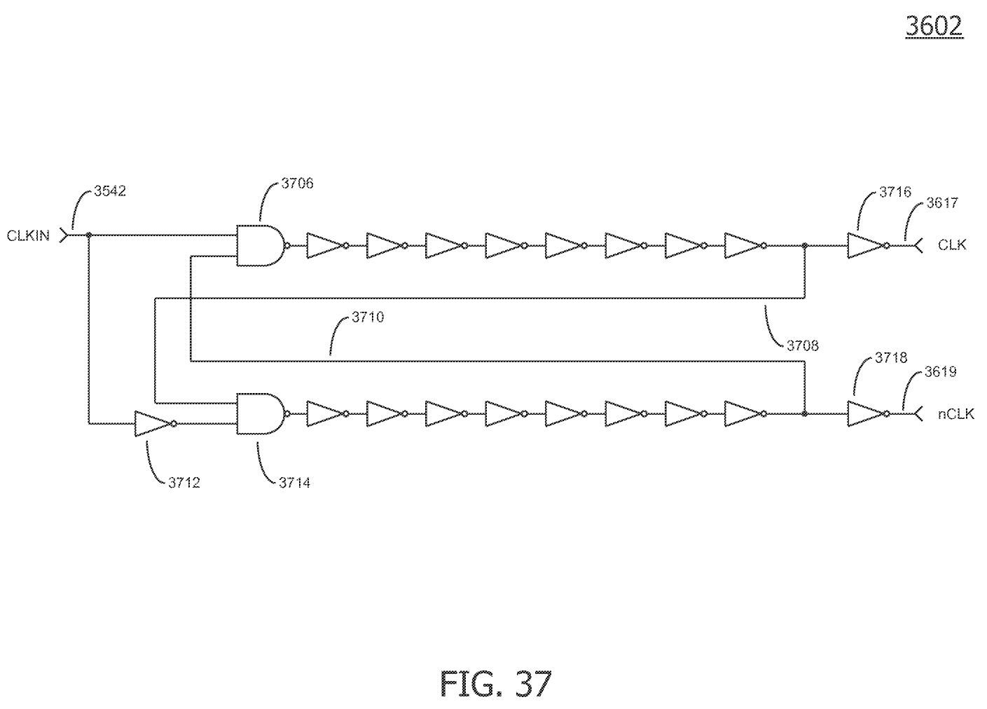

FIG. 37 is an example of the complementary, non-overlapping circuit 3602. The signal Fref on line 3542 is provided to a first input terminal of a first two-input NAND gate 3706. The signal CLKIN is also provided to the input terminal of an inverter 3712 which drives a signal that is the complement of CLKIN to a first input terminal of a second two-input NAND gate 3714. Through a series of inverters, the output lead of the first NAND gate 3706 is connected to the second input terminal of the second NAND gate 3714. An even number of inverters between the output terminal of the first NAND gate 3706 and the second input terminal of the second NAND gate 3714 provides a delay between the rising edge of the signal CLKIN at NAND gate 3706 and the falling edge of the signal at the second input terminal of the second NAND gate 3714. Similarly, the output terminal of the second NAND gate 3714 is connected to the second input terminal of the first NAND gate 3706 through a series of inverters. In some embodiments the number of inverters in each path is the same as the number of inverters in the other path.

The number of inverters in each path (that is between NAND 3706 and NAND 3714) is such that the delay from one NAND gate output signal to the next NAND gate input signal is sufficiently long under all design assumptions that the output signals CLK on line 3617 and nCLK on line 3619 are non-overlapping. Final inverters 3716, 3718 act as buffers and invert the signals on lines 3708 and 3710 to make the polarity of CLK the same as that of CLKIN for ease of understanding.

The simulations shown in FIG. 38 correspond to simulations of the signals Vddl on line 3516, Vdd on line 3512, and Vsum and Vref (superimposed) on line 3511 and 3513 (FIG. 35), during a time window between 1 msec and 5 msec. At 1.5 msec, a 10 mA load is applied to Vddl on line 3516, simulating the load RL 2562 to ground, through a 10 mohm resistor 3514 which represents interconnect resistance between the output lead of the voltage regulator (the voltage on line 3512) and the circuitry that is monitored by the TPM 3502. The resulting voltage drop across the resistor 3514 causes a reduction in the voltage Vddl seen by the TPM 3502, resulting in a higher propagation delay in the elements of the TPM 3502 and the circuitry it is monitoring, and a concomitant increase in the period of the TCS 122 on line 3518. The resulting increase in the period of the signal on line 3505 causes an increase in the resistance of switched-capacitor resistor 3506, causing signal Vsum on line 3511 to increase. The behavior of these signals is seen more clearly in the expanded view of FIG. 39.

The increase of the voltage Vsum on line 3511, which connects with the non-inverting input lead of error amplifier 3508, causes the output voltage on line 3512 of error amplifier 3508 to increase. A new steady-state operating point is established when the voltage on line 3512 is 100 mV (Iload*Rinterconnect=10 mA*10 ohms=100 mV) higher than the previous voltage level on line 3512. The voltage Vddl on line 3516 is again at or very close to the voltage that was on line 3516 before the imposition of the 10 mA load. The propagation delay that sets the period of the TCS on line 3518 is restored to its previous steady-state value.

Returning to FIG. 38, the new steady-state condition persists until the 10 mA load RL 2562 is removed at the 3 msec time point. The voltage Vddl on line 3516, seen by the TPM 3502, increases by nearly 100 mV because the voltage drop across the interconnect resistance 3514 has decreased by that much and the loop has not had time to respond. The now-lower propagation delay in the TPM 3502 causes a reduction in the resistance of the switched-capacitor resistor 3506 and a decrease of the voltage Vsum on line 3511.

In this implementation, amplifier 3508 responds quickly to a reduction of the voltage Vddl on line 3516 in order to maintain an adequate operating voltage for the circuitry being monitored by the TPM 3502. In one embodiment, the response to an increase in that voltage is much slower to provide better efficiency. The circuitry drains the excess voltage off of capacitor C2 3540 until the propagation delay in the TPM 3502 and its surrounding circuitry has reached its target and the steady-state operating condition is restored.

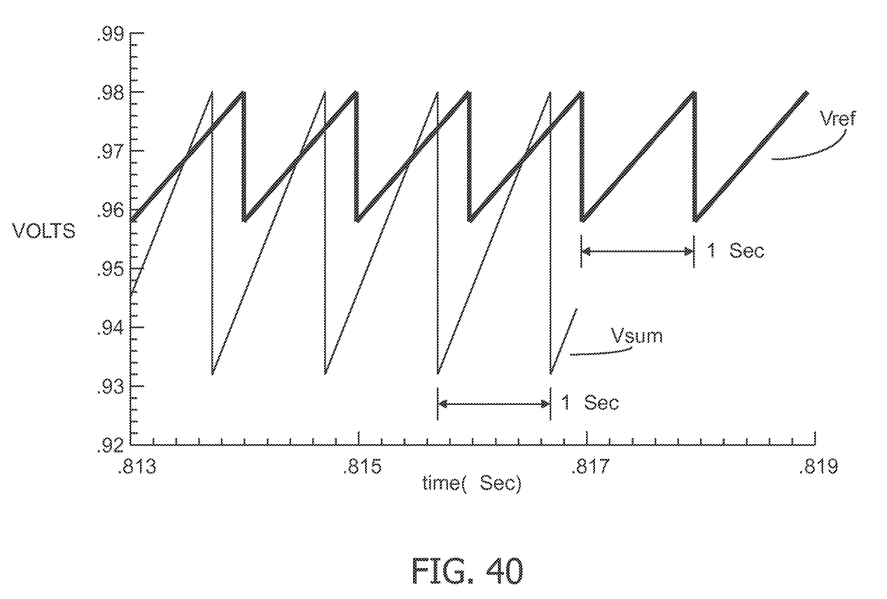

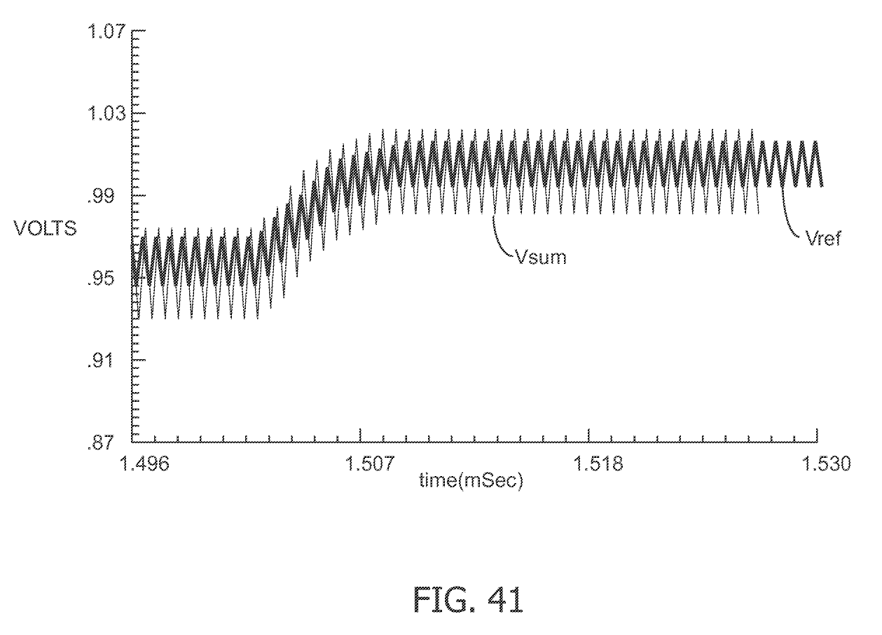

FIG. 40 is a further expanded view of FIG. 38 in the vicinity of the 0.8 mSec time point. At the 0.8 mSec point the signals Vref and Vsum are steady state. One can see that the signal periods are the same, with the RMS voltage of Vref slightly higher than the RMS voltage of Vsum due to the drop of the resistor 3514. FIG. 41 presents an expanded view at approximately 1.5 mSec (FIG. 38), illustrating the relationship between Vref and Vsum during transient recovery.

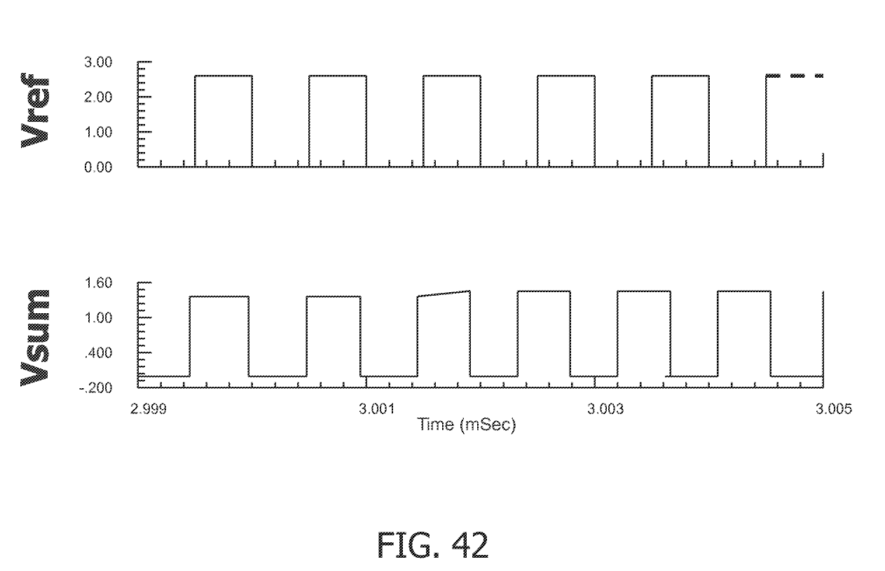

FIG. 42 shows the signal Fref on line 3542 and the corresponding TCS 122 on line 3518 at approximately the 3 mSec time point (FIG. 38). The increase in the voltage monitored by the TPM 3502 due to the removal of the load can be seen where the target propagation delay corresponds to a period of 5.0 minor ticks on the X-axis. Initially, the TCS 122, before 3.001 mSec, shows a period that is essentially identical to that of Fref, which represents the condition required for steady-state operation. Between 3.001 and 3.003 mSec, the voltage monitored by the TPM 3502 increases by 100 mV, resulting in a shorter propagation delay, about 4.4 minor ticks on the X-axis of FIG. 3. This associated inequality of signal periods driving the switched-capacitor resistors causes the slow corrections of the voltages seen in FIG. 38.

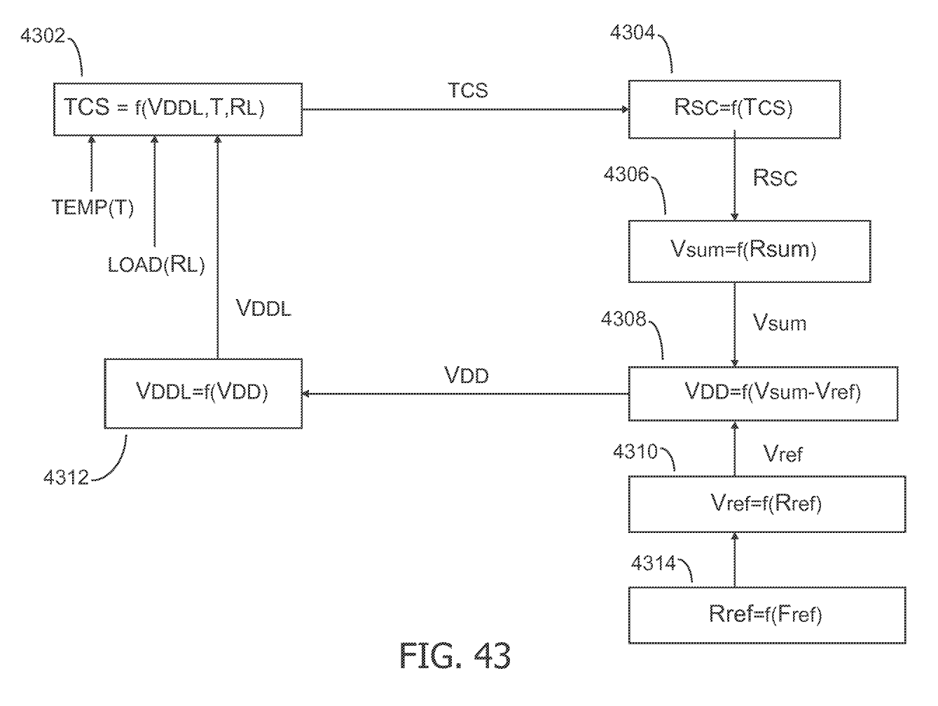

Though a control loop algorithm is not used, the apparatus and methods just described provide a control loop function. The interactions providing propagation delay control are illustrated by FIG. 43. The period of TCS 122 is a function of temperature, Vddl, and the load through RL 3552 (4302). The resistance of switched capacitance resistor 3506, denominated here as Rsum, is a function of the frequency of TCS 122 (4304). The voltage Vsum on line 3511 is a function of Rsum (4306). The resistance of the switched capacitance resistor 3550, denominated here as Rref, is a function of the frequency of the precision timing signal Fref (4314). The voltage Vref is a function of Rref (4310). Vdd, the output of the error amplifier 3508 on line 3512, is a function of the difference between Vsum and Vref (4308). Vddl is a function of Vdd (4312). Vddl, the voltage on line 3516, is a function of Vdd. Note that only dynamic elements are described by FIG. 43, though others may be lower order factors. For example, the value of the resistor 3514 representing the resistance of the power matrix of the monitored device may change slightly with temperature, which would be part of the function at 4312 (Vddl is lower than Vdd by the drop on resistor 3514), but is relatively fixed.

### Reservation of Extra-Patent Rights, Resolution of Conflicts, and Interpretation of Terms

If any disclosures are incorporated herein by reference and such incorporated disclosures conflict in part or whole with the present disclosure, then to the extent of conflict, and/or broader disclosure, and/or broader definition of terms, the present disclosure controls. If such incorporated disclosures conflict in part or whole with one another, then to the extent of conflict, the later-dated disclosure controls.

Given the above disclosure of general concepts and specific embodiments, the scope of protection sought is to be defined by the claims appended hereto. The issued claims are not to be taken as limiting Applicant's right to claims disclosed, but not yet literally claimed subject matter by way of one or more further applications including those filed pursuant to 35 U.S.C. §120 and/or 35 U.S.C. §251.

### APPENDIX A

### Given: the function

$$f ( x ) = \frac{1}{\sqrt{1 - a \cdot {x}^{2}}} ,$$

where 1>a>0 and 1/\sqrt{a}>x>−1/\sqrt{a}.
Its first derivative is:

$${f}^{′} ( x ) = \frac{( - 1 / 2 ) \cdot ( - 2 \cdot a \cdot x )}{{( 1 - a \cdot {x}^{2} )}^{3 / 2}} = a \cdot x \cdot \frac{1}{{( 1 - a \cdot {x}^{2} )}^{3 / 2}}$$

Its second derivative is:

$${f}^{″} ( x ) = \frac{a}{{( 1 - a \cdot {x}^{2} )}^{3 / 2}} + \frac{3 \cdot {a}^{2} \cdot {x}^{2}}{{( 1 - a \cdot {x}^{2} )}^{5 / 2}} = a \cdot \frac{1 + 2 \cdot a \cdot {x}^{2}}{{( 1 - a \cdot {x}^{2} )}^{5 / 2}}$$

Its third derivative is:

$$\begin{matrix}{f}^{′′′} ( x ) = a \cdot [ \frac{4 \cdot a \cdot x}{{( 1 - a \cdot {x}^{2} )}^{5 / 2}} + \frac{5 \cdot a \cdot x \cdot ( 1 + 2 \cdot a \cdot {x}^{2} )}{{( 1 - a \cdot {x}^{2} )}^{7 / 2}} ] = \\ = {a}^{2} \cdot x \cdot [ \frac{4}{{( 1 - a \cdot {x}^{2} )}^{5 / 2}} + \frac{5 \cdot ( 1 + 2 \cdot a \cdot {x}^{2} )}{{( 1 - a \cdot {x}^{2} )}^{7 / 2}} ] = \\ = \frac{{a}^{2} \cdot x}{{( 1 - a \cdot {x}^{2} )}^{7 / 2}} \cdot ( 4 - 4 \cdot a \cdot {x}^{2} + 5 + 10 \cdot a \cdot {x}^{2} ) = \\ = 9 \cdot {a}^{2} \cdot x \cdot \frac{1 + 2 / 3 \cdot a \cdot {x}^{2}}{{( 1 - a \cdot {x}^{2} )}^{7 / 2}}\end{matrix}$$

Its fourth derivative is:

$$\begin{matrix}{f}^{4} ( x ) = 3 \cdot {a}^{2} \cdot [ \frac{3 + 6 \cdot a \cdot {x}^{2}}{{( 1 - a \cdot {x}^{2} )}^{7 / 2}} + \frac{7 \cdot a \cdot x \cdot ( 3 \cdot x + 2 \cdot a \cdot {x}^{3} )}{{( 1 - a \cdot {x}^{2} )}^{9 / 2}} ] = \\ = 3 \cdot {a}^{2} \cdot [ \begin{matrix}\frac{3 + 6 \cdot a \cdot {x}^{2} - 3 \cdot a \cdot {x}^{2} - 6 \cdot {a}^{2} \cdot {x}^{4}}{{( 1 - a \cdot {x}^{2} )}^{9 / 2}} + \\ \frac{21 \cdot a \cdot {x}^{2} + 14 \cdot {a}^{2} \cdot {x}^{4}}{{( 1 - a \cdot {x}^{2} )}^{9 / 2}}\end{matrix} ] = \\ = 9 \cdot {a}^{2} \cdot [ \frac{1 + 8 \cdot a \cdot {x}^{2} + 8 / 3 \cdot {a}^{2} \cdot {x}^{4}}{{( 1 - a \cdot {x}^{2} )}^{9 / 2}} ]\end{matrix}$$

Its fifth derivative is:

$$\begin{matrix}{f}^{5} ( x ) = 9 \cdot {a}^{2} \cdot [ \begin{matrix}\frac{16 \cdot a \cdot x + 32 / 3 \cdot {a}^{2} \cdot {x}^{3}}{{( 1 - a \cdot {x}^{2} )}^{9 / 2}} + \\ \frac{9 \cdot a \cdot x \cdot ( 1 + 8 \cdot a \cdot {x}^{2} + 8 / 3 \cdot {a}^{2} \cdot {x}^{4} )}{{( 1 - a \cdot {x}^{2} )}^{9 / 2}}\end{matrix} ] = \\ = 9 \cdot {a}^{2} \cdot [ \begin{matrix}\frac{16 \cdot a \cdot x + 32 / 3 \cdot {a}^{2} \cdot {x}^{3}}{{( 1 - a \cdot {x}^{2} )}^{9 / 2}} + \\ \frac{9 \cdot a \cdot x \cdot ( 1 + 8 \cdot a \cdot {x}^{2} + 8 / 3 \cdot {a}^{2} \cdot {x}^{4} )}{{( 1 - a \cdot {x}^{2} )}^{9 / 2}}\end{matrix} ] = \\ = 9 \cdot {a}^{2} \cdot [ \begin{matrix}\frac{16 \cdot a \cdot x - 16 / 3 \cdot {a}^{2} \cdot {x}^{3} - 32 / 3 \cdot {a}^{3} \cdot {x}^{5}}{{( 1 - a \cdot {x}^{2} )}^{11 / 2}} + \\ \frac{9 \cdot a \cdot x + 72 \cdot {a}^{2} \cdot {x}^{3} + 24 \cdot {a}^{3} \cdot {x}^{5}}{{( 1 - a \cdot {x}^{2} )}^{11 / 2}}\end{matrix} ] = \\ = 225 \cdot {a}^{3} \cdot x \cdot [ \frac{1 + 8 / 3 \cdot a \cdot {x}^{2} + 8 / 15 \cdot {a}^{2} \cdot {x}^{4}}{{( 1 - a \cdot {x}^{2} )}^{11 / 2}} ]\end{matrix}$$

Its sixth derivative is:

$$\begin{matrix}{f}^{6} ( x ) = 225 \cdot {a}^{3} \cdot [ \begin{matrix}\frac{1 + 8 \cdot a \cdot {x}^{2} + 8 / 3 \cdot {a}^{2} \cdot {x}^{4}}{{( 1 - a \cdot {x}^{2} )}^{11 / 2}} + \\ \frac{11 \cdot a \cdot x \cdot ( x + 8 / 3 \cdot a \cdot {x}^{3} + 8 / 15 \cdot {a}^{2} \cdot {x}^{5} )}{{( 1 - a \cdot {x}^{2} )}^{13 / 2}}\end{matrix} ] = \\ = 225 \cdot {a}^{3} \cdot [ \begin{matrix}\frac{1 + 7 \cdot a \cdot {x}^{2} - 16 / 3 \cdot {a}^{2} \cdot {x}^{4} - 8 / 3 \cdot {a}^{3} \cdot {x}^{6}}{{( 1 - a \cdot {x}^{2} )}^{13 / 2}} + \\ \frac{11 \cdot a \cdot {x}^{2} + 88 / 3 \cdot {a}^{2} \cdot {x}^{4} + 88 / 15 \cdot {a}^{3} \cdot {x}^{6}}{{( 1 - a \cdot {x}^{2} )}^{13 / 2}}\end{matrix} ] = \\ = 225 \cdot {a}^{3} \cdot [ \frac{1 + 18 \cdot a \cdot {x}^{2} + 72 / 3 \cdot {a}^{2} \cdot {x}^{4} + 48 / 15 \cdot {a}^{3} \cdot {x}^{6}}{{( 1 - a \cdot {x}^{2} )}^{13 / 2}} ]\end{matrix}$$

It is clear that, for all odd derivatives:

fⁿ(0)=0 where n=1,3,5,7, . . . .

### Therefore, the Taylor series expansion of f(x) around x=0 yields:

$$f ( x ) = 1 + \frac{1}{2} \cdot a \cdot {x}^{2} + \frac{9}{24} \cdot {a}^{2} \cdot {x}^{4} + \frac{225}{720} \cdot {a}^{3} \cdot {x}^{6} + {\sum }_{n = 4}^{∞} \frac{{\prod }_{i = 1}^{n} {( 2 \cdot i - 1 )}^{2}}{( 2 n ) !} \cdot {a}^{n} \cdot {x}^{2 n}$$

Considering that:

$$( 2 n ) != {\prod }_{i = 1}^{n} ( 2 i ) \cdot {\prod }_{i = 1}^{n} ( 2 i - 1 ) and {\prod }_{i = 1}^{n} ( 2 u ) = {2}^{n} \cdot n ! , \\ we have {\prod }_{i = 1}^{n} ( 2 i - 1 ) = \frac{( 2 n ) !}{{2}^{n} \cdot n !} .$$

Therefore the Taylor Series Expansion can be simplified to:

$$f ( x ) = {\sum }_{n = 0}^{∞} \frac{( 2 n ) !}{{2}^{2 n} \cdot ( n ) !} \cdot {a}^{n} \cdot {x}^{2 n}$$

Applying a convergence test:

$$\begin{matrix}{lim}_{n \to ∞} [ \frac{\vert {b}_{n + 1} \vert}{\vert {b}_{n} \vert} ] = {lim}_{n \to ∞} [ \frac{( 2 n + 2 ) \cdot ( 2 n + 1 )}{{2}^{2} \cdot {( n + 1 )}^{2}} \cdot a \cdot {x}^{2} ] \\ = {lim}_{n \to ∞} [ \frac{( 2 n + 1 )}{2 \cdot ( n + 1 )} \cdot a \cdot {x}^{2} ] \\ = a \cdot {x}^{2} < 1.\end{matrix}$$

### Therefore, the series converges absolutely for

$$\vert x \vert < \frac{1}{\sqrt{a}} .$$

### Now, given the following approximation of the function f(x):

$$\overline{f ( x )} = 1 + \frac{1}{2} \cdot a \cdot {x}^{2} ,$$

its error function is:

$$Δ ( x ) = f ( x ) - \overline{f ( x )} = \frac{1}{\sqrt{1 - a \cdot {x}^{2}}} - ( 1 + \frac{1}{2} \cdot a \cdot {x}^{2} )$$

Now, given: the function g(x)=\sqrt{1−a·x²}
where 1>a>0 and i/\sqrt{a}>x>−1/\sqrt{a}.
Its first derivative is:

$${g}^{′} ( x ) = - \frac{a \cdot x}{\sqrt{1 - a \cdot {x}^{2}}} = - a \cdot x \cdot f ( x )$$

Its second derivative is:

g″(x)=−a·f(x)−a·x·f′(x)=−a·(f(x)+x·f′(x))

Its third derivative is:

g′″(x)=−a·(2·f′(x)+x·f″(x))

Its fourth derivative is:

g⁴(x)=−a·(3·f″(x)+x·f′″(x))

Therefore, its n^{th} derivative is:

g″(x)=−a·[(n−1)·fⁿ⁻²(x)+x·fⁿ⁻¹(x)]

For x=0, we have:

g(0)=1

g′(0)=0

g″(0)=−a·f(0)=−a

g′″(0)=−2·a·f′(0)=0

g⁴(x)=−3·a·f″(0)=−3·a²

gⁿ(x)=−(n−1)·a·fⁿ⁻²(0).

Therefore its Taylor Expansion Series is:

$$f ( x ) = 1 - \frac{1}{2} \cdot a \cdot {x}^{2} - \frac{3}{24} \cdot {a}^{2} \cdot {x}^{4} - {\sum }_{n = 3}^{∞} \frac{{\prod }_{i = 1}^{n} ( 2 \cdot i - 1 ) \cdot {\prod }_{i = 1}^{n - 1} ( 2 \cdot i - 1 )}{( 2 n ) !} \cdot {a}^{n} \cdot {x}^{2 n}$$

However, we have already shown that:

$${\prod }_{i = 1}^{n} ( 2 \cdot i - 1 ) = \frac{( 2 \cdot n ) !}{{2}^{n} \cdot n !} ⇒ ( 2 \cdot i - 1 ) = \frac{( 2 \cdot n ) !}{{2}^{n} \cdot n !} \cdot \frac{1}{2 \cdot n - 1}$$

Therefore its Taylor Expansion Series can be simplified to:

$$f ( x ) = - {\sum }_{n = 3}^{∞} \frac{( 2 n ) !}{{2}^{2 n} \cdot {( n ! )}^{2}} \cdot \frac{{a}^{n} \cdot {x}^{2 n}}{2 n - 1}$$

Therefore, the series converges absolutely for:

$$\vert x \vert < \frac{1}{\sqrt{a}} ,$$

and it diverges outside that interval, as it should, considering that the function f(x) is not defined outside that interval.

We claim:

1. Structure for controlling the voltage applied to an integrated circuit which comprises:
a power supply;
an integrated circuit including a temporal process monitor formed as part of said integrated circuit;
a voltage controlled oscillator provided as part of said temporal process monitor for producing a first output signal having a first period; and
a comparator for comparing said first period to one or more reference values;
wherein said first period greater than a first selected reference value causes said comparator to send a signal to said power supply to increase the voltage being supplied to said integrated circuit and wherein said first period less than a second selected reference value causes said comparator to send a signal to said power supply to decrease the voltage applied to said integrated circuit.

2. Structure as in claim 1 wherein said first selected value and said second selected value are equal.

3. Structure as in claim 1 wherein said first selected value is greater than said second selected value.

4. Structure as in claim 1, the voltage controlled oscillator further comprising means to prevent the voltage controlled oscillator from oscillating.

5. Structure as in claim 1 further comprising:
means for deriving from said first output signal a second output signal having a second period larger than said first period; and
wherein said comparator compares said second period to one or more reference values.

6. Structure as in claim 5 wherein said second period greater than a first selected value causes said comparator to send a signal to said power supply to increase the voltage being supplied to said integrated circuit and wherein said second period less than a second selected value causes said comparator to send a signal to said power supply to decrease the voltage being supplied to said integrated circuit.

7. Structure as in claim 6 wherein said first selected value and said second selected value are equal.

8. Structure as in claim 6 wherein said first selected value is greater than said second selected value.

9. Structure as in claim 1 wherein said comparator comprises:
a microprocessor for receiving a digital indication of said first period and for comparing said first period to a reference period, said microprocessor generating a signal to increase the voltage being supplied by said power supply to said integrated circuit when said first period exceeds said reference value by at least a first selected amount and said microprocessor generating a signal to decrease the voltage being supplied by said power supply to said integrated circuit when said first period is beneath said reference value by at least a second selected amount.

10. The structure of claim 9 further comprising a temporal power converter comprising said microprocessor, a counter and an oscillator for producing an output signal at a selected frequency for use in driving said counter to count the units of time represented by said first period.

11. The structure of claim 9 further comprising:
means for scaling said output signal from said voltage controlled oscillator to provide a temporal control signal with a second period different from said first period.

12. The structure of claim 11 wherein said second period is longer than said first period.

13. The structure of claim 11 wherein said temporal process monitor further comprises a level shifter connected to shift the level of said first output signal.

14. The structure of claim 10 wherein said temporal power converter comprises:
means for comparing said first period to at least one reference value; and
means for adjusting the voltage supplied by said power supply to said integrated circuit as a function of the difference between said first period and said at least one reference value.

15. The structure of claim 1 further comprising:
means for scaling the output signal from said voltage controlled oscillator to provide a temporal control signal with a second period longer than said first period; and
means for changing during operation the means for scaling to provide for a different magnitude of change in the temporal control signal.

16. The structure of claim 15 wherein said temporal process monitor is on an integrated circuit chip the voltage applied to which is being controlled and a temporal power converter is also on said integrated circuit chip.

17. The structure of claim 15 wherein said temporal process monitor is on an integrated circuit chip the voltage applied to which is being controlled and a temporal power converter is not on said integrated circuit chip.

18. The structure of claim 1, wherein a version of said first output signal is provided to said integrated circuit.

19. The structure of claim 18, wherein said version of said first output signal is a clock signal for digital logic of the integrated circuit.

20. The structure of claim 5, wherein a version of said second output signal is provided to said integrated circuit.

21. The structure of claim 20, wherein said version of said second output signal is a clock signal for digital logic of the integrated circuit.

22. A one or more structures, each for controlling the voltage applied to at least a portion of an integrated circuit wherein each such structure comprises:
a temporal process monitor formed as part of an integrated circuit said temporal process monitor comprising;
a voltage controlled oscillator for producing a first output signal having a first period;
a divider for dividing said first output signal to produce a second output signal having a second period longer than said first period;
means for providing a first output signal from said temporal process monitor, said means for providing comprising:
two input leads, one input lead carrying a first intermediate signal representing said second period, and the other input lead carrying a signal from a temporal process monitor in a preceding structure or a reference voltage if the structure containing said means for providing is the first structure in a series of said structures; and
an output lead from said means for providing, said output lead comprising one input lead to a means for providing in a next following temporal process monitor or, if the means for providing is in the last temporal process monitor in a series of such temporal process monitors, said output lead being connected to one or more pull-up transistors for pulling up the voltage on said output lead following a change of voltage on said output lead which indicates that all structures have completed the generation of a measure of the second period of the second output signal from the divider in each such temporal process monitor.

23. Structure as in claim 22 further comprising:
a comparator for comparing said second period to a reference period;
wherein said second period greater than a first selected value causes said comparator to send a signal to a power supply to increase the voltage being supplied to said integrated circuit and wherein a second period less than a second selected value causes said comparator to send a signal to said power supply to decrease the voltage being supplied to said integrated circuit.

24. Structure as in claim 23 wherein said first selected value is equal to said second selected value.

25. Structure as in claim 23, wherein said first selected value is greater than said second selected value.

26. Structure as in claim 22 wherein each temporal process monitor is on a separate integrated circuit chip.

27. Structure as in claim 22 wherein each temporal process monitor is on a different portion of a single integrated circuit chip.

28. Structure as in claim 25 wherein said first selected value and said second selected value are such as to provide a dead band between said first selected value and said second selected value within which no correction is made to the power being supplied to the integrated circuit.

29. A one or more structures, each for controlling the voltage applied to at least a portion of an integrated circuit, wherein each such one or more structures comprises:
a temporal process monitor formed as part of an integrated circuit, said temporal process monitor comprising;
a voltage controlled oscillator for producing a first output signal having a first period;
a divider for dividing said first output signal to produce a second output signal having a second period longer than said first period;
means for providing a first output signal from said temporal process monitor, said means for providing comprising:
an input lead, the input lead carrying a signal representing said second period; and
an output lead, said output lead connected one more pull-up transistors for pulling up the voltage on said output lead following a change of voltage on said output lead which indicates that all said one or more structures have completed the generation of a measure of the second period of the second output signal from the divider in each such temporal process monitor.

30. Structure as in claim 29, further comprising means to stop operation of said voltage controlled oscillator, said means to stop operation comprising:
a first lead carrying a signal from a preceding inverting element in the voltage controlled oscillator;
a second lead carrying the signal representing the second output signal from the divider in each such temporal process monitor; and
an output lead connected to an input of a next following inverting element in the voltage controlled oscillator.

31. Structure as in claim 30, further comprising means to start operation of said in the voltage controlled oscillator, said means to start operation comprising:
an input lead carrying the first output signal from the temporal process monitor, said input lead connected to means to reset said divider, wherein the divider changes a logical state of said second output signal.

32. Structure as in claim 29 further comprising:
a comparator for comparing said second period to a reference period;
wherein said second period greater than a first selected value causes said comparator to send a signal to a power supply to increase the voltage being supplied to said integrated circuit and wherein a second period less than a second selected value causes said comparator to send a signal to said power supply to decrease the voltage being supplied to said integrated circuit.

33. Structure as in claim 32 wherein said first selected value is equal to said second selected value.

34. Structure as in claim 32 wherein said first selected value is greater than said second selected value.

35. Structure as in claim 29 wherein each temporal process monitor is on a separate integrated circuit chip.

36. Structure as in claim 29 wherein each temporal process monitor is on a different portion of a single integrated circuit chip.

37. Structure as in claim 34 wherein said first selected value and said second selected value are such as to provide a dead band between said first selected value and said second selected value within which no correction is made to the power being supplied to the integrated circuit.

38. A method for controlling a propagation delay of an integrated circuit, wherein the integrated circuit includes a temporal process monitor formed as part of said integrated circuit, the method comprising generating one or more signals for a first circuit in a power converter, an output voltage of the first circuit controlling the propagation delay in accordance with the one or more signals, the one or more signals being generated according to one or more parameters, wherein generating the one or more signals comprises:
(1) performing consecutive period sampling operations to sample a period of a temporal control signal;
(2) in response to the period sampling operations, determining the one or more parameters by either (i) calculating at least one of the one or more parameters or (ii) leaving the one or more parameters unchanged without calculating the one or more parameters, wherein for each given period sampling operation in a first plurality of said period sampling operations, determining the one or more parameters comprises:
(2A) determining if at least one of the following conditions is true:
Condition 1: the period sampled in the given period sampling operation is above a period value obtained in an earlier period sampling operation associated with the given period sampling operation and is above a first selected value;
Condition 2: the period sampled in the given period sampling operation is below said period value obtained in said associated earlier period sampling operation and is below a second selected value;
(2B) if at least one of the Conditions 1 and 2 is true, then calculating at least one of the one or more parameters;
(2C) if neither the Condition 1 nor the Condition 2 are true, then leaving the one or more parameters unchanged without calculating the one or more parameters; and
(3) generating the one or more signals in accordance with the parameters determined in the operation (2).

39. The method of claim 38, wherein said first selected value and said second selected value are equal.

40. The method of claim 38, wherein said first selected value is greater than said second selected value.

41. The method of claim 40, wherein at least one of the one or more parameters is calculated proportional to a difference between the period sampled and one of the selected values.

42. The method of claim 38 wherein controlling the propagation delay comprises intermittently coupling an input power source to provide a current flow to generate the output voltage, and calculating at least one of the one or more parameters comprises calculating one or more parameters that determine a duration in which the input power source is coupled to provide the current flow.

43. The method of claim 38 wherein the parameter calculations are performed by a microprocessor.

44. The method of claim 38 wherein each said earlier period sampling operation immediately precedes its associated given period sampling operation in a sequence of said consecutive period sampling operations.

45. The method of claim 38 wherein determining the one or more parameters further comprises:
measuring a time since a Condition 3 is detected, wherein the Condition 3 is that the sampled period remains unchanged in consecutive period sampling operations;
if the Condition 3 persists for less than a predetermined interval of time, then leaving the one or more parameters unchanged without calculating the one or more parameters;
when the Condition 3 is detected to last for more than the predetermined interval of time, then calculating at least one of the one or more parameters to change the at least one of the one or more parameters.

46. The method of claim 38 wherein generating the one or more signals comprises:
providing consecutive current pulses from an input power source to generate the output voltage;
if the one or more parameters are changed, then changing an amount of charge in said current pulses, wherein each change in the amount of charge is at least as large in magnitude as a ringing charge.

47. A method for controlling a propagation delay of an integrated circuit, wherein the integrated circuit includes a temporal process monitor formed as part of said integrated circuit, the method comprising generating one or more signals for a first circuit in a power converter, an output voltage of the first circuit controlling the propagation delay in accordance with the one or more signals, the one or more signals being generated according to one or more parameters, wherein generating the one or more signals comprises:
(1) performing consecutive period sampling operations to sample a period of a temporal control signal;
(2) in response to the period sampling operations, determining the one or more parameters, wherein determining the one or more parameters comprises:
(2A) measuring a time since predefined one or more conditions are detected including a condition that the sampled period remains unchanged in consecutive period sampling operations;
(2B) if said predefined one or more conditions persist for less than a predetermined interval of time, then leaving the one or more parameters unchanged;
(2C) when said predefined one or more conditions are detected to last for more than the predetermined interval of time, changing at least one of the one or more parameters;
(3) generating the one or more signals in accordance with the parameters determined in the operation (2).

48. The method of claim 47 wherein controlling the propagation delay comprises intermittently coupling an input power source to provide a current flow to generate the output voltage, and calculating at least one of the one or more parameters comprises calculating one or more parameters that determine a duration in which the input power source is coupled to provide the current flow.

49. The method of claim 47 wherein generating the one or more signals comprises:
providing consecutive current pulses from an input power source to generate the output voltage;
if the one or more parameters are changed, then changing an amount of charge in said current pulses, wherein each change in the amount of charge is at least as large in magnitude as a ringing charge.

50. A computer readable storage medium comprising one or more computer instructions for determining the parameters according to the method of claim 38.

51. The computer readable storage medium of claim 50 wherein controlling the propagation delay comprises intermittently coupling an input power source to provide a current flow to generate the output voltage, and calculating at least one of the one or more parameters comprises calculating one or more parameters that determine a duration in which the input power source is coupled to provide the current flow.

52. A computer readable storage medium comprising one or more computer instructions for determining the parameters according to the method of claim 47.

53. The computer readable storage medium of claim 52 wherein controlling the propagation delay comprises intermittently coupling an input power source to provide a current flow to generate the output voltage, and calculating at least one of the one or more parameters comprises calculating one or more parameters that determine a duration in which the input power source is coupled to provide the current flow.

54. A computer data signal embodied in a carrier wave and comprising one or more computer instructions for determining the parameters according to the method of claim 38.

55. The computer data signal of claim 54 wherein controlling the propagation delay comprises intermittently coupling an input power source to provide a current flow to generate the output voltage, and calculating at least one of the one or more parameters comprises calculating one or more parameters that determine a duration in which the input power source is coupled to provide the current flow.

56. A computer data signal embodied in a carrier wave and comprising one or more computer instructions for determining the parameters according to the method of claim 47.

57. The computer data signal of claim 56 wherein controlling the propagation delay comprises intermittently coupling an input power source to provide a current flow to generate the output voltage, and calculating at least one of the one or more parameters comprises calculating one or more parameters that determine a duration in which the input power source is coupled to provide the current flow.

58. A method for controlling a propagation delay of an integrated circuit, wherein the integrated circuit includes a temporal process monitor formed as part of said integrated circuit, the method comprising generating one or more signals for a first circuit in a power converter, an output voltage of the first circuit controlling the propagation delay in accordance with the one or more signals, the one or more signals being generated according to one or more parameters, wherein generating the one or more signals comprises:
(1) performing a first period sampling operation to sample a first period of a temporal control signal;
(2) in response to the first period sampling operation, determining if the first period sampled in the first period sampling operation is above a first selected value;
(3) if the first period sampled is above the first selected value, generating the one or more signals in accordance with the one or more parameters.

59. The method of claim 58, further comprising:
(4) performing a second period sampling operation to sample a second period of the temporal control signal;
(5) in response to the second period sampling operation, calculating replacement one or more parameters, wherein said replacement one or more parameters are calculated by scaling the previous one or more parameters by the ratio of the second period sampled divided by a second selected value.

60. The method of claim 59, wherein said first selected value is greater than said second selected value.

61. The method of claim 58 wherein controlling the propagation delay comprises intermittently coupling an input power source to provide a current flow to generate the output voltage, and at least one of the one or more parameters determines a duration in which the input power source is coupled to provide the current flow.

62. The method of claim 59 wherein the one or more parameter scaling calculations are performed by a microprocessor.

63. A computer readable storage medium comprising one or more computer instructions for determining the parameters according to the method of claim 58.

64. The computer readable storage medium of claim 63 wherein controlling the propagation delay comprises intermittently coupling an input power source to provide a current flow to generate the output voltage, and at least one of the one or more parameters determines a duration in which the input power source is coupled to provide the current flow.

65. A computer data signal embodied in a carrier wave and comprising one or more computer instructions for determining the parameters according to the method of claim 58.

66. The computer data signal of claim 65 wherein controlling the propagation delay comprises intermittently coupling an input power source to provide a current flow to generate the output voltage, and at least one of the one or more parameters determines a duration in which the input power source is coupled to provide the current flow.

67. A method for controlling a switching power converter, said switching power converter including a power FET (UFET) and a synchronous regulator FET (LFET), said method comprising a first control loop, wherein said first control loop controls drive signals to the control gate of said UFET so that said switching power converter provides current to a load, wherein said current is in equilibrium with said load, and said first control loop further controls drive signals to said control gate of said LFET as a function of one or more variables provided by a second control loop.

68. The method according to claim 67, wherein said first control loop is executed more frequently than said second control loop.

69. The method according to claim 68, wherein said first control loop is executed at least ten times more frequently than said second control loop.

70. The method according to claim 67, wherein said one or more variables comprises a scalar, wherein said first control loop calculates an ON time period of said drive signal to said control gate of said LFET as a function of said scalar and of an ON time period of said drive signal to said control gate of said UFET.

71. The method according to claim 67, wherein said one or more variables comprises an ON time period of said drive signal to said control gate of said LFET.

72. The method according to claim 67, wherein said one or more variables comprises a delay time period between turning off the drive signal to said control gate of said UFET and turning on the drive signal to said control gate of said LFET.

73. The method according to claim 67, wherein said one or more variables comprises a delay time period between turning on the drive signal to said control gate of said UFET and turning off the drive signal to said control gate of said LFET.

74. The method according to claim 67, wherein said second control loop comprises the ordered steps of:
(a) retrieving a stored value of said variable;
(b) monitoring the ON time period of said UFET until the ON time of said UFET drive signal is approximately steady;
(c) storing said ON time period of said UFET;
(d) increasing the value of said variable;
(e) monitoring the ON time period of said UFET until said ON time of said UFET drive signal is approximately steady;
(f) comparing the instant value of the ON time period of said UFET to said stored value of the ON time period of said UFET;
(g) if the instant value of the ON time period of said UFET is less than or equal to the stored value of the ON time period of said UFET, repeating the steps beginning with step (c), wherein said instant value of the ON time period is stored; otherwise
(h) storing said instant value of said UFET ON time period;
(i) decreasing the value of said variable;
(j) monitoring the ON time period of said UFET until the ON time period of said UFET drive signal is approximately steady;
(k) comparing said instant value of said UFET ON time period to said instant value of the ON time period of said UFET; and
(l) if said instant value of the ON time period of said UFET is less than or equal to said stored value of the ON time period of said UFET, repeating the steps beginning with step (h), wherein said instant value of the ON time period is stored.
